(19) United States
(12) Patent Application Publication
(10) Pub. No.: US 2023/0100327 A1
(43) Pub. Date: Mar. 30, 2023

(54) COMPOSITION, DRIED PRODUCT, CURED SUBSTANCE, TRANSFER FILM, MANUFACTURING METHOD OF TRANSFER FILM, AND PATTERN FORMING METHOD

(71) Applicant: FUJIFILM Corporation, Tokyo (JP)

(72) Inventors: Masaya SUZUKI, Shizuoka (JP); Keigo YAMAGUCHI, Shizuoka (JP); Yohei ARITOSHI, Shizuoka (JP); Tadashi KAJIYA, Shizuoka (JP)

(73) Assignee: FUJIFILM Corporation, Tokyo (JP)

(21) Appl. No.: 17/873,826

(22) Filed: Jul. 26, 2022

(30) Foreign Application Priority Data
Jul. 30, 2021 (JP) 2021-126171
Mar. 24, 2022 (JP) 2022-048835

(51) Int. Cl. G03F 7/028; G03F 7/004; G03F 7/34

(52) U.S. Cl. CPC G03F 7/028; G03F 7/0048; G03F 7/343

(57) ABSTRACT

Provided are (1) a composition including an alkali-soluble resin, a polymerizable compound, a photopolymerization initiator, a surfactant, and a solvent, in which a surface tension measured by a Wilhelmy method at 25° C. is 26.5 mN/m or less; (2) a composition including a surfactant and a solvent, in which a surface tension T1 measured by a Wilhelmy method at 25° C. and a surface tension T2 measured by a Wilhelmy method at 25° C. immediately before a timing that a volume reaches 60% of an initial volume in an environment of a temperature of 25° C. and a relative humidity of 60% satisfy a relationship of T1>T2; and (3) applications thereof.

### CROSS-REFERENCE TO RELATED APPLICATIONS

This application claims priority under 35 USC 119 from Japanese Patent Application No. 2021-126171 filed on Jul. 30, 2021, and from Japanese Patent Application No. 2022-048835 filed on Mar. 24, 2022, the disclosures of which are incorporated by reference herein in their entirety.

### BACKGROUND OF THE INVENTION

### 1. Field of the Invention

The present disclosure relates to a composition, a dried product, a cured substance, a transfer film, a manufacturing method of a transfer film, and a pattern forming method.

### 2. Description of the Related Art

In a pattern forming method using a photosensitive composition, for example, a pattern is formed by exposing and developing a photosensitive layer formed of the photosensitive composition. The photosensitive composition may also be used in a method of forming a protective film of an electrode for a touch panel. For example, WO2013/084873A discloses a photosensitive resin composition used for forming a protective film of an electrode for a touch panel. The photosensitive resin composition disclosed in WO2013/084873A contains a binder polymer having a carboxyl group and having an acid value of 30 to 120 mgKOH/g, a photopolymerizable compound having at least three ethylenically unsaturated groups, and a photopolymerization initiator.

### SUMMARY OF THE INVENTION

In a pattern forming method using a composition in the related art, bubbles may be generated in a development. In a case where a time from the generation of bubbles to the disappearance of bubbles is long, a contact of to developer with an object to be treated may be hindered and a uniformity of development may be reduced.

In a case where the composition is applied to the object, a coating streak may occur. The following phenomena are considered as one of causes of the coating streak. For example, by raising the composition discharged from a coating device such as a slit coater, it is considered that a liquid pool of the composition is generated near a discharge port of the coating device, and the liquid pool adheres to a coating film so that the coating streak occur. Further, as a coating speed increases, the coating streak is more likely to occur.

An object of one embodiment of the present disclosure is to provide a composition in which, even in a case where bubbles are generated during development, a time from the generation of bubbles to the disappearance of bubbles is shortened.

An object of another embodiment of the present disclosure is to provide a composition in which a coating streak during high-speed coating is reduced.

An object of another embodiment of the present disclosure is to provide a dried product of the above-described composition.

An object of another embodiment of the present disclosure is to provide a cured substance of the above-described composition.

An object of another embodiment of the present disclosure is to provide a transfer film formed of the above-described composition.

An object of another embodiment of the present disclosure is to provide a manufacturing method of a transfer film formed of the above-described composition.

An object of another embodiment of the present disclosure is to provide a pattern forming method using the above-described composition.

The present disclosure includes the following aspects.

<1> A composition comprising:
an alkali-soluble resin;
a polymerizable compound;
a photopolymerization initiator;
a surfactant; and
a solvent,
in which a surface tension measured by a Wilhelmy method at 25° C. is 26.5 mN/m or less.

<2> The composition according to <1>,
in which the surface tension at 25° C. is 23.0 mN/m or more.

<3> The composition according to <1> or <2>,
in which the surfactant is at least one compound selected from a fluorine-based surfactant, a silicone-based surfactant, or a hydrocarbon-based surfactant.

<4> The composition according to <1> or <2>,
in which the surfactant is a silicone-based surfactant.

<5> The composition according to any one of <1> to <4>,
in which a surface tension of a mixture of 1 part by mass of a solid content of the surfactant, 1,000 parts by mass of water, and 2,300 parts by mass of methanol, which is measured by the Wilhelmy method, at 25° C., is 20.0 mN/m to 29.0 mN/m.

<6> The composition according to any one of <1> to <5>,
in which the solvent is at least one compound selected from the group consisting of methyl ethyl ketone, propylene glycol monomethyl ether acetate, propylene glycol monomethyl ether, toluene, xylene, isobutanol, phenyl glycol, methoxypropyl acetate, phenoxyethanol, dipropylene glycol monomethyl ether, n-butyl acetate, n-propyl acetate, ethyl acetate, isopropyl acetate, isobutyl acetate, methyl acetate, diacetone alcohol, cyclohexanone, ethylene glycol monoethyl ether, ethylene glycol monoethyl ether acetate, ethylene glycol mono-n-butyl ether, and ethylene glycol monomethyl ether.

<7> A manufacturing method of a transfer film, comprising, in the following order:
applying the composition according to any one of <1> to <6> to a temporary support; and
drying the composition.

<8> A transfer film comprising:
a temporary support; and
a dried product of the composition according to any one of <1> to <6>.

<9> A pattern forming method comprising, in the following order:
preparing a laminate including a base material and a dried product of the composition according to any one of <1> to <6>;
exposing the dried product in a patterned manner; and
developing the dried product using a developer to form a resin pattern.

<10> A cured substance of the composition according to any one of <1> to <6>.

<11> A composition comprising:
a surfactant; and
a solvent,
in which a surface tension T1 measured by a Wilhelmy method at 25° C. and a surface tension T2 measured by a Wilhelmy method at 25° C. immediately before a timing that a volume reaches 60% of an initial volume in an environment of a temperature of 25° C. and a relative humidity of 60% satisfy a relationship of T1>T2.

<12> The composition according to <11>,
in which the surface tension T1 is 25 mN/m to 35 mN/m.

<13> The composition according to <11> or <12>, in which the surface tension T2 is 20 mN/m to 26 mN/m.

<14> The composition according to any one of <11> to <13>, in which the surface tension T1 and the surface tension T2 satisfy a relationship of 5 mN/m<(T1−T2)<10 mN/m.

<15> The composition according to any one of <11> to <14>,
in which the solvent includes water and an organic solvent.

<16> The composition according to <15>,
in which the organic solvent is an organic solvent which does not azeotrope with the water.

<17> The composition according to <16>,
in which a ratio of a content of the organic solvent which does not azeotrope with the water to a content of the water is 10/90 to 90/10 on a mass basis.

<18> The composition according to <16> or <17>,
in which the organic solvent which does not azeotrope with the water is methanol.

<19> The composition according to any one of <11> or <18>,
in which the surfactant is at least one compound selected from a fluorine-based surfactant, a silicone-based surfactant, or a hydrocarbon-based surfactant.

<20> The composition according to any one of <11> to <18>,
in which the surfactant is a nonionic surfactant.

<21> The composition according to any one of <11> to <20>, further comprising:
a photopolymerization initiator.

<22> The composition according to any one of <11> to <21>, further comprising:
a polymerizable compound.

<23> The composition according to any one of <11> to <22>, further comprising:
a polymer.

<24> The composition according to any one of <11> to <23>, further comprising:
particles.

<25> A pattern forming method comprising, in the following order:
preparing a laminate including a base material and a dried product of the composition according to any one of <11> to <24>;
exposing the dried product in a patterned manner; and
developing the dried product using a developer to form a resin pattern.

<26> A transfer film comprising:
a temporary support; and
a dried product of the composition according to any one of <11> to <24>.

<27> A dried product of the composition according to any one of <11> to <24>.

According to one embodiment of the present disclosure, a composition in which, even in a case where bubbles are generated during development, a time from the generation of bubbles to the disappearance of bubbles is shortened is provided.

According to another embodiment of the present disclosure, a composition in which a coating streak during high-speed coating is reduced is provided.

According to another embodiment of the present disclosure, a dried product of the above-described composition is provided.

According to another embodiment of the present disclosure, a cured substance of the above-described composition is provided.

According to another embodiment of the present disclosure, a transfer film formed of the above-described composition is provided.

According to another embodiment of the present disclosure, a manufacturing method of a transfer film formed of the above-described composition is provided.

According to another embodiment of the present disclosure, a pattern forming method using the above-described composition is provided.

### BRIEF DESCRIPTION OF THE DRAWINGS

FIG. 1 is a schematic cross-sectional view showing a transfer film according to one embodiment.

FIG. 2 is a schematic cross-sectional view showing a transfer film according to another embodiment.

### DESCRIPTION OF THE PREFERRED EMBODIMENTS

Hereinafter, embodiments of the present disclosure will be described in detail. The present disclosure is not limited to the following embodiments. The following embodiments may be modified as appropriate within the scope of the purposes of the present disclosure.

In a case where the embodiments of the present disclosure are described with reference to the drawings, a dimensional ratio in the drawings does not necessarily represent the actual dimensional ratio.

In the present disclosure, the numerical ranges shown using “to” indicate ranges including the numerical values described before and after “to” as the lower limit value and the upper limit value.

In the numerical range described stepwise in the present disclosure, the upper limit value or the lower limit value described in a certain numerical range may be replaced with the upper limit value or the lower limit value of another numerical range described stepwise. In addition, regarding the numerical range described in the present disclosure, an upper limit value or a lower limit value described in a numerical value may be replaced with a value described in Examples.

In the present disclosure, the term “step” includes not only an independent step but also a step that cannot be clearly distinguished from other steps, as long as the intended purpose of the step is achieved.

In the present disclosure, “transparent” means that an average transmittance of visible light having a wavelength of 400 nm to 700 nm is 80% or more, preferably 90% or more.

In the present disclosure, a transmittance is a value measured by using a spectrophotometer, and for example, can be measured by using a spectrophotometer U-3310 manufactured by Hitachi, Ltd.

In the present disclosure, unless otherwise specified, a weight-average molecular weight (Mw) and a number average molecular weight (Mn) are values obtained by a gel permeation chromatography (GPC) analysis apparatus and converted using polystyrene as a standard substance, with TSKgel GMHxL, TSKgel G4000HxL, or TSKgel G2000HxL (all product names manufactured by Tosoh Corporation) as a column, tetrahydrofuran (THF) as an eluent, and a differential refractometer as a detector.

In the present disclosure, unless otherwise specified, a ratio of constitutional units of a polymer is a mass ratio.

In the present disclosure, unless otherwise specified, a molecular weight of a compound having a molecular weight distribution is the weight-average molecular weight (Mw).

In the present disclosure, unless otherwise specified, a content of metal elements is a value measured by using an inductively coupled plasma (ICP) spectroscopic analysis apparatus.

In the present disclosure, unless otherwise specified, a refractive index is a value measured by using an ellipsometer at a wavelength of 550 nm.

In the present disclosure, unless otherwise specified, a hue is a value measured by using a colorimeter (CR-221, manufactured by Konica Minolta, Inc.).

In the present disclosure, “(meth)acrylic” is a concept including both acrylic and methacrylic, and “(meth)acryloxy group” is a concept including both an acryloxy group and a methacryloxy group.

In the present disclosure, “alkali-soluble” means that the solubility in 100 g of aqueous solution of 1% by mass sodium carbonate at 22° C. is 0.1 g or more.

In the present disclosure, “water-soluble” means that the solubility in 100 g of water with a pH of 7.0 at a liquid temperature of 22° C. is 0.1 g or more.

In the present disclosure, “solid content” means all components excluding a solvent. In addition, a liquid component excluding the solvent is also regarded as the solid content.

In the present disclosure, a combination of two or more preferred aspects is a more preferred aspect.

Composition

Hereinafter, a composition according to embodiments of the present disclosure will be described. Specifically, in the following description, a composition according to a first embodiment and a composition according to a second embodiment will be described in this order.

### Composition According to First Embodiment

In the first embodiment, the composition includes an alkali-soluble resin, a polymerizable compound, a photopolymerization initiator, a surfactant, and a solvent. Further, a surface tension of the composition, which is measured by a Wilhelmy method at 25° C., is 26.5 mN/m or less. According to the above-described embodiment, a composition in which, even in a case where bubbles are generated during development, a time from the generation of bubbles to the disappearance of bubbles is shortened is provided. Hereinafter, details of the composition according to the first embodiment will be described. In the following description, the “composition according to the first embodiment” may be simply referred to as a “composition”.

Surface Tension

The surface tension of the composition, which is measured by a Wilhelmy method at 25° C., is 26.5 mN/m or less. In a case where the surface tension of the composition at 25° C. is 26.5 mN/m or less, even in a case where bubbles are generated during development, a time from the generation of bubbles to the disappearance of bubbles is shortened. That is, a disappearance rate of bubbles is improved. From the viewpoint of improving the disappearance rate of bubbles generated during development, the surface tension of the composition at 25° C. is preferably 26.0 mN/m or less, more preferably 25.7 mN/m or less, and still more preferably 25.4 mN/m or less. From the viewpoint of suppressing the generation of bubbles during development, the surface tension of the composition at 25° C. is preferably 23.0 mN/m or more, more preferably 23.3 mN/m or more, and still more preferably 23.6 mN/m or more. The surface tension of the composition may be adjusted by a known method. Examples of main factors affecting the surface tension of the composition include the type of the surfactant, the content of the surfactant, the type of the solvent, and the content of the solvent. The type of the surfactant may be selected based on a surface tension of a mixture of a surfactant, water, and methanol, which will be described later.

From the viewpoint of improving the disappearance rate of bubbles, a surface tension of a mixture of 1 part by mass of a solid content of the surfactant, 1,000 parts by mass of water, and 2,300 parts by mass of methanol, which is measured by the Wilhelmy method at 25° C., is preferably 20.0 mN/m to 29.0 mN/m, more preferably 22.0 mN/m to 29.0 mN/m, and still more preferably 23.0 mN/m to 26.5 mN/m.

The surface tension is measured by the following method. A 50 mL sample is prepared, and the surface tension is measured three times by the Wilhelmy method in an environment of a temperature of 25° C. and a relative humidity of 60%. In the measurement of the surface tension, a CBVP-A3 type automatic surface tension meter manufactured by Kyowa Interface Science Co., Ltd. is used, and a platinum plate is used as a probe according to the Wilhelmy method. An arithmetic mean value of the measured value is adopted as the surface tension of the object.

Alkali-Soluble Resin

The composition includes an alkali-soluble resin. Examples of the alkali-soluble resin include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and acid anhydride.

From the viewpoint of excellent alkali developability and film formability, examples of one suitable aspect of the alkali-soluble resin include a (meth)acrylic resin. In the present disclosure, the (meth)acrylic resin means a resin having a constitutional unit derived from a (meth)acrylic compound. The content of the constitutional unit derived from a (meth)acrylic compound is preferably 50% by mass or more, more preferably 70% by mass or more, and still more preferably 90% by mass or more with respect to all constitutional units of the (meth)acrylic resin. The (meth)acrylic resin may be composed of only the constitutional unit derived from a (meth)acrylic compound, or may have a constitutional unit derived from a polymerizable monomer other than the (meth)acrylic compound. That is, the upper limit of the content of the constitutional unit derived from a (meth)acrylic compound is 100% by mass or less with respect to all constitutional units of the (meth)acrylic resin.

Examples of the (meth)acrylic compound include (meth)acrylic acid, (meth)acrylic acid ester, (meth)acrylamide, and (meth)acrylonitrile.

Examples of the (meth)acrylic acid ester include (meth)acrylic acid alkyl ester, (meth)acrylic acid tetrahydrofurfuryl ester, (meth)acrylic acid dimethylaminoethyl ester, (meth)acrylic acid diethylaminoethyl ester, (meth)acrylic acid glycidyl ester, (meth)acrylic acid benzyl ester, 2,2,2-trifluoroethyl (meth)acrylate, and 2,2,3,3-tetrafluoropropyl (meth)acrylate, and (meth)acrylic acid alkyl ester is preferable.

Examples of the (meth)acrylamide include acrylamides such as diacetone acrylamide.

An alkyl group of the (meth)acrylic alkyl ester may be linear or branched. Specific examples of the (meth)acrylic acid alkyl ester include (meth)acrylic acid alkyl esters having an alkyl group having 1 to 12 carbon atoms, such as methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate. As the (meth)acrylic acid ester, (meth)acrylic acid alkyl ester having an alkyl group having 1 to 4 carbon atoms is preferable, and methyl (meth)acrylate or ethyl (meth)acrylate is more preferable.

The (meth)acrylic resin may have a constitutional unit other than the constitutional unit derived from a (meth)acrylic compound. The polymerizable monomer forming the above-described constitutional unit is not particularly limited as long as it is a compound other than the (meth)acrylic compound, which can be copolymerized with the (meth)acrylic compound, and examples thereof include styrene compounds which may have a substituent at an α-position or an aromatic ring, such as styrene, vinyltoluene, and α-methylstyrene, vinyl alcohol esters such as acrylonitrile and vinyl-n-butyl ether, maleic acid monoesters such as maleic acid, maleic acid anhydride, monomethyl maleate, monoethyl maleate, and monoisopropyl maleate, fumaric acid, cinnamic acid, α-cyanocinnamic acid, itaconic acid, and crotonic acid. These polymerizable monomers may be used alone or in combination of two or more kinds thereof.

In addition, from the viewpoint of improving alkali developability, the (meth)acrylic resin preferably has a constitutional unit having an acid group. Examples of the acid group include a carboxy group, a sulfo group, a phosphoric acid group, and a phosphonic acid group. The (meth)acrylic resin more preferably has a constitutional unit having a carboxy group, and still more preferably has a constitutional unit derived from the above-described (meth)acrylic acid.

From the viewpoint of excellent developability, the content of the constitutional unit having an acid group (preferably, the constitutional unit derived from (meth)acrylic acid) in the (meth)acrylic resin is preferably 10% by mass or more with respect to the total mass of the (meth)acrylic resin. In addition, the upper limit value thereof is not particularly limited, but from the viewpoint of excellent alkali resistance, is preferably 50% by mass or less and more preferably 40% by mass or less.

It is more preferable that the (meth)acrylic resin has a constitutional unit derived from the above-described (meth)acrylic acid alkyl ester. In a case where the (meth)acrylic resin has a constitutional unit derived from the (meth)acrylic acid alkyl ester, a content of the constitutional unit derived from (meth)acrylic acid alkyl ester in the (meth)acrylic resin is preferably 1% by mass to 90% by mass, more preferably 1% by mass to 50% by mass, and still more preferably 1% by mass to 30% by mass with respect to all constitutional units of the (meth)acrylic resin.

As the (meth)acrylic resin, a resin having both the constitutional unit derived from (meth)acrylic acid and the constitutional unit derived from (meth)acrylic acid alkyl ester is preferable, and a resin composed only of the constitutional unit derived from (meth)acrylic acid and the constitutional unit derived from (meth)acrylic acid alkyl ester is more preferable.

As the (meth)acrylic resin, an acrylic resin which has a constitutional unit derived from methacrylic acid, a constitutional unit derived from methyl methacrylate, and a constitutional unit derived from ethyl acrylate is also preferable.

From the viewpoint that the effects of the present disclosure are more excellent, the (meth)acrylic resin preferably has at least one selected from the group consisting of a constitutional unit derived from methacrylic acid and a constitutional unit derived from methacrylic acid alkyl ester, and preferably has both the constitutional unit derived from methacrylic acid and the constitutional unit derived from methacrylic acid alkyl ester. From the viewpoint that the effects of the present disclosure are more excellent, the total content of the constitutional unit derived from methacrylic acid and the constitutional unit derived from methacrylic acid alkyl ester in the (meth)acrylic resin is preferably 40% by mass or more and more preferably 60% by mass or more with respect to all constitutional units of the (meth)acrylic resin. The upper limit is not particularly limited, and may be 100% by mass or less, preferably 80% by mass or less.

From the viewpoint that the effects of the present disclosure are more excellent, it is also preferable that the (meth)acrylic resin has at least one selected from the group consisting of a constitutional unit derived from methacrylic acid and a constitutional unit derived from methacrylic acid alkyl ester, and has at least one selected from the group consisting of a constitutional unit derived from acrylic acid and a constitutional unit derived from acrylic acid alkyl ester. From the viewpoint that the effects of the present disclosure are more excellent, the total content of the constitutional unit derived from methacrylic acid and the constitutional unit derived from methacrylic acid alkyl ester is preferably 60/40 to 80/20 in terms of mass ratio with respect to the total content of the constitutional unit derived from acrylic acid and the constitutional unit derived from acrylic acid alkyl ester.

From the viewpoint of excellent developability of a photosensitive layer formed of the composition, the (meth)acrylic resin preferably has an ester group at the terminal. The terminal portion of the (meth)acrylic resin is composed of a site derived from a polymerization initiator used in the synthesis. The (meth)acrylic resin having an ester group at the terminal can be synthesized by using a polymerization initiator which generates a radical having an ester group.

From the viewpoint of developability, the alkali-soluble resin is preferably a resin having an acid value of 60 mgKOH/g or more. In addition, from the viewpoint that it is easy to form a strong film by thermally crosslinking with a crosslinking component by heating, for example, the alkali-soluble resin is more preferably a resin (so-called a carboxy group-containing resin) having an acid value of 60 mgKOH/g or more and having a carboxy group, and still more preferably a (meth)acrylic resin (so-called a carboxy group-containing (meth)acrylic resin) having an acid value of 60 mgKOH/g or more and having a carboxy group. In a case where the alkali-soluble resin is a resin having a carboxy group, for example, the three-dimensional crosslinking density can be increased by adding a thermal crosslinking compound such as a blocked isocyanate compound and thermally crosslinking. In addition, in a case where the carboxy group of the resin having a carboxy group is anhydrous and hydrophobized, wet heat resistance can be improved.

The carboxy group-containing (meth)acrylic resin having an acid value of 60 mgKOH/g or more is not particularly limited as long as the above-described conditions of acid value are satisfied, and a known (meth)acrylic resin can be appropriately selected. For example, a carboxy group-containing acrylic resin having an acid value of 60 mgKOH/g or more among polymers described in paragraph [0025] of JP2011-095716A, a carboxy group-containing acrylic resin having an acid value of 60 mgKOH/g or more among polymers described in paragraphs [0033] to [0052] of JP2010-237589A, and the like can be preferably used.

Examples of other suitable aspects of the alkali-soluble resin include a styrene-acrylic copolymer. In the present disclosure, the styrene-acrylic copolymer refers to a resin having a constitutional unit derived from a styrene compound and a constitutional unit derived from a (meth)acrylic compound, and the total content of the constitutional unit derived from a styrene compound and the constitutional unit derived from a (meth)acrylic compound is preferably 30% by mass or more and more preferably 50% by mass or more with respect to all constitutional units of the copolymer. In addition, the content of the constitutional unit derived from a styrene compound is preferably 1% by mass or more, more preferably 5% by mass or more, and still more preferably 5% by mass to 80% by mass with respect to the all constitutional units of the above-described copolymer. In addition, the content of the constitutional unit derived from the above-described (meth)acrylic compound is preferably 5% by mass or more, more preferably 10% by mass or more, and still more preferably 20% by mass to 95% by mass with respect to the all constitutional units of the above-described copolymer.

From the viewpoint that the effects of the present disclosure are more excellent, the alkali-soluble resin preferably has an aromatic ring structure, and more preferably has a constitutional unit having an aromatic ring structure. Examples of a monomer forming the constitutional unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer). A monomer having an aralkyl group or styrene is preferable.

Examples of the aralkyl group include a substituted or unsubstituted phenylalkyl group (excluding a benzyl group), and a substituted or unsubstituted benzyl group, and a substituted or unsubstituted benzyl group is preferable.

Examples of a monomer having the phenylalkyl group include phenylethyl (meth)acrylate.

Examples of a monomer having the benzyl group include (meth)acrylates having a benzyl group, such as benzyl (meth)acrylate and chlorobenzyl (meth)acrylate; and vinyl monomers having a benzyl group, such as vinylbenzyl chloride and vinylbenzyl alcohol. Among these, benzyl (meth)acrylate is preferable.

From the viewpoint that the effects of the present disclosure are more excellent, the alkali-soluble resin more preferably has a constitutional unit represented by Formula (S) (constitutional unit derived from styrene).

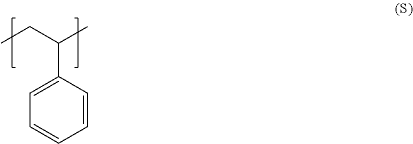

In a case where the alkali-soluble resin has the constitutional unit having an aromatic ring structure, from the viewpoint that the effects of the present disclosure are more excellent, the content of the constitutional unit having an aromatic ring structure is preferably 5% by mass to 90% by mass, more preferably 10% by mass to 70% by mass, and still more preferably 20% by mass to 60% by mass with respect to the all constitutional units of the alkali-soluble resin.

From the viewpoint that the effects of the present disclosure are more excellent, the content of the constitutional unit having an aromatic ring structure in the alkali-soluble resin is preferably 5 mol % to 70 mol %, more preferably 10 mol % to 60 mol %, and still more preferably 20 mol % to 60 mol % with respect to all constitutional units of the alkali-soluble resin.

From the viewpoint that the effects of the present disclosure are more excellent, the content of the constitutional unit represented by Formula (S) in the alkali-soluble resin is preferably 5 mol % to 70 mol %, more preferably 10 mol % to 60 mol %, still more preferably 20 mol % to 60 mol %, and particularly preferably 20 mol % to 50 mol % with respect to all constitutional units of the alkali-soluble resin.

In the present disclosure, in a case where the content of a “constitutional unit” is defined by a molar ratio, the “constitutional unit” is synonymous with the “monomer unit”. In addition, in the present disclosure, the “monomer unit” may be modified after polymerization by a polymer reaction or the like. The same applies to the following.

From the viewpoint that the effects of the present disclosure are more excellent, the alkali-soluble resin preferably has an aliphatic hydrocarbon ring structure. That is, the alkali-soluble resin preferably has a constitutional unit having an aliphatic hydrocarbon ring structure. The aliphatic hydrocarbon ring structure may be monocyclic or polycyclic. Among these, the alkali-soluble resin more preferably has a ring structure in which two or more aliphatic hydrocarbon rings are fused.

Examples of a ring constituting the aliphatic hydrocarbon ring structure in the constitutional unit having an aliphatic hydrocarbon ring structure include a tricyclodecane ring, a cyclohexane ring, a cyclopentane ring, a norbornane ring, and an isophorone ring. Among these, from the viewpoint that the effects of the present disclosure are more excellent, a ring in which two or more aliphatic hydrocarbon rings are fused is preferable, and a tetrahydrodicyclopentadiene ring (tricyclo[5.2.1.0^{2,6}]decane ring) is more preferable.

Examples of a monomer forming the constitutional unit having an aliphatic hydrocarbon ring structure include dicyclopentanyl (meth)acrylate, cyclohexyl (meth)acrylate, and isobornyl (meth)acrylate.

In addition, from the viewpoint that the effects of the present disclosure are more excellent, the alkali-soluble resin more preferably has a constitutional unit represented by Formula (Cy), and still more preferably has the constitutional unit represented by Formula (S) and the constitutional unit represented by Formula (Cy).

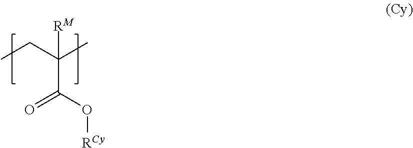

In Formula (Cy), R^{M} represents a hydrogen atom or a methyl group, and R^{Cy} represents a monovalent group having an aliphatic hydrocarbon ring structure.

R^{M} in Formula (Cy) is preferably a methyl group.

From the viewpoint that the effects of the present disclosure are more excellent, R^{Cy} in Formula (Cy) is preferably a monovalent group having an aliphatic hydrocarbon ring structure having 5 to 20 carbon atoms, more preferably a monovalent group having an aliphatic hydrocarbon ring structure having 6 to 16 carbon atoms, and still more preferably a monovalent group having an aliphatic hydrocarbon ring structure having 8 to 14 carbon atoms.

From the viewpoint that the effects of the present disclosure are more excellent, the aliphatic hydrocarbon ring structure in R^{Cy} of Formula (Cy) is preferably a cyclopentane ring structure, a cyclohexane ring structure, a tetrahydrodicyclopentadiene ring structure, a norbornane ring structure, or an isophorone ring structure, more preferably a cyclohexane ring structure or a tetrahydrodicyclopentadiene ring structure, and still more preferably a tetrahydrodicyclopentadiene ring structure.

From the viewpoint that the effects of the present disclosure are more excellent, the aliphatic hydrocarbon ring structure in R^{Cy} of Formula (Cy) is preferably a ring structure in which two or more aliphatic hydrocarbon rings are fused, and more preferably a ring in which two to four aliphatic hydrocarbon rings are fused.

From the viewpoint that the effects of the present disclosure are more excellent, R^{Cy} in Formula (Cy) is preferably a group in which the oxygen atom in —C(═O)O— of Formula (Cy) and the aliphatic hydrocarbon ring structure are directly bonded, that is, an aliphatic hydrocarbon ring group, more preferably a cyclohexyl group or a dicyclopentanyl group, and still more preferably a dicyclopentanyl group.

The alkali-soluble resin may have one constitutional unit having an aliphatic hydrocarbon ring structure alone, or two or more kinds thereof.

In a case where the alkali-soluble resin has the constitutional unit having an aliphatic hydrocarbon ring structure, from the viewpoint that the effects of the present disclosure are more excellent, the content of the constitutional unit having an aliphatic hydrocarbon ring structure is preferably 5% by mass to 90% by mass, more preferably 10% to 80% by mass, and still more preferably 20% by mass to 70% by mass with respect to the all constitutional units of the alkali-soluble resin.

From the viewpoint that the effects of the present disclosure are more excellent, the content of the constitutional unit having an aliphatic hydrocarbon ring structure in the alkali-soluble resin is preferably 5 mol % to 70 mol %, more preferably 10 mol % to 60 mol %, and still more preferably 20 mol % to 50 mol % with respect to all constitutional units of the alkali-soluble resin.

From the viewpoint that the effects of the present disclosure are more excellent, the content of the constitutional unit represented by Formula (Cy) in the alkali-soluble resin is preferably 5 mol % to 70 mol %, more preferably 10 mol % to 60 mol %, and still more preferably 20 mol % to 50 mol % with respect to all constitutional units of the alkali-soluble resin.

In a case where the alkali-soluble resin includes the constitutional unit having an aromatic ring structure and the constitutional unit having an aliphatic hydrocarbon ring structure, from the viewpoint that the effects of the present disclosure are more excellent, the total content of the constitutional unit having an aromatic ring structure and the constitutional unit having an aliphatic hydrocarbon ring structure is preferably 10% by mass to 90% by mass, more preferably 20% by mass to 80% by mass, and particularly preferably 40% by mass to 75% by mass with respect to all constitutional units of the alkali-soluble resin.

From the viewpoint that the effects of the present disclosure are more excellent, the total content of the constitutional unit having an aromatic ring structure and the constitutional unit having an aliphatic hydrocarbon ring structure in the alkali-soluble resin is preferably 10 mol % to 80 mol %, more preferably 20 mol % to 70 mol %, and still more preferably 40 mol % to 60 mol % with respect to all constitutional units of the alkali-soluble resin.

From the viewpoint that the effects of the present disclosure are more excellent, the total content of the constitutional unit represented by Formula (S) and the constitutional unit represented by Formula (Cy) in the alkali-soluble resin is preferably 10 mol % to 80 mol %, more preferably 20 mol % to 70 mol %, and still more preferably 40 mol % to 60 mol % with respect to all constitutional units of the alkali-soluble resin.

From the viewpoint that the effects of the present disclosure are more excellent, a molar amount nS of the constitutional unit represented by Formula (S) and a molar amount nCy of the constitutional unit represented by Formula (Cy) in the alkali-soluble resin preferably satisfy the relationship shown in the following expression (SCy), more preferably satisfy the following expression (SCy-1), and still more preferably satisfy the following expression (SCy-2).

0.2≤nS/(nS+nCy)≤0.8: Expression (SCy)

0.30≤nS/(nS+nCy)≤0.75: Expression (SCy-1)

0.40≤nS/(nS+nCy)≤0.70: Expression (SCy-2)

From the viewpoint that the effects of the present disclosure are more excellent, the alkali-soluble resin preferably has a constitutional unit having an acid group. Examples of the acid group include a carboxy group, a sulfo group, a phosphonic acid group, and a phosphoric acid group, and a carboxy group is preferable. As the constitutional unit having an acid group, constitutional units derived from (meth)acrylic acid, which are shown below, is preferable, and a constitutional unit derived from methacrylic acid is more preferable.

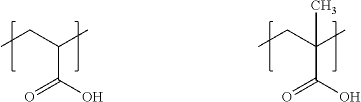

The alkali-soluble resin may have one constitutional unit having an acid group alone, or two or more kinds thereof.

In a case where the alkali-soluble resin has the constitutional unit having an acid group, from the viewpoint that the effects of the present disclosure are more excellent, the content of the constitutional unit having an acid group is preferably 5% by mass to 50% by mass, more preferably 5% by mass to 40% by mass, and still more preferably 10% by mass to 30% by mass with respect to the all constitutional units of the alkali-soluble resin.

From the viewpoint that the effects of the present disclosure are more excellent, the content of the constitutional unit having an acid group in the alkali-soluble resin is preferably 5 mol % to 70 mol %, more preferably 10 mol % to 50 mol %, and still more preferably 20 mol % to 40 mol % with respect to all constitutional units of the alkali-soluble resin.

From the viewpoint that the effects of the present disclosure are more excellent, the content of the constitutional unit derived from (meth)acrylic acid in the alkali-soluble resin is preferably 5 mol % to 70 mol %, more preferably 10 mol % to 50 mol %, and still more preferably 20 mol % to 40 mol % with respect to all constitutional units of the alkali-soluble resin.

From the viewpoint that the effects of the present disclosure are more excellent, the alkali-soluble resin preferably has a reactive group, and more preferably has a constitutional unit having a reactive group. As the reactive group, a radically polymerizable group is preferable, and an ethylenically unsaturated group is more preferable. In addition, in a case where the alkali-soluble resin has an ethylenically unsaturated group, the alkali-soluble resin preferably has a constitutional unit having an ethylenically unsaturated group in a side chain. In the present disclosure, the “main chain” represents a relatively longest binding chain in a molecule of a polymer compound constituting a resin, and the “side chain” represents an atomic group branched from the main chain. As the ethylenically unsaturated group, an allyl group or a (meth)acryloxy group is more preferable. Examples of the constitutional unit having a reactive group include those shown below, but the constitutional unit having a reactive group is not limited thereto.

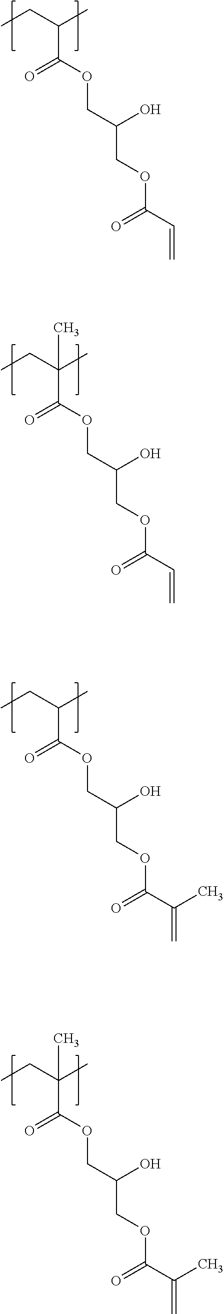

The alkali-soluble resin may have one constitutional unit having a reactive group alone, or two or more kinds thereof.

In a case where the alkali-soluble resin has the constitutional unit having a reactive group, from the viewpoint that the effects of the present disclosure are more excellent, the content of the constitutional unit having a reactive group is preferably 5% by mass to 70% by mass, more preferably 10% by mass to 50% by mass, and still more preferably 20% by mass to 40% by mass with respect to the all constitutional units of the alkali-soluble resin.

From the viewpoint that the effects of the present disclosure are more excellent, the content of the constitutional unit having a reactive group in the alkali-soluble resin is preferably 5 mol % to 70 mol %, more preferably 10 mol % to 60 mol %, and still more preferably 20 mol % to 50 mol % with respect to all constitutional units of the alkali-soluble resin.

Examples of a method for introducing the reactive group into the alkali-soluble resin include a method of reacting a compound such as an epoxy compound, a blocked isocyanate compound, an isocyanate compound, a vinyl sulfone compound, an aldehyde compound, a methylol compound, and a carboxylic acid anhydride with a functional group such as a hydroxy group, a carboxy group, a primary amino group, a secondary amino group, an acetoacetyl group, and a sulfo group.

Preferred examples of the method for introducing the reactive group into the alkali-soluble resin include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a alkali-soluble resin having a (meth)acryloxy group in the side chain can be obtained. The polymerization reaction is preferably carried out under a temperature condition of 70° C. to 100° C., and more preferably carried out under a temperature condition of 80° C. to 90° C. As a polymerization initiator used in the polymerization reaction, an azo-based initiator is preferable, and for example, V-601 (product name) or V-65 (product name) manufactured by FUJIFILM Wako Pure Chemical Corporation is more preferable. The polymer reaction is preferably carried out under a temperature condition of 80° C. to 110° C. In the polymer reaction, it is preferable to use a catalyst such as an ammonium salt.

As the alkali-soluble resin, from the viewpoint that the effects of the present disclosure are more excellent, polymers shown below are more preferable. Content ratios (a to d) and weight-average molecular weights Mw of each of the constitutional units shown below can be appropriately changed according to the purpose.

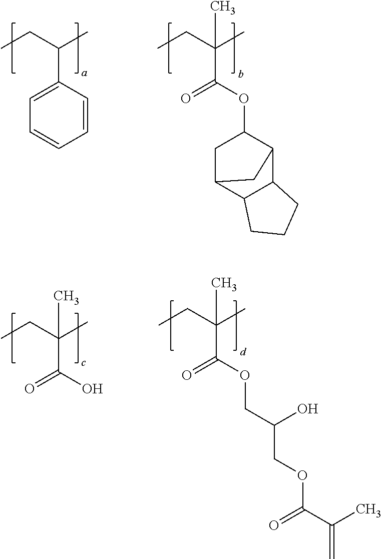

Preferred values for the content ratio of the above-described constitutional units are shown below.
a: 20% by mass to 60% by mass
b: 10% by mass to 50% by mass
c: 5.0% by mass to 25% by mass
d: 10% by mass to 50% by mass

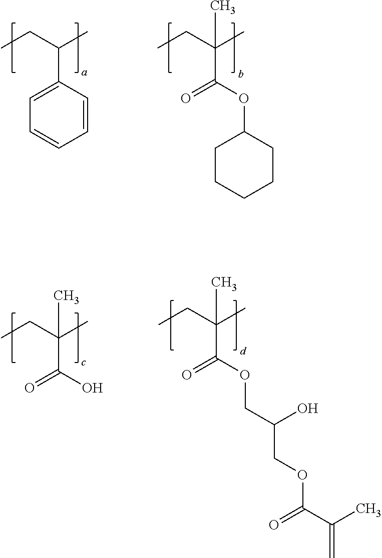

Preferred values for the content ratio of the above-described constitutional units are shown below.
a: 20% by mass to 60% by mass
b: 10% by mass to 50% by mass
c: 5.0% by mass to 25% by mass
d: 10% by mass to 50% by mass

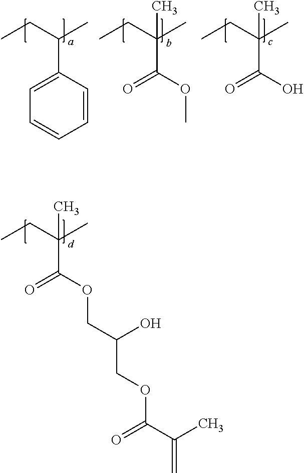

Preferred values for the content ratio of the above-described constitutional units are shown below.
a: 30% by mass to 65% by mass
b: 1.0% by mass to 20% by mass
c: 5.0% by mass to 25% by mass
d: 10% by mass to 50% by mass

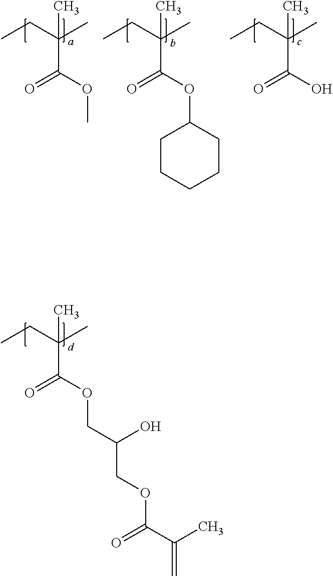

Preferred values for the content ratio of the above-described constitutional units are shown below.
a: 1.0% by mass to 20% by mass
b: 20% by mass to 60% by mass
c: 5.0% by mass to 25% by mass
d: 10% by mass to 50% by mass

The alkali-soluble resin may include a polymer (hereinafter, also referred to as a “polymer X”) having a constitutional unit having a carboxylic acid anhydride structure. The carboxylic acid anhydride structure may be either a chain carboxylic acid anhydride structure or a cyclic carboxylic acid anhydride structure, and a cyclic carboxylic acid anhydride structure is preferable. The ring of the cyclic carboxylic acid anhydride structure is preferably a 5- to 7-membered ring, more preferably a 5-membered ring or a 6-membered ring, and still more preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

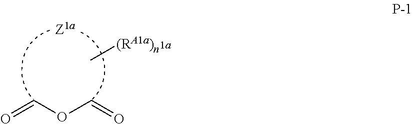

In Formula P-1, R^{A1a} represents a substituent, n^{1a} pieces of R^{A1a}'s may be the same or different, Zia represents a divalent group forming a ring including —C(═O)—O—C(═O)—, and n^{1a} represents an integer of 0 or more.

Examples of the substituent represented by R^{A1a} include an alkyl group.

Zia is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Zia represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

As the constitutional unit having a carboxylic acid anhydride structure, a constitutional unit derived from an unsaturated carboxylic acid anhydride is preferable, a constitutional unit derived from an unsaturated cyclic carboxylic acid anhydride is more preferable, a constitutional unit derived from an unsaturated aliphatic carboxylic acid anhydride is still more preferable, a constitutional unit derived from maleic anhydride or itaconic anhydride is particularly preferable, and a constitutional unit derived from maleic acid anhydride is most preferable.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

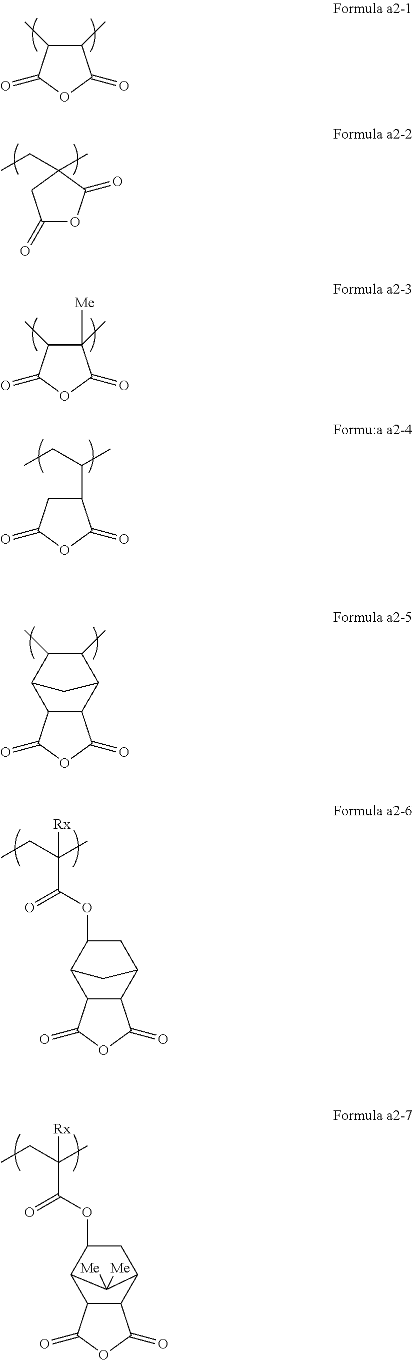

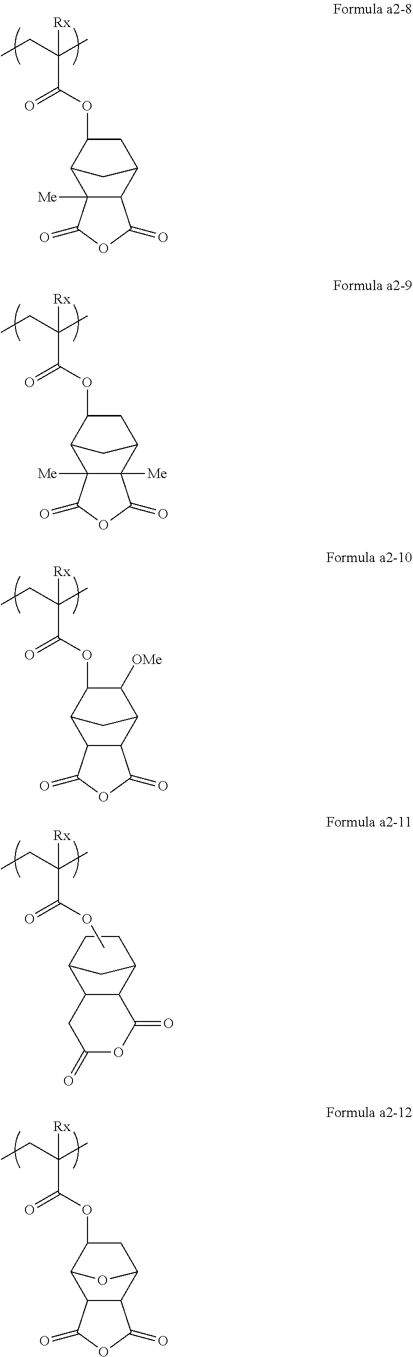

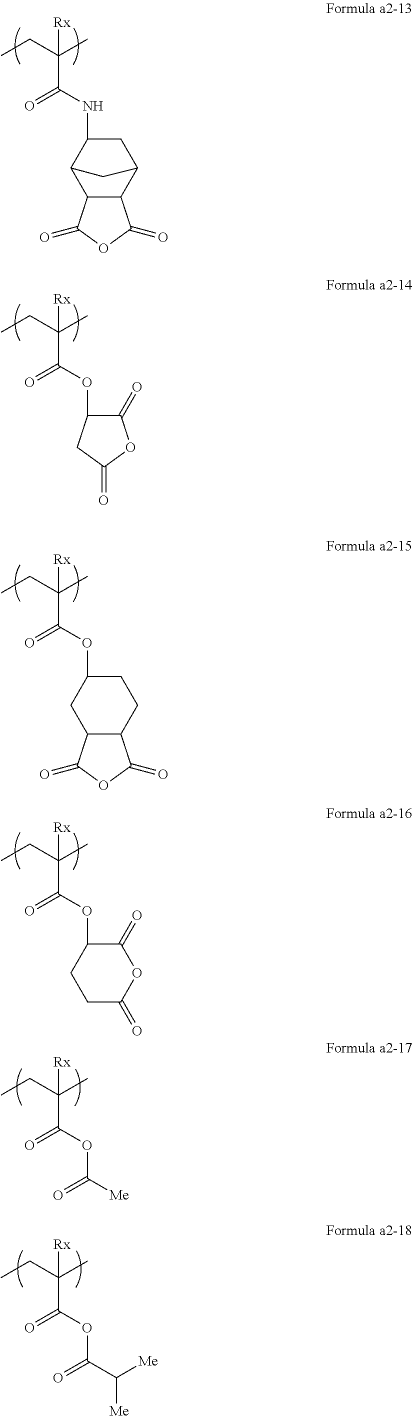

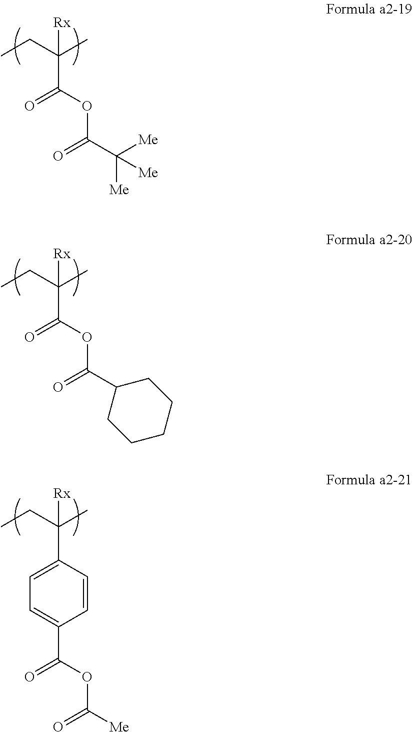

The polymer X may have one constitutional unit having a carboxylic acid anhydride structure alone, or two or more kinds thereof.

The total content of the constitutional unit having a carboxylic acid anhydride structure is preferably 0 mol % to 60 mol %, more preferably 5 mol % to 40 mol %, and still more preferably 10 mol % to 35 mol % with respect to all constitutional units of the polymer X.

The composition may include only one kind of the polymer X, or may include two or more kinds thereof.

In a case where the composition includes the polymer X, from the viewpoint that the effects of the present disclosure are more excellent, the content of the polymer X is preferably 0.1% by mass to 30% by mass, more preferably 0.2% by mass to 20% by mass, still more preferably 0.5% by mass to 20% by mass, and particularly preferably 1% by mass to 20% by mass with respect to the total mass of the solid content of the composition.

From the viewpoint that the effects of the present disclosure are more excellent, a weight-average molecular weight (Mw) of the alkali-soluble resin is preferably 5,000 or more, more preferably 10,000 or more, still more preferably 10,000 to 50,000, and particularly preferably 15,000 to 30,000.

An acid value of the alkali-soluble resin is preferably 10 mgKOH/g to 200 mgKOH/g, more preferably 60 mgKOH/g to 200 mgKOH/g, still more preferably 60 mgKOH/g to 150 mgKOH/g, and particularly preferably 70 mgKOH/g to 130 mgKOH/g. The acid value of the alkali-soluble resin is a value measured according to the method described in JIS K0070: 1992.

From the viewpoint of developability, a dispersity of the alkali-soluble resin is preferably 1.0 to 6.0, more preferably 1.0 to 5.0, still more preferably 1.0 to 4.0, and particularly preferably 1.0 to 3.0.

The composition may include only one kind of the alkali-soluble resin, or may include two or more kinds thereof.

From the viewpoint that the effects of the present disclosure are more excellent, a content of the alkali-soluble resin is preferably 10% by mass to 90% by mass, more preferably 20% by mass to 80% by mass, and still more preferably 30% by mass to 70% by mass with respect to the total mass of the solid content of the composition.

Polymerizable Compound

The composition includes a polymerizable compound. The polymerizable compound is a compound having a polymerizable group. Examples of the polymerizable group include a radically polymerizable group and a cationically polymerizable group, and a radically polymerizable group is preferable.

The polymerizable compound preferably includes a radically polymerizable compound having an ethylenically unsaturated group (hereinafter, also simply referred to as an “ethylenically unsaturated compound”). As the ethylenically unsaturated group, a (meth)acryloxy group is preferable. The ethylenically unsaturated compound in the present disclosure is a compound other than the above-described alkali-soluble resin, and preferably has a molecular weight of less than 5,000.

Examples of one suitable aspect of the polymerizable compound include a compound represented by Formula (M) (simply referred to as a “compound M”).

Q²-R¹-Q¹: Formula (M)

In Formula (M), Q¹ and Q² each independently represent a (meth)acryloyloxy group, and R¹ represents a divalent linking group having a chain structure.

From the viewpoint of easiness of synthesis, Q¹ and Q² in Formula (M) preferably have the same group. In addition, from the viewpoint of reactivity, Q¹ and Q² in Formula (M) are preferably acryloyloxy groups.

From the viewpoint that the effects of the present disclosure are more excellent, R¹ in Formula (M) is preferably an alkylene group, an alkyleneoxyalkylene group (-L¹-O-L¹-), or a polyalkyleneoxyalkylene group (-(L¹-O)ₚ-L¹-), more preferably a hydrocarbon group having 2 to 20 carbon atoms or a polyalkyleneoxyalkylene group, still more preferably an alkylene group having 4 to 20 carbon atoms, and particularly preferably a linear alkylene group having 6 to 18 carbon atoms. It is sufficient that the hydrocarbon group has a chain structure at least in part, and a portion other than the chain structure is not particularly limited. For example, the portion may be a branched chain, a cyclic or a linear alkylene group having 1 to 5 carbon atoms, an arylene group, an ether bond, or a combination thereof, and an alkylene group or a group in which two or more alkylene groups and one or more arylene groups are combined is preferable, an alkylene group is more preferable, and a linear alkylene group is still more preferable. L¹'s each independently represent an alkylene group, and an ethylene group, a propylene group, or a butylene group is preferable and an ethylene group or a 1,2-propylene group is more preferable. p represents an integer of 2 or more, and is preferably an integer of 2 to 10.

From the viewpoint that the effects of the present disclosure are more excellent, the number of atoms in the shortest linking chain which links Q¹ and Q² in the compound M is preferably 3 to 50, more preferably 4 to 40, still more preferably 6 to 20, and particularly preferably 8 to 12. In the present disclosure, the “number of atoms in the shortest linking chain which links Q¹ and Q²” is the shortest number of atoms linking from an atom in R¹ linked to Q¹ to an atom in R¹ linked to Q².

Specific examples of the compound M include 1,3-butanediol di(meth)acrylate, tetramethylene glycol di(meth)acrylate, neopentyl glycol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, hydrogenated bisphenol A di(meth)acrylate, hydrogenated bisphenol F di(meth)acrylate, polyethylene glycol di(meth)acrylate, polypropylene glycol di(meth)acrylate, poly (ethylene glycol/propylene glycol) di(meth)acrylate, and polybutylene glycol di(meth)acrylate. The above-described ester monomers can also be used as a mixture. Among the above-described compounds, from the viewpoint that the effects of the present disclosure are more excellent, at least one compound selected from the group consisting of 1,6-hexanediol di(meth)acrylate, 1,9-nonanediol di(meth)acrylate, 1,10-decanediol di(meth)acrylate, and neopentyl glycol di(meth)acrylate is preferable, at least one compound selected from the group consisting of 1,6-hexanediol di(meth)acrylate, 1,9-nonanediol di(meth)acrylate, and 1,10-decanediol di(meth)acrylate is more preferable, and at least one compound selected from the group consisting of 1,9-nonanediol di(meth)acrylate and 1,10-decanediol di(meth)acrylate is still more preferable.

In addition, examples of one suitable aspect of the polymerizable compound include a bi- or higher functional ethylenically unsaturated compound. In the present disclosure, the “bi- or higher functional ethylenically unsaturated compound” means a compound having two or more ethylenically unsaturated groups in one molecule. As the ethylenically unsaturated group in the ethylenically unsaturated compound, a (meth)acryloyl group is preferable. As the ethylenically unsaturated compound, a (meth)acrylate compound is preferable.

The bifunctional ethylenically unsaturated compound is not particularly limited and can be appropriately selected from a known compound. Examples of the bifunctional ethylenically unsaturated compound other than the above-described compound M include tricyclodecane dimethanol di(meth)acrylate, dioxane glycol di(meth)acrylate, and 1,4-cyclohexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,9-nonanediol diacrylate (product name: NK ESTER A-NOD-N, manufactured by Shin-Nakamura Chemical Co., Ltd.), 1,6-hexanediol diacrylate (product name: NK ESTER A-HD-N, manufactured by Shin-Nakamura Chemical Co., Ltd.), and dioxane glycol diacrylate (KAYARAD R-604 manufactured by Nippon Kayaku Co., Ltd.).

The tri- or higher functional ethylenically unsaturated compound is not particularly limited and can be appropriately selected from a known compound. Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton. In the present disclosure, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (NK ESTER A-GLY-9E manufactured by Shin-Nakamura Chemical Co., Ltd., or the like).

Examples of the polymerizable compound also include a urethane (meth)acrylate compound. Examples of the urethane (meth)acrylate include urethane di(meth)acrylate, and examples thereof include propylene oxide-modified urethane di(meth)acrylate and ethylene oxide and propylene oxide-modified urethane di(meth)acrylate. In addition, examples of the urethane (meth)acrylate also include tri- or higher functional urethane (meth)acrylate. The lower limit of the number of functional groups is more preferably 6 or more and still more preferably 8 or more. The upper limit of the number of functional groups is preferably 20 or less. Examples of the tri- or higher functional urethane (meth)acrylate include 8UX-015A (manufactured by Taisei Fine Chemical Co., Ltd.), UA-32P (manufactured by Shin-Nakamura Chemical Co., Ltd.), U-15HA (manufactured by Shin-Nakamura Chemical Co., Ltd.), UA-1100H (manufactured by Shin-Nakamura Chemical Co., Ltd.), AH-600 (product name) manufactured by KYOEISHA CHEMICAL Co., LTD, UA-306H, UA-306T, UA-306I, UA-510H, and UX-5000 (all manufactured by Nippon Kayaku Co., Ltd.).

Examples of one suitable aspect of the polymerizable compound include an ethylenically unsaturated compound having an acid group. Examples of the acid group include a phosphoric acid group, a sulfo group, and a carboxy group. Among these, as the acid group, a carboxy group is preferable.

Examples of the ethylenically unsaturated compound having an acid group include a tri- or tetra-functional ethylenically unsaturated compound having an acid group [compound obtained by introducing a carboxy group to pentaerythritol tri- and tetra-acrylate (PETA) skeleton (acid value: 80 to 120 mgKOH/g)), and a penta- to hexa-functional ethylenically unsaturated compound having an acid group [compound obtained by introducing a carboxy group to dipentaerythritol penta- and hexa-acrylate (DPHA) skeleton (acid value: 25 to 70 mgKOH/g)]. The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable. In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced. The bi- or higher functional ethylenically unsaturated compound having a carboxy group is not particularly limited and can be appropriately selected from a known compound. Examples of the bi- or higher functional ethylenically unsaturated compound having a carboxy group include ARONIX (registered trademark) TO-2349 manufactured by Toagosei Co., Ltd., ARONIX (registered trademark) M-520 manufactured by Toagosei Co., Ltd., and ARONIX (registered trademark) M-510 manufactured by Toagosei Co., Ltd.

As the ethylenically unsaturated compound having an acid group, polymerizable compounds having an acid group, which are described in paragraphs [0025] to [0030] of JP2004-239942A, are preferable, and the contents described in this publication are incorporated in the present specification.

Examples of the polymerizable compound also include a compound obtained by reacting a polyhydric alcohol with an α,β-unsaturated carboxylic acid, a compound obtained by reacting a glycidyl group-containing compound with an α,β-unsaturated carboxylic acid, urethane monomer such as a (meth)acrylate compound having a urethane bond, phthalate compounds such as γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate, and (meth)acrylic acid alkyl esters. These compounds may be used alone or in combination of two or more kinds thereof.

Examples of the compound obtained by reacting a polyhydric alcohol with an α,β-unsaturated carboxylic acid include bisphenol A-based (meth)acrylate compounds such as 2,2-bis(4-((meth)acryloxypolyethoxy)phenyl)propane, 2,2-bis(4-((meth)acryloxypolypropoxy)phenyl)propane, and 2,2-bis(4-((meth)acryloxypolyethoxypolypropoxy)phenyl)propane, polyethylene glycol di(meth)acrylate having 2 to 14 ethylene oxide groups, polypropylene glycol di(meth)acrylate having 2 to 14 propylene oxide groups, polyethylene polypropylene glycol di(meth)acrylate having 2 to 14 ethylene oxide groups and 2 to 14 propylene oxide groups, trimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylolpropane pentaethoxy tri(meth)acrylate, di(trimethylolpropane) tetraacrylate, tetramethylolmethane tri(meth)acrylate, tetramethylolmethane tetra(meth)acrylate, dipentaerythritol tetra(meth)acrylate, dipentaerythritol penta(meth)acrylate, and dipentaerythritol hexa(meth)acrylate. Among these, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

Examples of the polymerizable compound also include a caprolactone-modified compound of ethylenically unsaturated compound (for example, KAYARAD (registered trademark) DPCA-20 manufactured by Nippon Kayaku Co., Ltd., A-9300-1CL manufactured by Shin-Nakamura Chemical Co., Ltd., and the like), an alkylene oxide-modified compound of ethylenically unsaturated compound (for example, KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., and the like), and ethoxylated glycerin triacrylate (A-GLY-9E manufactured by Shin-Nakamura Chemical Co., Ltd., and the like).

Among these, as the polymerizable compound (particularly, the ethylenically unsaturated compound), from the viewpoint of excellent developability of the photosensitive layer formed of the composition, a polymerizable compound including an ester bond is also preferable. The ethylenically unsaturated compound including an ester bond is not particularly limited as long as it includes an ester bond in the molecule, but from the viewpoint that the effects of the present disclosure are excellent, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

As the ethylenically unsaturated compound, from the viewpoint of imparting reliability, it is preferable to include an ethylenically unsaturated compound having an aliphatic group having 6 to 20 carbon atoms and the ethylenically unsaturated compound having a tetramethylolmethane structure or a trimethylolpropane structure. Examples of the ethylenically unsaturated compound having an aliphatic group having 6 to 20 carbon atoms include 1,9-nonanediol di(meth)acrylate, 1,10-decanediol di(meth)acrylate, and tricyclodecane dimethanol di(meth)acrylate.

Examples of one suitable aspect of the polymerizable compound include a polymerizable compound (preferably, a bifunctional ethylenically unsaturated compound) having an aliphatic hydrocarbon ring structure. As the above-described polymerizable compound, a polymerizable compound having a ring structure in which two or more aliphatic hydrocarbon rings are fused (preferably, a structure selected from the group consisting of a tricyclodecane structure and a tricyclodecene structure) is preferable, a bifunctional ethylenically unsaturated compound having a ring structure in which two or more aliphatic hydrocarbon rings are fused is more preferable, and tricyclodecane dimethanol di(meth)acrylate is still more preferable. As the aliphatic hydrocarbon ring structure, from the viewpoint that the effects of the present disclosure are more excellent, a cyclopentane structure, a cyclohexane structure, a tricyclodecane structure, a tricyclodecene structure, a norbornane structure, or an isophorone structure is preferable.

A molecular weight of the polymerizable compound is preferably 200 to 3,000, more preferably 250 to 2,600, still more preferably 280 to 2,200, and particularly preferably 300 to 2,200.

A proportion of a content of a polymerizable compound having a molecular weight of 300 or less in the polymerizable compounds included in the composition is preferably 30% by mass or less, more preferably 25% by mass or less, and still more preferably 20% by mass or less with respect to the content of all the polymerizable compounds included in the composition.

As one suitable aspect of the composition, the composition preferably includes the bi- or higher functional ethylenically unsaturated compound, more preferably includes the tri- or higher functional ethylenically unsaturated compound, and still more preferably includes a tri- or tetrafunctional ethylenically unsaturated compound.

In addition, as one suitable aspect of the composition, the composition preferably includes the bifunctional ethylenically unsaturated compound having an aliphatic hydrocarbon ring structure and the alkali-soluble resin having the constitutional unit having an aliphatic hydrocarbon ring.

In addition, as one suitable aspect of the composition, the composition preferably includes the compound represented by Formula (M) and the ethylenically unsaturated compound having an acid group, more preferably includes 1,9-nonanediol diacrylate, tricyclodecane dimethanol diacrylate, and a polyfunctional ethylenically unsaturated compound having a carboxylic acid group, and still more preferably includes 1,9-nonanediol diacrylate, tricyclodecane dimethanol diacrylate, and a succinic acid-modified form of dipentaerythritol pentaacrylate.

In addition, as one suitable aspect of the composition, the composition preferably includes the compound represented by Formula (M), the ethylenically unsaturated compound having an acid group, and a thermal crosslinking compound described later, and more preferably includes the compound represented by Formula (M), the ethylenically unsaturated compound having an acid group, and a blocked isocyanate compound described later.

In addition, as one suitable aspect of the composition, from the viewpoint of development residue inhibitory property and rust preventive property, the composition preferably includes the bifunctional ethylenically unsaturated compound (preferably, a bifunctional (meth)acrylate compound) and the tri- or higher functional ethylenically unsaturated compound (preferably, a tri- or higher functional (meth)acrylate compound).

A mass ratio of a content of the bifunctional ethylenically unsaturated compound and a content of the tri- or higher functional ethylenically unsaturated compound is preferably 10:90 to 90:10 and more preferably 30:70 to 70:30.

The content of the bifunctional ethylenically unsaturated compound is preferably 20% by mass to 80% by mass and more preferably 30% by mass to 70% by mass with respect to the total amount of all ethylenically unsaturated compounds.

The bifunctional ethylenically unsaturated compound in the total mass of the solid content of the composition is preferably 10% by mass to 60% by mass and more preferably 15% by mass to 40% by mass.

In addition, as one suitable aspect of the composition, from the viewpoint of rust preventive property, the composition preferably includes the compound M and the bifunctional ethylenically unsaturated compound having an aliphatic hydrocarbon ring structure.

In addition, as one suitable aspect of the composition, from the viewpoint of substrate adhesiveness, development residue inhibitory property, and rust preventive property, the composition preferably includes the compound M and the ethylenically unsaturated compound having an acid group, more preferably includes the compound M, the bifunctional ethylenically unsaturated compound having an aliphatic hydrocarbon ring structure, and the ethylenically unsaturated compound having an acid group, still more preferably includes the compound M, the bifunctional ethylenically unsaturated compound having an aliphatic hydrocarbon ring structure, the tri- or higher functional ethylenically unsaturated compound, and the ethylenically unsaturated compound having an acid group, and particularly preferably includes the compound M, the bifunctional ethylenically unsaturated compound having an aliphatic hydrocarbon ring structure, the tri- or higher functional ethylenically unsaturated compound, the ethylenically unsaturated compound having an acid group, and the urethane (meth)acrylate compound.

In addition, as one suitable aspect of the composition, from the viewpoint of substrate adhesiveness, development residue inhibitory property, and rust preventive property, the composition preferably includes 1,9-nonanediol diacrylate and the polyfunctional ethylenically unsaturated compound having a carboxylic acid group, more preferably includes 1,9-nonanediol diacrylate, tricyclodecane dimethanol diacrylate, and the polyfunctional ethylenically unsaturated compound having a carboxylic acid group, still more preferably includes 1,9-nonanediol diacrylate, tricyclodecane dimethanol diacrylate, dipentaerythritol hexaacrylate, and an ethylenically unsaturated compound having a carboxylic acid group, and particularly preferably includes 1,9-nonanediol diacrylate, tricyclodecane dimethanol diacrylate, an ethylenically unsaturated compound having a carboxylic acid group, and a urethane acrylate compound.

The composition may include a monofunctional ethylenically unsaturated compound as the ethylenically unsaturated compound.

The content of the bi- or higher functional ethylenically unsaturated compound in the above-described ethylenically unsaturated compound is preferably 60% by mass to 100% by mass, more preferably 80% by mass to 100% by mass, and still more preferably 90% by mass to 100% by mass with respect to the total content of all ethylenically unsaturated compounds included in the composition.

The polymerizable compound (particularly, the ethylenically unsaturated compound) may be used alone or in combination of two or more kinds thereof.

A content of the polymerizable compound (particularly, the ethylenically unsaturated compound) in the composition is preferably 1% by mass to 70% by mass, more preferably 5% by mass to 70% by mass, still more preferably 5% by mass to 60% by mass, and particularly preferably 5% by mass to 50% by mass with respect to the total mass of the solid content of the composition.

Photopolymerization Initiator

The composition includes a photopolymerization initiator. The photopolymerization initiator is not particularly limited and a known photopolymerization initiator can be used. The photopolymerization initiator may be a photoradical polymerization initiator.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators described in paragraphs [0031] to [0042] of JP2011-95716A and paragraphs [0064] to [0081] of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], IRGACURE (registered trademark) OXE-03 (manufactured by BASF SE), IRGACURE (registered trademark) OXE-04 (manufactured by BASF SE), 2-(dimethylamino)-2-[4-methylphenyl)methyl]-1-[4-(4-morpholinyl)phenyl]-1-butanone [product name: Omnirad (registered trademark) 379EG, manufactured by IGM Resins B.V.], 2-methyl-1-(4-methylthiophenyl)-2-morpholinopropan-1-one [product name: Omnirad (registered trademark) 907, manufactured by IGM Resins B.V.], 2-hydroxy-1-{4-[4-(2-hydroxy-2-methylpropionyl)benzyl]phenyl}-2-methylpropan-1-one [product name: Omnirad (registered trademark) 127, manufactured by IGM Resins B.V.], 2-benzyl-2-dimethylamino-1-(4-morpholinophenyl)butanone-1 [product name: Omnirad (registered trademark) 369, manufactured by IGM Resins B.V.], 2-hydroxy-2-methyl-1-phenylpropan-1-one [product name: Omnirad (registered trademark) 1173, manufactured by IGM Resins B.V.], 1-hydroxy cyclohexyl phenyl ketone [product name: Omnirad (registered trademark) 184, manufactured by IGM Resins B.V.], 2,2-dimethoxy-1,2-diphenylethan-1-one (product name: Omnirad (registered trademark) 651, manufactured by IGM Resins B.V.], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY), and APi-307 (1-(biphenyl-4-yl)-2-methyl-2-morpholinopropan-1-one, manufactured by Shenzhen UV-ChemTech Co., Ltd.).

The photopolymerization initiator may be used alone or in combination of two or more kinds thereof. In a case of using two or more kinds of photopolymerization initiators, it is preferable to use at least one selected from the oxime-based photopolymerization initiator, the α-aminoalkylphenone-based photopolymerization initiator, or the α-hydroxyalkylphenone-based photopolymerization initiator.

A content of the photopolymerization initiator is preferably 0.1% by mass or more, more preferably 0.5% by mass or more, and still more preferably 1.0% by mass or more with respect to the total mass of the solid content of the composition. In addition, the upper limit thereof is preferably 10% by mass or less and more preferably 5% by mass or less with respect to the total mass of the solid content of the composition.

Surfactant

The composition includes a surfactant. Examples of the surfactant include surfactants described in paragraph [0017] of JP4502784B and paragraphs [0060] to [0071] of JP2009-237362A.

It is preferable that the surfactant is at least one compound selected from a fluorine-based surfactant, a silicone-based surfactant, or a hydrocarbon-based surfactant. Further, the surfactant is preferably a silicone-based surfactant.

Examples of the fluorine-based surfactant include the following available commercially products.
EXP.MFS-578-2 (DIC Corporation)
EXP.MFS-628 (DIC Corporation)
EXP.MFS-631 (DIC Corporation)
EXP.MFS-603 (DIC Corporation)
U-120E (Uni-chem Co., Ltd.)
FTERGENT 212M (NEOS COMPANY LIMITED)

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used.

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the silicone-based surfactant include a linear polymer consisting of a siloxane bond and a modified siloxane polymer with an organic group introduced in the side chain or the terminal.

Examples of the silicone-based surfactant include the following available commercially products.
EXP.S-309-2 (DIC Corporation)
EXP.S-310-2 (DIC Corporation)
EXP.S-315 (DIC Corporation)
EXP.S-503-2 (DIC Corporation)
EXP.S-505-2 (DIC Corporation)
EXP.S-506 (DIC Corporation)
BYK-302 (BYK Chemie Japan)
BYK-307 (BYK Chemie Japan)
BYK-313 (BYK Chemie Japan)
BYK-315N (BYK Chemie Japan)
BYK-323 (BYK Chemie Japan)
BYK-324 (BYK Chemie Japan)
BYK-330 (BYK Chemie Japan)
BYK-331 (BYK Chemie Japan)
BYK-333 (BYK Chemie Japan)
BYK-342 (BYK Chemie Japan)
BYK-377 (BYK Chemie Japan)
BYK-378 (BYK Chemie Japan)
BYK-300 (BYK Chemie Japan)
BYK-306 (BYK Chemie Japan)
BYK-310 (BYK Chemie Japan)
BYK-320 (BYK Chemie Japan)
BYK-325 (BYK Chemie Japan)
BYK-345 (BYK Chemie Japan)
BYK-347 (BYK Chemie Japan)
BYK-349 (BYK Chemie Japan)
BYK-370 (BYK Chemie Japan)
KP-124 (Shin-Etsu Chemical Co., Ltd.)
KP-109 (Shin-Etsu Chemical Co., Ltd.)
KP-121 (Shin-Etsu Chemical Co., Ltd.)
KP-103 (Shin-Etsu Chemical Co., Ltd.)
KP-341 (Shin-Etsu Chemical Co., Ltd.)
KP-112 (Shin-Etsu Chemical Co., Ltd.)
KP-125 (Shin-Etsu Chemical Co., Ltd.)
KP-101 (Shin-Etsu Chemical Co., Ltd.)
KP-106 (Shin-Etsu Chemical Co., Ltd.)
KP-120 (Shin-Etsu Chemical Co., Ltd.)
KP-105 (Shin-Etsu Chemical Co., Ltd.)
KP-104 (Shin-Etsu Chemical Co., Ltd.)
KP-611 (Shin-Etsu Chemical Co., Ltd.)
KP-626 (Shin-Etsu Chemical Co., Ltd.)
KP-327 (Shin-Etsu Chemical Co., Ltd.)
KP-323 (Shin-Etsu Chemical Co., Ltd.)
KP-322 (Shin-Etsu Chemical Co., Ltd.)
KP-310 (Shin-Etsu Chemical Co., Ltd.)
KP-109 (Shin-Etsu Chemical Co., Ltd.)
KP-620 (Shin-Etsu Chemical Co., Ltd.)
KP-652 (Shin-Etsu Chemical Co., Ltd.)
KP-306 (Shin-Etsu Chemical Co., Ltd.)
KP-301 (Shin-Etsu Chemical Co., Ltd.)
KP-621 (Shin-Etsu Chemical Co., Ltd.)
KP-369 (Shin-Etsu Chemical Co., Ltd.)
KP-368 (Shin-Etsu Chemical Co., Ltd.)

Examples of the hydrocarbon-based surfactant include surfactants having at least one structure selected from the group consisting of an aliphatic hydrocarbon structure and an aromatic hydrocarbon structure. Examples of a commercially available product of the hydrocarbon-based surfactant include PIONIN D-6115 and PIONIN D-1105 manufactured by Takemoto Oil&Fat Co., Ltd. Examples of a commercially available product of the hydrocarbon-based surfactant also include HYDROPALAT WE 3323 (BASF Japan).

The surfactant may be used alone or in combination of two or more kinds thereof.

A content of the surfactant is preferably 0.01% by mass to 3.0% by mass, more preferably 0.01% by mass to 1.0% by mass, and still more preferably 0.05% by mass to 0.80% by mass with respect to the total mass of the solid content of the composition.

From the viewpoint of improving the disappearance rate of bubbles generated during development, a ratio of the content of the surfactant to the content of the solvent (that is, surfactant/solvent) is preferably 1/100 to 1/30000, more preferably 1/500 to 1/15000, and still more preferably 1/1000 to 1/3000 on a mass basis.

Solvent

The composition includes a solvent. Examples of the solvent include water and an organic solvent. It is preferable that the composition includes an organic solvent. The composition may include water and an organic solvent.

Examples of the organic solvent include methyl ethyl ketone, propylene glycol monomethyl ether acetate, propylene glycol monomethyl ether, toluene, xylene, isobutanol, phenyl glycol, methoxypropyl acetate, phenoxyethanol, dipropylene glycol monomethyl ether, n-butyl acetate, n-propyl acetate, ethyl acetate, isopropyl acetate, isobutyl acetate, methyl acetate, diacetone alcohol, cyclohexanone, ethylene glycol monoethyl ether, ethylene glycol monoethyl ether acetate, ethylene glycol mono-n-butyl ether, and ethylene glycol monomethyl ether.

It is preferable that the solvent is at least one compound selected from the group consisting of methyl ethyl ketone, propylene glycol monomethyl ether acetate, propylene glycol monomethyl ether, toluene, xylene, isobutanol, phenyl glycol, methoxypropyl acetate, phenoxyethanol, dipropylene glycol monomethyl ether, n-butyl acetate, n-propyl acetate, ethyl acetate, isopropyl acetate, isobutyl acetate, methyl acetate, diacetone alcohol, cyclohexanone, ethylene glycol monoethyl ether, ethylene glycol monoethyl ether acetate, ethylene glycol mono-n-butyl ether, and ethylene glycol monomethyl ether.

The solvent may be an organic solvent (high-boiling-point solvent) having a boiling point of 180° C. to 250° C.

The solvent may be used alone or in combination of two or more kinds thereof.

A content of the solid content of the composition is preferably 5% by mass to 80% by mass, more preferably 5% by mass to 40% by mass, and still more preferably 5% by mass to 30% by mass with respect to the total mass of the composition. That is, a content of the solvent in the composition is preferably 20% by mass to 95% by mass, more preferably 60% by mass to 95% by mass, and still more preferably 70% by mass to 95% by mass with respect to the total mass of the composition.

Heterocyclic Compound

The composition may include a heterocyclic compound. A heterocyclic ring included in the heterocyclic compound may be either a monocyclic or polycyclic heterocyclic ring. Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound. Among the above-described compounds, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below. Examples of the triazole compound and the benzotriazole compound include the following compounds.

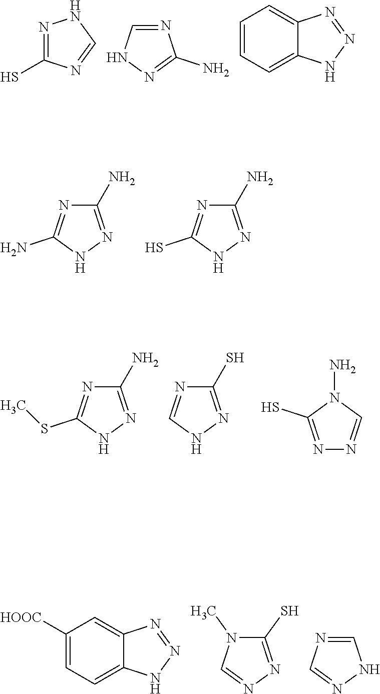

Examples of the tetrazole compound include the following compounds.

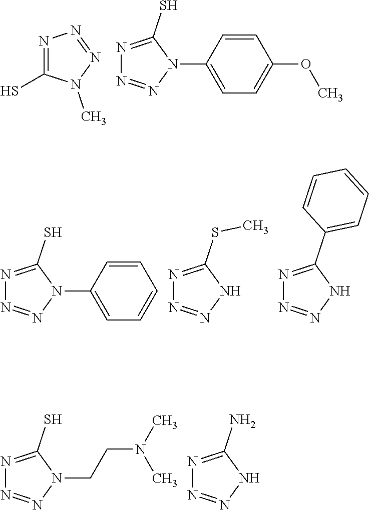

Examples of the thiadiazole compound include the following compounds.

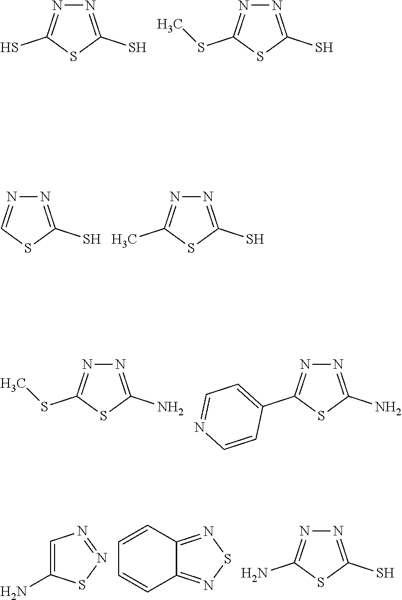

Examples of the triazine compound include the following compounds.

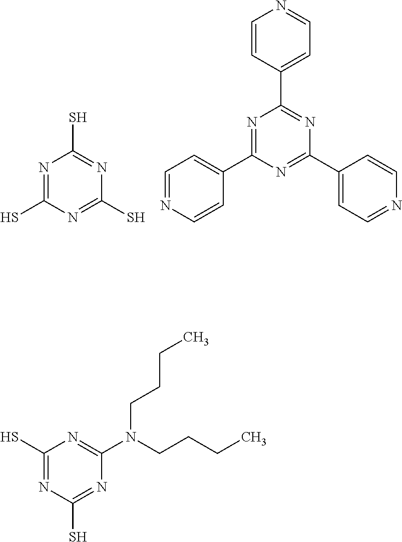

Examples of the rhodanine compound include the following compounds.

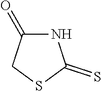

Examples of the thiazole compound include the following compounds.

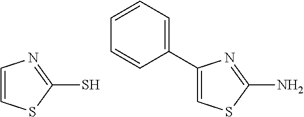

Examples of the benzothiazole compound include the following compounds.

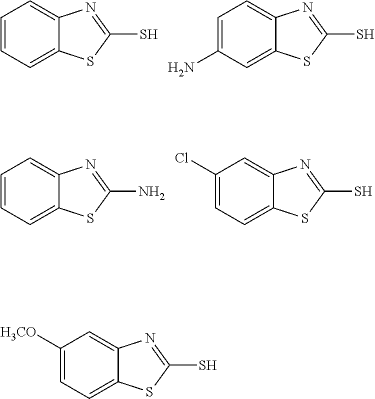 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

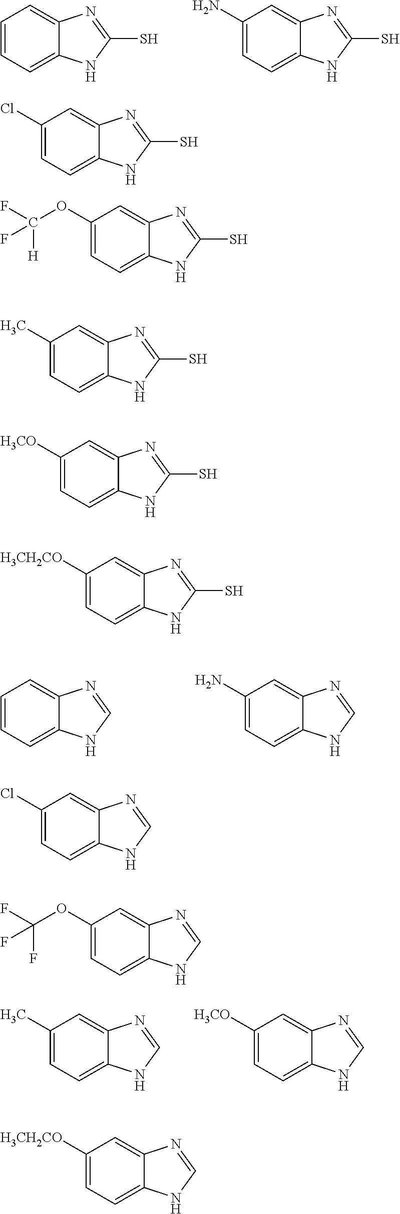

Examples of the benzoxazole compound include the following compounds.

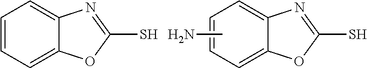

The heterocyclic compound may be used alone or in combination of two or more kinds thereof.

In a case where the composition includes the heterocyclic compound, a content of the heterocyclic compound is preferably 0.01% by mass to 20.0% by mass, more preferably 0.10% by mass to 10.0% by mass, still more preferably 0.30% by mass to 8.0% by mass, and particularly preferably 0.50% by mass to 5.0% by mass with respect to the total mass of the solid content of the composition.

Aliphatic Thiol Compound

The composition may include an aliphatic thiol compound. In a case where the composition includes an aliphatic thiol compound, an ene-thiol reaction of the aliphatic thiol compound with the radically polymerizable compound having an ethylenically unsaturated group suppresses a curing contraction of the formed film and relieves stress.

As the aliphatic thiol compound, a monofunctional aliphatic thiol compound or a polyfunctional aliphatic thiol compound (that is, bi- or higher functional aliphatic thiol compound) is preferable.

As the aliphatic thiol compound, from the viewpoint of adhesiveness of a pattern formed of the composition (particularly, adhesiveness after exposure), a polyfunctional aliphatic thiol compound is preferable. In the present disclosure, the “polyfunctional aliphatic thiol compound” refers to an aliphatic compound having two or more thiol groups (also referred to as “mercapto groups”) in a molecule.

As the polyfunctional aliphatic thiol compound, a low-molecular-weight compound having a molecular weight of 100 or more is preferable. Specifically, the molecular weight of the polyfunctional aliphatic thiol compound is more preferably 100 to 1,500 and still more preferably 150 to 1,000.

From the viewpoint of adhesiveness of the formed pattern, for example, the number of functional groups in the polyfunctional aliphatic thiol compound is preferably 2 to 10, more preferably 2 to 8, and still more preferably 2 to 6.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl] isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among the above-described compounds, the polyfunctional aliphatic thiol compound is preferably at least one compound selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

The composition may include only one kind of the aliphatic thiol compound, or may include two or more kinds of the aliphatic thiol compounds.

In a case where the composition includes the aliphatic thiol compound, a content of the aliphatic thiol compound is preferably 5% by mass or more, more preferably 5% by mass to 50% by mass, still more preferably 5% by mass to 30% by mass, and particularly preferably 8% by mass to 20% by mass with respect to the total mass of the solid content of the composition.

Thermal Crosslinking Compound

From the viewpoint of hardness of a cured film to be obtained and pressure-sensitive adhesiveness of an uncured film to be obtained, the composition preferably includes a thermal crosslinking compound. In the present disclosure, a thermal crosslinking compound having an ethylenically unsaturated group, which will be described later, is not treated as the ethylenically unsaturated compound, but is treated as the thermal crosslinking compound.

Examples of the thermal crosslinking compound include an epoxy compound, an oxetane compound, a methylol compound, and a blocked isocyanate compound. From the viewpoint of hardness of a cured film to be obtained and pressure-sensitive adhesiveness of an uncured film to be obtained, a blocked isocyanate compound is preferable.

Since the blocked isocyanate compound reacts with a hydroxy group and a carboxy group, for example, in a case where at least one of the alkali-soluble resin or the radically polymerizable compound having an ethylenically unsaturated group has at least one of a hydroxy group or a carboxy group, hydrophilicity of the formed film tends to decrease, and the function as a protective film tends to be strengthened. The blocked isocyanate compound refers to a “compound having a structure in which the isocyanate group of isocyanate is protected (so-called masked) with a blocking agent”.

A dissociation temperature of the blocked isocyanate compound is not particularly limited, but is preferably 90° C. to 160° C. and more preferably 100° C. to 150° C. The dissociation temperature of blocked isocyanate means “temperature at an endothermic peak accompanied with a deprotection reaction of blocked isocyanate, in a case where the measurement is performed by differential scanning calorimetry (DSC) analysis using a differential scanning calorimeter”. As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (dimethyl malonate, diethyl malonate, di-n-butyl malonate, di-2-ethylhexyl malonate, and the like)], and an oxime compound (compound having a structure represented by —C(═N—OH)— in a molecule, such as formaldoxime, acetoaldoxime, acetoxime, methyl ethyl ketoxime, and cyclohexanoneoxime). Among these, from the viewpoint of storage stability, the blocking agent having a dissociation temperature of 90° C. to 160° C. is preferably, for example, at least one selected from an oxime compound and a pyrazole compound.

From the viewpoint of improving brittleness of the film and improving the adhesion to the object to be transferred, for example, the blocked isocyanate compound preferably has an isocyanurate structure. The blocked isocyanate compound having an isocyanurate structure can be obtained, for example, by isocyanurate-forming and protecting hexamethylene diisocyanate. Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group. The polymerizable group is not particularly limited, and a known polymerizable group can be used, and a radically polymerizable group is preferable. Examples of the polymerizable group include a (meth)acryloxy group, a (meth)acrylamide group, an ethylenically unsaturated group such as styryl group, and an epoxy group such as a glycidyl group. Among these, as the polymerizable group, an ethylenically unsaturated group is preferable, a (meth)acryloxy group is more preferable, and an acryloxy group still more preferable.

As the blocked isocyanate compound, a commercially available product can be used. Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, DURANATE (registered trademark) SBN-70D, DURANATE (registered trademark) WT32-B75P, and the like manufactured by Asahi Kasei Corporation).

From the viewpoint that the effects of the present disclosure are more excellent, it is preferable that the composition contain a blocked isocyanate compound having an NCO value of 4.5 mmol/g or more (hereinafter, may be referred to as a first blocked isocyanate compound). The NCO value of the first blocked isocyanate compound is preferably 5.0 mmol/g or more and more preferably 5.3 mmol/g or more. From the viewpoint that the effects of the present disclosure are more excellent, the upper limit value of the NCO value of the first blocked isocyanate compound is preferably 8.0 mmol/g or less, more preferably 6.0 mmol/g or less, still more preferably less than 5.8 mmol/g, and particularly preferably 5.7 mmol/g or less. The NCO value of the blocked isocyanate compound in the present disclosure means the number of moles of isocyanate groups included in 1 g of the blocked isocyanate compound, and is a value calculated from the structural formula of the blocked isocyanate compound.

From the viewpoint that the effects of the present disclosure are more excellent, the first blocked isocyanate compound preferably has a ring structure. Examples of the ring structure include an aliphatic hydrocarbon ring, an aromatic hydrocarbon ring, and a heterocyclic ring, and from the viewpoint that the effects of the present disclosure are more excellent, an aliphatic hydrocarbon ring or an aromatic hydrocarbon ring is preferable, and an aliphatic hydrocarbon ring is more preferable.

Specific examples of the aliphatic hydrocarbon ring include a cyclopentane ring and a cyclohexane ring, and among these, a cyclohexane ring is preferable.

Specific examples of the aromatic hydrocarbon ring include a benzene ring and a naphthalene ring, and among these, a benzene ring is preferable.

Specific examples of the heterocyclic ring include an isocyanurate ring.

In a case where the first blocked isocyanate compound has a ring structure, from the viewpoint that the effects of the present disclosure are more excellent, the number of rings is preferably 1 or 2 and more preferably 1. In a case where the first blocked isocyanate compound includes a fused ring, the number of rings constituting the fused ring is counted, for example, the number of rings in the naphthalene ring is counted as 2.

From the viewpoint that the strength of the formed pattern is excellent and the effects of the present disclosure are more excellent, the number of blocked isocyanate groups in the first blocked isocyanate compound is preferably 2 to 5, more preferably 2 or 3, and still more preferably 2.

From the viewpoint that the effects of the present disclosure are more excellent, the first blocked isocyanate compound is preferably a blocked isocyanate compound represented by Formula Q.

B¹-A¹-L¹-A²-B²: Formula Q

In Formula Q, B¹ and B² each independently represent a blocked isocyanate group. The blocked isocyanate group is not particularly limited, but from the viewpoint that the effects of the present disclosure are more excellent, a group in which an isocyanate group is blocked with an oxime compound is preferable, and a group in which an isocyanate group is blocked with methyl ethyl ketooxime (specifically, a group represented by *—NH—C(═O)—O—N═C(CH₃)—C₂H₅; * represents a bonding position with A¹ or A²) is more preferable. B¹ and B² are preferably the same group.

In Formula Q, A¹ and A² each independently represent a single bond or an alkylene group having 1 to 10 carbon atoms, and an alkylene group having 1 to 10 carbon atoms is preferable. The alkylene group may be linear, branched, or cyclic, and is preferably linear. The number of carbon atoms in the alkylene group is 1 to 10, and from the viewpoint that the effects of the present disclosure are more excellent, is preferably 1 to 5, more preferably 1 to 3, and still more preferably 1. A¹ and A² are preferably the same group.

In Formula Q, L¹ represents a divalent linking group. Specific examples of the divalent linking group include a divalent hydrocarbon group. Specific examples of the divalent hydrocarbon group include a divalent saturated hydrocarbon group, a divalent aromatic hydrocarbon group, and a group formed by linking two or more of these groups. The divalent saturated hydrocarbon group may be linear, branched, or cyclic, and from the viewpoint that the effects of the present disclosure are more excellent, is preferably cyclic. From the viewpoint that the effects of the present disclosure are more excellent, the number of carbon atoms in the divalent saturated hydrocarbon group is preferably 4 to 15, more preferably 5 to 10, and still more preferably 5 to 8. The divalent aromatic hydrocarbon group preferably has 5 to 20 carbon atoms, and examples thereof include a phenylene group. The divalent aromatic hydrocarbon group may have a substituent (for example, an alkyl group). As the divalent linking group, a linear, branched, or cyclic divalent saturated hydrocarbon group having 5 to 10 carbon atoms, a group in which a cyclic saturated hydrocarbon group having 5 to 10 carbon atoms is linked to a linear alkylene group having 1 to 3 carbon atoms, a divalent aromatic hydrocarbon group which may have a substituent, or a group in which a divalent aromatic hydrocarbon group is linked to a linear alkylene group having 1 to 3 carbon atoms is preferable, a cyclic divalent saturated hydrocarbon group having 5 to 10 carbon atoms or a phenylene group which may have a substituent is more preferable, a cyclohexylene group or a phenylene group which may have a substituent is still more preferable, and a cyclohexylene group is particularly preferable.

From the viewpoint that the effects of the present disclosure are more excellent, the blocked isocyanate compound represented by Formula Q is particularly preferably a blocked isocyanate compound represented by Formula QA.

B^{1a}-A^{1a}-L^{1a}-A^{2a}-B^{2a}: Formula QA

In Formula QA, B^{1a} and B^{2a} each independently represent a blocked isocyanate group. Suitable aspects of B^{1a} and B^{2a} are the same as those of B¹ and B² in Formula Q.

In Formula QA, A^{1a} and A^{2a} each independently represent a divalent linking group. A suitable aspect of the divalent linking group in A^{1a} and A^{2a} is the same as those of A¹ and A² in Formula Q.

In Formula QA, L^{1a} represents a cyclic divalent saturated hydrocarbon group or a divalent aromatic hydrocarbon group. The number of carbon atoms in the cyclic divalent saturated hydrocarbon group in L^{1a} is preferably 5 to 10, more preferably 5 to 8, still more preferably 5 or 6, and particularly preferably 6. A suitable aspect of the divalent aromatic hydrocarbon group in L^{1a} is the same as that of L¹ in Formula Q. L^{1a} is preferably a cyclic divalent saturated hydrocarbon group, more preferably a cyclic divalent saturated hydrocarbon group having 5 to 10 carbon atoms, still more preferably a cyclic divalent saturated hydrocarbon group having 5 to 8 carbon atoms, particularly preferably a cyclic divalent saturated hydrocarbon group having 5 or 6 carbon atoms, and most preferably a cyclohexylene group. In a case where L^{1a} is a cyclohexylene group, the blocked isocyanate compound represented by Formula QA may be an isomer mixture of a cis form and a trans form. A mass ratio of the cis form and the trans form is preferably cis form/trans form=10/90 to 90/10, and more preferably cis form/trans form=40/60 to 60/40.

Specific examples of the first blocked isocyanate compound are shown below, but the first blocked isocyanate compound is not limited thereto.

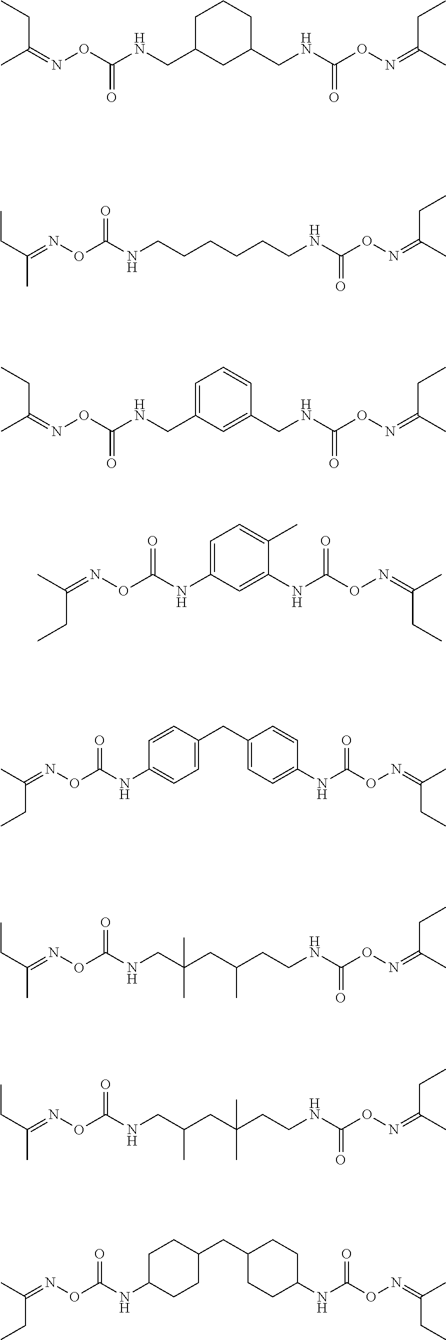

The thermal crosslinking compound may be used alone or in combination of two or more kinds thereof.

In a case where the composition includes the thermal crosslinking compound, a content of the thermal crosslinking compound is preferably 1% by mass to 50% by mass and more preferably 5% by mass to 30% by mass with respect to the total mass of the solid content of the composition.

Polymerization Inhibitor

The composition may include a polymerization inhibitor. The polymerization inhibitor means a compound having a function of delaying or prohibiting a polymerization reaction. As the polymerization inhibitor, for example, a known compound used as a polymerization inhibitor can be used.

Examples of the polymerization inhibitor include phenothiazine compounds such as phenothiazine, bis-(1-dimethylbenzyl)phenothiazine, and 3,7-dioctylphenothiazine; hindered phenolic compounds such as bis[3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, and pentaerythritol tetrakis3-(3,5-di-tert-butyl-4-hydroxyphenyl)propionate; nitroso compounds or a salt thereof, such as 4-nitrosophenol, N-nitrosodiphenylamine, N-nitrosocyclohexylhydroxylamine, and N-nitrosophenylhydroxylamine; quinone compounds such as methylhydroquinone, t-butylhydroquinone, 2,5-di-t-butylhydroquinone, and 4-benzoquinone; phenolic compounds such as 4-methoxyphenol, 4-methoxy-1-naphthol, and t-butylcatechol; and metal salt compounds such as copper dibutyldithiocarbamate, copper diethyldithiocarbamate, manganese diethyldithiocarbamate, and manganese diphenyldithiocarbamate. Among these, as the polymerization inhibitor, from the viewpoint that the effects of the present disclosure are more excellent, at least one selected from the group consisting of a phenothiazine compound, a nitroso compound or a salt thereof, and a hindered phenolic compound is preferable, and phenothiazine, bis[3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), p-methoxyphenol, or an aluminum salt of N-nitrosophenylhydroxylamine is more preferable.

The polymerization inhibitor may be used alone or in combination of two or more kinds thereof.

In a case where the composition includes the polymerization inhibitor, a content of the polymerization inhibitor is preferably 0.001% by mass to 5.0% by mass, more preferably 0.01% by mass to 3.0% by mass, and still more preferably 0.02% by mass to 2.0% by mass with respect to the total mass of the solid content of the composition. The content of the polymerization inhibitor is preferably 0.005% by mass to 5.0% by mass, more preferably 0.01% by mass to 3.0% by mass, and still more preferably 0.01% by mass to 1.0% by mass with respect to the total mass of the polymerizable compound.

Hydrogen Donating Compound

The composition may include a hydrogen donating compound. The hydrogen donating compound has a function of further improving sensitivity of the photopolymerization initiator to actinic ray, suppressing inhibition of polymerization of the polymerizable compound by oxygen, or the like.

Examples of the hydrogen donating compound include amines and an amino acid compound.

Examples of the amines include compounds described in M. R. Sander et al., “Journal of Polymer Society,” Vol. 10, page 3173 (1972), JP1969-020189B (JP-544-020189B), JP1976-082102A (JP-551-082102A), JP1977-134692A (JP-552-134692A), JP1984-138205A (JP-559-138205A), JP1985-084305A (JP-560-084305A), JP1987-018537A (JP-562-018537A), JP1989-033104A (JP-564-033104A), and Research Disclosure 33825. More specific examples thereof include 4,4′-bis(diethylamino)benzophenone, tris(4-dimethylaminophenyl)methane (another name: Leucocrystal Violet), triethanolamine, p-dimethylaminobenzoic acid ethyl ester, p-formyldimethylaniline, and p-methylthiodimethylaniline. As the amines, from the viewpoint that the effects of the present disclosure are more excellent, at least one selected from the group consisting of 4,4′-bis(diethylamino)benzophenone and tris(4-dimethylaminophenyl)methane is preferable.

Examples of the amino acid compound include N-phenylglycine, N-methyl-N-phenylglycine, and N-ethyl-N-phenylglycine. As the amino acid compound, from the viewpoint that the effects of the present disclosure are more excellent, N-phenylglycine is preferable.

In addition, examples of the hydrogen donating compound also include an organic metal compound described in JP1973-042965B (JP-548-042965B) (tributyl tin acetate and the like), a hydrogen donor described in JP1980-034414B (JP-555-034414B), and a sulfur compound described in JP1994-308727A (JP-H6-308727A) (trithiane and the like).

The hydrogen donating compound may be used alone or in combination of two or more kinds thereof.

In a case where the composition includes the hydrogen donating compound, from the viewpoint of improving a curing rate by balancing the polymerization growth rate and chain transfer, a content of the hydrogen donating compound is preferably 0.01% by mass to 10.0% by mass, more preferably 0.01% by mass to 8.0% by mass, and still more preferably 0.03% by mass to 5.0% by mass with respect to the total mass of the solid content of the composition.

Impurities

The composition may include a predetermined amount of impurities. Examples of the impurities include sodium, potassium, magnesium, calcium, iron, manganese, copper, aluminum, titanium, chromium, cobalt, nickel, zinc, tin, halogen, and ions of these. Among these, halide ion (for example, chloride ion, bromide ion, and iodide ion), sodium ion, and potassium ion are easily mixed as impurities, so that the following content is preferable.

A content of impurities in the composition is preferably 80 ppm or less, more preferably 10 ppm or less, and particularly preferably 2 ppm or less on a mass basis. The content of impurities in the composition may be 1 ppb or more or 0.1 ppm or more on a mass basis. Specific examples of the content of the impurities in the composition include an aspect in which all the above-described impurities are 0.6 ppm on a mass basis.

Examples of a method of setting the impurities in the above-described range include selecting a raw material having a low content of impurities as a raw material for the composition, preventing the impurities from being mixed in a case of forming the composition, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

Residual Monomer

The composition may include a residual monomer of each constitutional unit in the above-described alkali-soluble resin. From the viewpoint of patterning properties and reliability, a content of the residual monomer is preferably 5,000 ppm by mass or less, more preferably 2,000 ppm by mass or less, and still more preferably 500 ppm by mass or less with respect to the total mass of the alkali-soluble resin. The lower limit is not particularly limited, but is preferably 1 ppm by mass or more and more preferably 10 ppm by mass or more.

From the viewpoint of patterning properties and reliability, the residual monomer of each constitutional unit in the alkali-soluble resin is preferably 3,000 ppm by mass or less, more preferably 600 ppm by mass or less, and still more preferably 100 ppm by mass or less with respect to the total mass of the solid content of the composition. The lower limit is not particularly limited, but is preferably 0.1 ppm by mass or more and more preferably 1 ppm by mass or more.

It is preferable that the amount of residual monomer of the monomer in a case of synthesizing the alkali-soluble resin by the polymer reaction is also within the above-described range. For example, in a case where glycidyl acrylate is reacted with a carboxylic acid side chain to synthesize the alkali-soluble resin, the content of glycidyl acrylate is preferably within the above-described range.

The amount of residual monomers can be measured by a known method such as liquid chromatography and gas chromatography.

Other Components

The composition may include a component other than the above-mentioned components (hereinafter also referred to as “other components”). Examples of the other components include a colorant (for example, a pigment and a dye), an antioxidant, and particles (for example, metal oxide particles).

Colorant

In a case where the composition is used in applications where transparency is required, it is preferable that the composition does not substantially include a colorant. In a case where the composition includes the colorant, a content of the colorant is preferably less than 1% by mass and more preferably less than 0.1% by mass with respect to the total mass of the solid content of the composition.

On the other hand, the composition may be a composition including a colorant (preferably, a pigment). In a liquid crystal display window included in electronic apparatuses in the recent years, in order to protect the liquid crystal display window, a cover glass having a black frame-shaped light-shielding layer formed on a peripheral edge of the back surface of a transparent glass substrate or the like may be attached. A coloring composition may be used to form such a light-shielding layer. In addition, the composition including a colorant may be used for forming a black matrix of a color filter. In addition, the composition including a colorant may be used for forming an antireflection film for various devices, a partition wall of a display, and the like. However, the applications of the composition including a colorant are not limited to the above-described specific examples.

The pigment may be selected from a black pigment, a white pigment, and a chromatic pigment other than black and white. Among these, in a case of forming a black pattern, a black pigment is suitably selected as the pigment.

As the black pigment, known black pigments (organic pigments, inorganic pigments, or the like) can be appropriately selected as long as the effects of the present disclosure are not impaired. Among these, from the viewpoint of optical density, suitable examples of the black pigment include carbon black, titanium oxide, titanium carbide, iron oxide, and graphite, and carbon black is particularly preferable. As the carbon black, from the viewpoint of surface electrical resistance, carbon black in which at least a part of a surface is coated with a resin is preferable.

Examples of the carbon black include lamp black, acetylene black, thermal black, channel black, and furnace black. Examples of a commercially available product of the carbon black include carbon black described in paragraph [0018] of JP2021-012355A. In a case where the composition includes the carbon black, a content of the carbon black is preferably 10% by mass to 30% by mass and more preferably 15% by mass to 30% by mass with respect to the total mass of the solid content of the composition.

From the viewpoint of dispersion stability, a particle size of the black pigment (specifically, a number average particle diameter) is preferably 0.001 μm to 0.2 μm, more preferably 0.001 μM to 0.1 μm, and still more preferably 0.01 μm to 0.08 μm. The particle diameter refers to a diameter of a circle in a case where an area of pigment particles is obtained from a photographic image of the pigment particles taken with an electron microscope and a circle having the same area as the area of the pigment particles is considered, and the number average particle diameter is an average value obtained by determining the particle diameters for any 100 particles and averaging the determined 100 particle diameters.

White pigments described in paragraphs [0015] and [0114] of JP2005-007765A can be used as the white pigment. Specifically, among the white pigments, as an inorganic pigment, titanium oxide, zinc oxide, lithopone, light calcium carbonate, white carbon, aluminum oxide, aluminum hydroxide, or barium sulfate is preferable, titanium oxide or zinc oxide is more preferable, and titanium oxide is still more preferable. As the inorganic pigment, rutile-type or anatase-type titanium oxide is still more preferable, and rutile-type titanium oxide is particularly preferable.

A surface of titanium oxide may be subjected to a silica treatment, an alumina treatment, a titania treatment, a zirconia treatment, or an organic substance treatment, or may be subjected to two or more treatments thereof. As a result, catalytic activity of titanium oxide is suppressed, and heat resistance, light resistance, and the like are improved. As the surface treatment of the surface of titanium oxide, at least one of the alumina treatment or the zirconia treatment is preferable, and both alumina treatment and zirconia treatment are particularly preferable.

From the viewpoint of more excellent dispersibility, a particle size of the chromatic pigment other than black and white is preferably 0.1 μm or less and more preferably 0.08 μm or less. Examples of the chromatic pigment include Victoria Pure Blue BO (Color Index (hereinafter, C. I.) 42595, Auramine O (C. I. 41000), Fat Black HB (C. I. 26150), Monolite Yellow GT (C. I. Pigment Yellow 12), Permanent Yellow GR (C. I. Pigment Yellow 17), Permanent Yellow HR (C. I. Pigment Yellow 83), Permanent Carmine FBB (C. I. Pigment Red 146), Hostaperm Red ESB (C. I. Pigment Violet 19), Permanent Rubine FBH (C. I. Pigment Red 11), Fastel Pink B Supra (C. I. Pigment Red 81), Monastral Fast Blue (C. I. Pigment Blue 15), Monolite Fast Black B (C. I. Pigment Black 1), Carbon, C. I. Pigment Red 97, C. I. Pigment Red 122, C. I. Pigment Red 149, C. I. Pigment Red 168, C. I. Pigment Red 177, C. I. Pigment Red 180, C. I. Pigment Red 192, C. I. Pigment Red 215, C. I. Pigment Green 7, C. I. Pigment Blue 15:1, C. I. Pigment Blue 15:4, C. I. Pigment Blue 22, C. I. Pigment Blue 60, C. I. Pigment Blue 64, and C. I. Pigment Violet 23. Among these, C. I. Pigment Red 177 is preferable.

In a case where the composition includes the pigment, a content of the pigment is preferably more than 3% by mass and 40% by mass or less, more preferably more than 3% by mass and 35% by mass or less, still more preferably more than 5% by mass and 35% by mass or less, and particularly preferably 10% by mass to 35% by mass with respect to the total mass of the solid content of the composition.

In a case where the composition includes pigments (the white pigment and the chromatic pigment) other than the black pigment, a content of the pigments other than the black pigment is preferably 30% by mass or less, more preferably 1% to 20% by mass, and still more preferably 3% to 15% by mass with respect to the black pigment.

In a case where the composition includes a black pigment, the black pigment is preferably introduced into the composition in a form of a pigment dispersion liquid. The dispersion liquid may be prepared by adding a mixture obtained by previously mixing the black pigment and a dispersing agent (also referred to as a pigment dispersing agent) to an organic solvent (or vehicle) and dispersing it with a disperser. That is, the composition may include the black pigment and the dispersing agent.

The dispersing agent may be selected depending on the pigment and the solvent. The dispersing agent may be a commercially available dispersing agent. Examples of the commercially available product include BYK-2012 (BYK Chemie Japan).

Examples of the dispersing agent include urethane-based dispersing agents such as polyurethane, polycarboxylic acid ester such as polyacrylate, unsaturated polyamide, polycarboxylic acid, polycarboxylic acid (partial)amine salt, polycarboxylic acid ammonium salt, polycarboxylic acid alkylamine salt, polysiloxane, long-chain polyaminoamide phosphate, hydroxyl group-containing polycarboxylic acid ester, a modified product thereof, oil-based dispersing agents such as an amide formed by a reaction of poly(lower alkyleneimine) with polyester having a liberate carboxyl group and a salt of the amide, water-soluble resins or water-soluble polymer compounds such as (meth)acrylic acid-styrene copolymer, (meth)acrylic acid-(meth)acrylic acid ester copolymer, styrene-maleic acid copolymer, polyvinyl alcohol, and polyvinylpyrrolidone, polyester-based compound, modified polyacrylate-based compound, ethylene oxide/propylene oxide addition compound, and phosphoric acid ester-based compound. The aspect of the dispersing agent may be selected from the matters described in paragraphs [0021] to [0065] of JP2021-012355A.

Examples of a preferred dispersing agent include a basic polymer-type dispersing agent. Examples of the basic polymer-type dispersing agent include a polymer including a nitrogen atom. The nitrogen atom may be included in a main chain of the polymer. The nitrogen atom may be included in a side chain of the polymer. The nitrogen atom may be included in the main chain and side chain of the polymer. The basic polymer-type dispersing agent is preferably a polymer including a nitrogen atom in the side chain. Since the surface of the carbon black is generally acidic, in a case where the carbon black is used as the pigment, the basic polymer-type dispersing agent is particularly preferable as the dispersing agent.

Examples of the polymer including a nitrogen atom (preferably, the polymer including a nitrogen atom in the side chain) include a polymer including at least one atomic group selected from the group consisting of a primary amino group, a secondary amino group, a tertiary amino group, a quaternary ammonium salt group, and a nitrogen-containing heterocyclic group. For example, a polymer including a quaternary ammonium salt group is preferable. The atomic group is preferably introduced into the side chain of the polymer. For example, a polymer including, in the side chain, at least one atomic group selected from the group consisting of a primary amino group, a secondary amino group, a tertiary amino group, a quaternary ammonium salt group, and a nitrogen-containing heterocyclic group is preferable, and a polymer including a quaternary ammonium salt group in the side chain is more preferable. Examples of a counter ion of a quaternary ammonium cation in the quaternary ammonium salt group include a carboxylic acid ion. Examples of the carboxylic acid ion include an aliphatic carboxylic acid ion and an aromatic carboxylic acid ion.

The polymer including a nitrogen atom (preferably, the polymer including a nitrogen atom in the side chain) is preferably a polymer including a constitutional unit derived from styrene and a constitutional unit derived from a maleimide derivative, and more preferably a copolymer of styrene and a maleimide derivative. The maleimide derivative has a structure in which at least one hydrogen atom of maleimide is substituted with a substituent. Examples of the maleimide derivative include a maleimide derivative including at least one atomic group selected from the group consisting of a primary amino group, a secondary amino group, a tertiary amino group, a quaternary ammonium salt group, and a nitrogen-containing heterocyclic group. The maleimide derivative is preferably a maleimide derivative including a quaternary ammonium salt group.

Examples of the basic polymer-type dispersing agent also include a polymer including at least one constitutional unit selected from the group consisting of a constitutional unit represented by General Formula (1), a constitutional unit represented by General Formula (2), and a constitutional unit represented by General Formula (3).

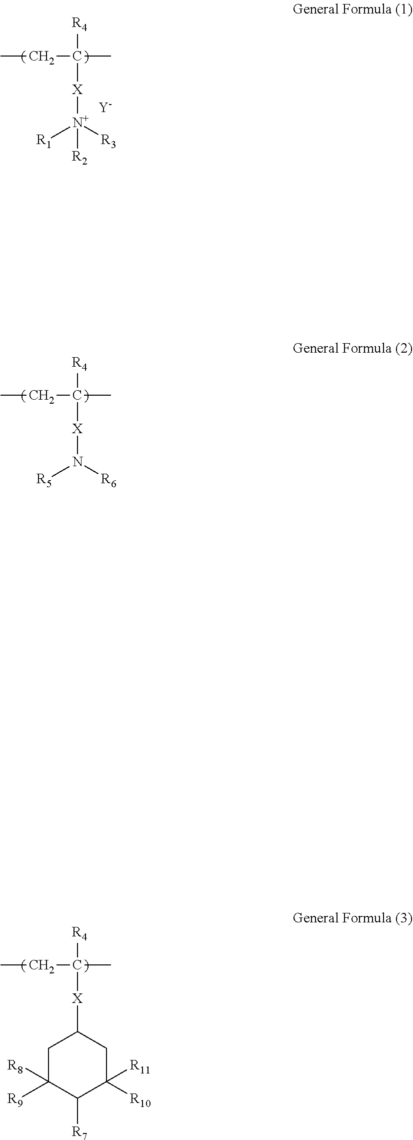

In General Formula (1), R₁ to R₃ each independently represent a hydrogen atom or a chain or cyclic hydrocarbon group which may have a substituent, two or more of R₁ to R₃ may be bonded to each other to form a cyclic structure, R₄ represents a hydrogen atom or a methyl group, X represents a divalent linking group, and Y⁻ represents a counter anion.

In General Formula (2), R₅ and R₆ each independently represent a hydrogen atom or a chain or cyclic hydrocarbon group which may have a substituent, R₅ and R₆ may be bonded to each other to form a cyclic structure, R₄ represents a hydrogen atom or a methyl group, and X represents a divalent linking group.

In General Formula (3), R₇ represents a hydrogen atom, an alkyl group having 1 to 18 carbon atoms, an aryl group having 6 to 20 carbon atoms, an aralkyl group having 7 to 12 carbon atoms, an acyl group, an oxyradical group, or OR₁₂, R₁₂ represents a hydrogen atom, an alkyl group having 1 to 18 carbon atoms, an aryl group having 6 to 20 carbon atoms, an aralkyl group having 7 to 12 carbon atoms, or an acyl group, R₈, R₉, R₁₀, and R₁₁ each independently represent a methyl group, an ethyl group, or a phenyl group, R₄ represents a hydrogen atom or a methyl group, and X represents a divalent linking group.

From the viewpoint of dispersion stability of the carbon black, a polymer including the constitutional unit represented by General Formula (3) (hereinafter, may be referred to as a “dispersing agent (B1)” is preferable. The dispersing agent (B1) may include other constitutional units in addition to the constitutional unit represented by General Formula (3). The dispersing agent (B1) may be a random polymer or a block polymer.

A monomer forming the constitutional unit represented by General Formula (3) is preferably a compound represented by General Formula (8-1) or a compound represented by General Formula (8-2).

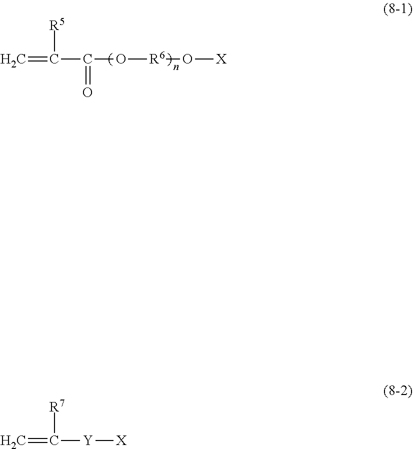

In General Formula (8-1) and General Formula (8-2), R⁵ and R⁷ each independently represent a hydrogen atom or a methyl group, R⁶ represents a methylene group or an alkylene group having 2 to 5 carbon atoms, X represents a group represented by General Formula (4), Y represents —CONH—, —SO₂—, or —SO₂NH—, and n represents an integer of 0 to 9. R⁶ is preferably an ethylene group or a propylene group, and more preferably an ethylene group. n is preferably an integer of 0 to 8, and more preferably an integer of 0 to 6.

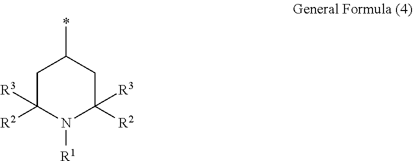

In General Formula (4), R¹ to R³ correspond to R⁷ to R¹¹ of General Formula (3), respectively. * is a bonding site.

Examples of the compound represented by General Formula (8-1) include compounds represented by General Formulae (9-1) to (9-7).

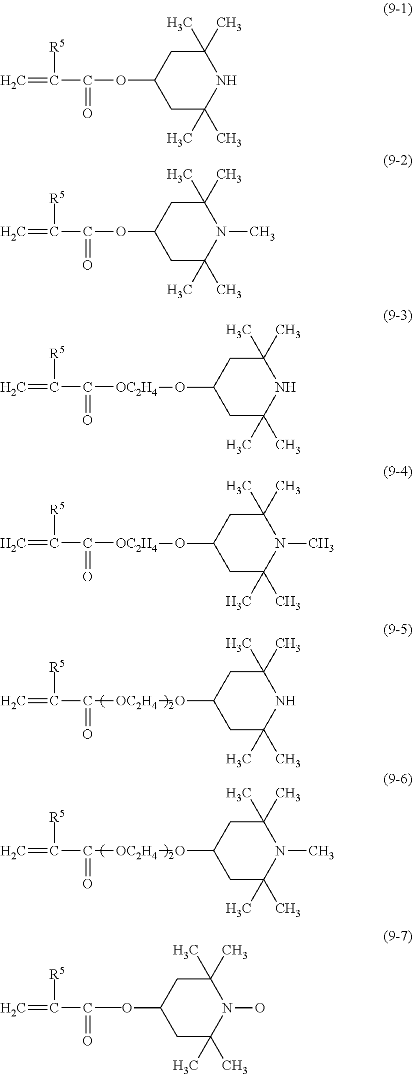

In General Formulae (9-1) to (9-7), R⁵ is the same as R⁵ in General Formula (8-1).

Examples of the compound represented by General Formula (8-2) include compounds represented by General Formulae (10-1) to (10-4).

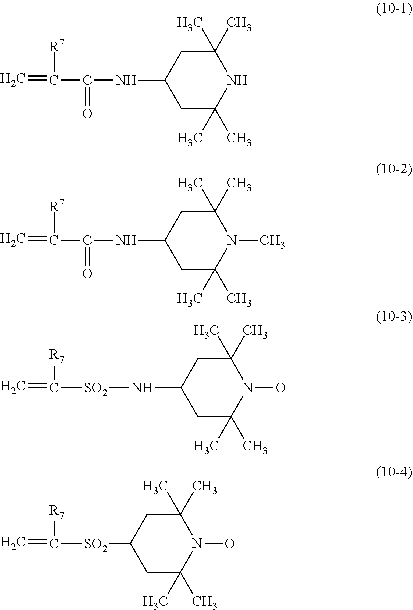

In General Formulae (10-1) to (10-4), R⁷ is the same as R⁷ in General Formula (8-2).

Among the above-described compounds, 2,2,6,6-tetramethylpiperidyl methacrylate (that is, a compound in which R⁷ in General Formula (10-1) is a methyl group) or 1,2,2,6,6-pentamethylpiperidyl methacrylate (that is, a compound in which R⁷ in General Formula (10-2) is a methyl group) is preferable, and 1,2,2,6,6-pentamethylpiperidyl methacrylate (that is, a compound in which R⁷ in General Formula (10-2) is a methyl group) is more preferable.

A content of the constitutional unit represented by General Formula (3) in all constitutional units of the dispersing agent (B1) is preferably 1% by mass to 100% by mass, more preferably 10% by mass to 80% by mass, and still more preferably 20% by mass to 70% by mass. In a case where the dispersing agent (B1) includes the constitutional unit represented by General Formula (3), a piperidine skeleton is more bulky and steric hindrance is large. Therefore, the dispersing agent (B1) improves the dispersion stability by suppressing an opportunity for other materials to come into contact with the carbon black.

Examples of the monomer forming other constitutional units in the dispersing agent (B1) include (meth)acrylic acid ester, a monomer including a nitrogen-containing group, and a vinyl monomer.

Examples of the (meth)acrylic acid ester include (meth)acrylic acid alkyl esters such as methyl (meth)acrylate, ethyl (meth)acrylate, n-propyl (meth)acrylate, isopropyl (meth)acrylate, n-butyl (meth)acrylate, isobutyl (meth)acrylate, 2-ethylhexyl (meth)acrylate, cyclohexyl (meth)acrylate, stearyl (meth)acrylate, and lauryl (meth)acrylate; aliphatic ring (meth)acrylates such as cyclohexyl (meth)acrylate, tertiary butyl cyclohexyl (meth)acrylate, dicyclopentanyl (meth)acrylate, dicyclopentenyl (meth)acrylate, and isobornyl (meth)acrylate; aromatic (meth)acrylates such as phenyl (meth)acrylate, benzyl (meth)acrylate, phenoxyethyl (meth)acrylate, and phenoxydiethylene glycol (meth)acrylate; heterocyclic (meth)acrylates such as tetrahydrofurfuryl (meth)acrylate and 3-methyl-3-oxetanyl (meth)acrylate; and alkoxypolyalkylene glycol (meth)acrylates such as methoxypolypropylene glycol (meth) acrylate and ethoxypolyethylene glycol (meth) acrylate.

Examples of the monomer including a nitrogen-containing group include N-substituted (meth)acrylamides such as (meth)acrylamide, N,N-dimethyl (meth)acrylamide, N,N-diethyl (meth)acrylamide, N-isopropyl (meth)acrylamide, diacetone (meth)acrylamide, and acryloyl morpholine; amino group-containing (meth)acrylates such as N,N-dimethylaminoethyl (meth)acrylate and N,N-diethylaminoethyl (meth) acrylate; and nitriles such as (meth)acrylonitrile.

Examples of the vinyl monomer include styrenes such as styrene and α-methylstyrene; vinyl ethers such as ethyl vinyl ether, n-propyl vinyl ether, isopropyl vinyl ether, n-butyl vinyl ether, and isobutyl vinyl ether; and fatty acid vinyls such as vinyl acetate and vinyl propionate.

An amine value of the dispersing agent (B1) is preferably 50 mgKOH/g to 350 mgKOH/g. Low viscosity and dispersion stability can be easily obtained with an appropriate amine value.

An organic solvent may be used in the synthesis of the dispersing agent. Examples of the organic solvent include ethyl acetate, n-butyl acetate, isobutyl acetate, hexane, toluene, xylene, acetone, methyl ethyl ketone, cyclohexanone, propylene glycol monomethyl ether acetate, dipropylene glycol monomethyl ether acetate, ethylene glycol monoethyl ether acetate, ethylene glycol monobutyl ether acetate, diethylene glycol monoethyl ether acetate, and diethylene glycol monobutyl ethyl acetate. One kind or two or more kinds of organic solvents may be used.

The vehicle refers to a part of a medium in which the pigment is dispersed in a case of being used as the pigment dispersion liquid, is liquid, and includes a binder component which maintains the black pigment in a dispersed state and a solvent component (organic solvent) which dissolves and dilutes the binder component.

The disperser is not particularly limited, and examples thereof include known dispersers such as a kneader, a roll mill, an attritor, a super mill, a dissolver, a homomixer, and a sand mill. Further, the pigment may be finely pulverized by a mechanical grinding using frictional force. For the disperser and fine pulverization, the description of “Encyclopedia of Pigments” (First Edition, published by Asakura Shoten, 2000, p. 438, p. 310) can be referred to.

The composition may include a dispersion aid (also referred to as a pigment dispersion aid) in addition to the pigment. The dispersion aid may be selected from a known dispersion aid.

Examples of the dispersion aid include a compound having an organic coloring agent residue. Examples of the organic coloring agent include a phthalocyanine-based pigment, a diketopyrrolopyrrole-based pigment, an anthraquinone-based pigment, a quinacridone-based pigment, a dioxazine-based pigment, a perinone-based pigment, a perylene-based pigment, a thiazineindigo-based pigment, a triazine-based pigment, a benzimidazolone-based pigment, indole-based pigments such as benzoisoindole, an isoindoline-based pigment, an isoindolinone-based pigment, a quinophthalone-based pigment, a naphthol-based pigment, a threne-based pigment, a metal complex-based pigment, and azo-based pigments such as azo, disazo, and polyazo. The compound having an organic coloring agent residue may have an acidic substituent, a basic substituent, or a neutral substituent. Examples of the acidic substituent include a sulfo group, a carboxy group, and a phosphoric acid group. Examples of the basic substituent include a sulfonamide group and an amino group. Examples of the neutral substituent include a phenyl group and a phthalimidealkyl group. The aspect of the dispersion aid may be selected from the matters described in paragraphs [0067] to [0084] of JP2021-012355A.

Examples of a preferred dispersion aid include a compound having a phthalocyanine residue. Specifically, the dispersion aid is preferably a phthalocyanine-based pigment derivative having an acidic substituent or a salt thereof, more preferably a phthalocyanine-based pigment derivative having at least one acidic substituent selected from the group consisting of a sulfo group, a carboxy group, and a phosphoric acid group or a salt thereof, and still more preferably a phthalocyanine-based pigment derivative having a sulfo group or a salt thereof. The phthalocyanine-based pigment derivative is described in, for example, JP2007-226161A, WO2016/163351A, JP2017-165820A, and JP5753266B. These publications are incorporated herein by reference.

Antioxidant

Examples of the antioxidant include 3-pyrazolidones such as 1-phenyl-3-pyrazolidone (another name; phenidone), 1-phenyl-4,4-dimethyl-3-pyrazolidone, and 1-phenyl-4-methyl-4-hydroxymethyl-3-pyrazolidone; polyhydroxybenzenes such as hydroquinone, catechol, pyrogallol, methylhydroquinone, and chlorohydroquinone; paramethylaminophenol, paraaminophenol, parahydroxyphenylglycine, and paraphenylenediamine. Among these, as the antioxidant, from the viewpoint that the effects of the present disclosure are more excellent, 3-pyrazolidones are preferable, and 1-phenyl-3-pyrazolidone is more preferable.

In a case where the composition includes the antioxidant, a content of the antioxidant is preferably 0.001% by mass or more, more preferably 0.005% by mass or more, and still more preferably 0.01% by mass or more with respect to the total mass of the solid content of the composition. The upper limit is not particularly limited, and is preferably 1% by mass or less.

Particles

As the particles, metal oxide particles are preferable. The metal of the metal oxide particles also includes semimetal such as B, Si, Ge, As, Sb, or Te. From the viewpoint of transparency of the cured film, for example, an average primary particle diameter of the particles is preferably 1 nm to 200 nm and more preferably 3 nm to 80 nm. The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the composition includes the particles, the photosensitive layer may include only one kind of particles, or may include two or more kinds of particles having different metal types, sizes, and the like.

It is preferable that the composition does not include the particles, or in a case where the composition includes the particles, a content of the particles is more than 0% by mass and 35% by mass or less with respect to the total mass of the solid content of the composition; it is more preferable that the composition does not include the particles, or in a case where the composition includes the particles, a content of the particles is more than 0% by mass and 10% by mass or less with respect to the total mass of the solid content of the composition; it is still more preferable that the composition does not include the particles, or in a case where the composition includes the particles, a content of the particles is more than 0% by mass and 5% by mass or less with respect to the total mass of the solid content of the composition; it is even more preferable that the composition does not include the particles, or in a case where the composition includes the particles, a content of the particles is more than 0% by mass and 1% by mass or less with respect to the total mass of the solid content of the composition; and it is particularly preferable that the composition does not include the particles.

In addition, examples of the other components also include other additives described in paragraphs [0058] to [0071] of JP2000-310706A.

Application

An application of the composition according to the first embodiment is not limited. Examples of the application of the composition according to the first embodiment also include an electrode protective film, an insulating film, a flattening film, an overcoat film, a hard coat film, a passivation film, a partition wall, a spacer, a microlens, an optical filter, an antireflection film, an etching resist, and a plating member. Examples of the application of the composition also include a protective film or an insulating film for a touch panel electrode, a protective film or an insulating film for a printed wiring board, a protective film or an insulating film for a TFT substrate, a color filter, an overcoat film for a color filter, and an etching resist for a wiring line formation. The composition may be used as a photosensitive composition. The composition may be used to form a photosensitive layer.

### Composition According to Second Embodiment

In the second embodiment, the composition includes a surfactant and a solvent. Further, with regard to a surface tension of the composition, a surface tension T1 measured by a Wilhelmy method at 25° C. and a surface tension T2 measured by a Wilhelmy method at 25° C. immediately before a timing that a volume reaches 60% of an initial volume in an environment of a temperature of 25° C. and a relative humidity of 60% satisfy a relationship of T1>T2. According to the above-described embodiment, a composition in which a coating streak during high-speed coating is reduced is provided. Hereinafter, details of the composition according to the second embodiment will be described. In the following description, the “composition according to the second embodiment” may be simply referred to as a “composition”.

Surface Tension

The surface tension T1 of the composition and the surface tension T2 of the composition satisfy the relationship of T1>T2. T1 represents the surface tension at 25° C. measured by the Wilhelmy method. T2 represents the surface tension at 25° C., which is measured by the Wilhelmy method immediately before a timing that a volume reaches 60% of an initial volume in an environment of a temperature of 25° C. and a relative humidity of 60%. The “surface tension at 25° C., which is measured by the Wilhelmy method immediately before a timing that a volume reaches 60% of an initial volume in an environment of a temperature of 25° C. and a relative humidity of 60%” is a measured value obtained by starting the measurement of the surface tension by the Wilhelmy method from the time when the volume of the object to be measured reaches 60% of the initial volume and performing the measurement operation without delay. The “initial volume” means the volume of the composition before being left in the environment of a temperature of 25° C. and a relative humidity of 60% in the measurement of the surface tension T2 described later. In the composition satisfying the relationship of T1>T2, even in a case where a drying proceeds to some extent, an increase in surface tension can be suppressed. In a case where the increase in surface tension of the composition due to the progress of drying is suppressed, the phenomenon which causes the coating streak described above, that is, the composition discharged from the coating device rises and the liquid pool of the composition is suppressed near the discharge port of the coating device. As a result, it is considered that the coating streak during high-speed coating is reduced.

From the viewpoint of improving coating properties, the surface tension T1 is preferably 25 mN/m to 35 mN/m, more preferably 27 mN/m to 34 mN/m, and still more preferably 28 mN/m to 33 mN/m.

From the viewpoint of reducing the coating streak during high-speed coating, the surface tension T2 is preferably 20 mN/m to 26 mN/m, more preferably 20 mN/m to 25 mN/m, and still more preferably 21 mN/m to 24 mN/m.

From the viewpoint of reducing the coating streak during high-speed coating, it is preferable that the surface tension T1 and the surface tension T2 satisfy a relationship of 5 mN/m<(T1−T2)<10 mN/m. Further, it is preferable that the surface tension T1 and the surface tension T2 satisfy a relationship of 5 mN/m<(T1−T2)<7 mN/m.

The surface tension T1 is measured according to the measuring method of the surface tension of the composition according to the first embodiment described above.

The surface tension T2 is measured by the following method. A 50 mL sample is prepared, and the sample is left in an environment of a temperature of 25° C. and a relative humidity of 60%, and dried until a liquid volume of the sample reaches 30 mL. The 30 mL corresponds to 60% of 50 mL (that is, the initial volume). After drying, the surface tension is measured three times by the Wilhelmy method. In the measurement of the surface tension, a CBVP-A3 type automatic surface tension meter manufactured by Kyowa Interface Science Co., Ltd. is used, and a platinum plate is used as a probe according to the Wilhelmy method. An arithmetic mean value of the measured value is adopted as the surface tension of the object.

The surface tension T1 and the surface tension T2 may be adjusted by a known method. Examples of main factors affecting the surface tension T1 and the surface tension T2 include the type of the surfactant, the content of the surfactant, the type of the solvent, and the content of the solvent. For example, in a case of a water/methanol mixed solvent system, the surface tension T2 tends to be smaller than the surface tension T1 in a case where a surfactant which is more soluble in methanol than water is used.

Surfactant

The composition includes a surfactant. Examples of the surfactant include the surfactants described in the above section of “Composition according to first embodiment”. A preferred aspect of the surfactant is the same as the preferred aspect of the surfactant described in the above section of “Composition according to first embodiment”. For example, it is preferable that the surfactant is at least one compound selected from a fluorine-based surfactant, a silicone-based surfactant, or a hydrocarbon-based surfactant. Further, the surfactant is also preferably a nonionic surfactant.

The composition may include one kind or two or more kinds of surfactants.

From the viewpoint of reducing the coating streak during high-speed coating, a content of the surfactant is preferably 0.1% by mass to 10% by mass, more preferably 0.5% by mass to 5% by mass, and still more preferably 1% by mass to 4% by mass with respect to the total mass of the solid content of the composition.

From the viewpoint of reducing the coating streak during high-speed coating, a ratio of the content of the surfactant to the content of the solvent (that is, surfactant/solvent) is preferably 0.005% by mass to 0.3% by mass, more preferably 0.008% by mass to 0.2% by mass, and still more preferably 0.01% by mass to 0.10% by mass on a mass basis.

In addition, from the viewpoint of uniformity of a thickness of the coating film, the content of the surfactant is preferably 0.005% by mass to 0.100% by mass, more preferably 0.010% by mass to 0.070% by mass, and still more preferably 0.015% by mass to 0.050% by mass with respect to the total mass of the composition.

The uniformity of the thickness of the coating film is advantageous, for example, from the viewpoint of suppressing color unevenness in a case where the composition is adopted to a formation of a refractive index adjusting layer.

Solvent

The composition includes a solvent. Examples of the solvent include water and an organic solvent. The solvent preferably includes at least one compound selected from the group consisting of water and an organic solvent. It is also preferable that the solvent includes water and an organic solvent.

Examples of the organic solvent include alcohol, acetone, ethylene glycol, and glycerin. The organic solvent is preferably an alcohol having 1 to 3 carbon atoms, more preferably methanol or ethanol, and still more preferably methanol.

From the viewpoint of reducing the coating streak during high-speed coating, the organic solvent is preferably an organic solvent which does not azeotrope with water. The organic solvent which does not azeotrope with water may be selected from known organic solvents. The organic solvent which does not azeotrope with water is preferably methanol.

From the viewpoint of reducing the coating streak during high-speed coating, in a case where the composition includes water and an organic solvent, a ratio of a content of the organic solvent which does not azeotrope with water to the content of water (that is, organic solvent which does not azeotrope with water/water) is preferably 10/90 to 90/10, more preferably 30/70 to 85/15, and still more preferably 40/60 to 80/20 on a mass basis.

The composition may include one kind or two or more kinds of solvents.

From the viewpoint of improving coating properties and reducing the coating streak during high-speed coating, the content of the solvent is preferably 50 parts by mass to 2,500 parts by mass, more preferably 50 parts by mass to 1,900 parts by mass, and still more preferably 100 parts by mass to 900 parts by mass with respect to 100 parts by mass of the solid content of the composition.

Photopolymerization Initiator

The composition preferably further includes a photopolymerization initiator.

Examples of the photopolymerization initiator include the photopolymerization initiators described in the above section of “Composition according to first embodiment”. A preferred aspect of the photopolymerization initiator is the same as the preferred aspect of the photopolymerization initiator described in the above section of “Composition according to first embodiment”.

The composition may include one kind or two or more kinds of photopolymerization initiators.

A content of the photopolymerization initiator is preferably 0.1% by mass to 20% by mass, more preferably 0.2% by mass to 15% by mass, and still more preferably 0.5% by mass to 10% by mass with respect to the total mass of the solid content of the composition.

Polymerizable Compound

The composition preferably further includes a polymerizable compound. Examples of the polymerizable compound include the polymerizable compounds described in the above section of “Composition according to first embodiment”. A preferred aspect of the polymerizable compound is the same as the preferred aspect of the polymerizable compound described in the above section of “Composition according to first embodiment”.

The composition may include one kind or two or more kinds of polymerizable compounds.

A content of the polymerizable compound is preferably 0.01% by mass to 90% by mass, more preferably 0.05% by mass to 85% by mass, and still more preferably 0.1% by mass to 80% by mass with respect to the total mass of the solid content of the composition.

Polymer

The composition preferably further includes a polymer. Examples of the polymer include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and acid anhydride. Examples of the polymer also include an alkali-soluble resin. Examples of the alkali-soluble resin include the alkali-soluble resins described in the above section of “Composition according to first embodiment”. A preferred aspect of the alkali-soluble resin is the same as the preferred aspect of the alkali-soluble resin described in the above section of “Composition according to first embodiment”.

The composition may include one kind or two or more kinds of polymers.

A content of the polymer is preferably 1% by mass to 90% by mass, more preferably 5% by mass to 80% by mass, and still more preferably 10% by mass to 70% by mass with respect to the total mass of the solid content of the composition.

Particles

The composition preferably further includes particles. Examples of the particles include metal oxide particles and metal particles.

The type of the metal oxide particles is not particularly limited, and examples thereof include known metal oxide particles. The metal of the metal oxide particles also includes semimetal such as B, Si, Ge, As, Sb, and Te.

Specifically, as the metal oxide particles, at least one selected from the group consisting of zirconium oxide particles (ZrO₂ particles), Nb₂O₅ particles, titanium oxide particles (TiO₂ particles), silicon dioxide particles (SiO₂ particles), and composite particles thereof is preferable. Among these, for example, from the viewpoint that it is easy to adjust the refractive index, the metal oxide particles are more preferably at least one selected from the group consisting of zirconium oxide particles and titanium oxide particles.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-530M, manufactured by Nissan Chemical Corporation), and zirconium oxide particles (NanoUse OZ-530K, manufactured by Nissan Chemical Corporation).

From the viewpoint of transparency of the cured film, for example, an average primary particle diameter of the particles is preferably 1 nm to 200 nm and more preferably 3 nm to 80 nm. The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

The particles may be used alone or in combination of two or more kinds thereof.

A content of the particles is preferably 1% by mass to 95% by mass, more preferably 20% by mass to 90% by mass, and still more preferably 40% by mass to 85% by mass with respect to the total mass of the solid content of the composition. In a case where titanium oxide is used as the metal oxide particles, the content of the titanium oxide particles is preferably 1% by mass to 95% by mass, more preferably 20% by mass to 90% by mass, and still more preferably 40% by mass to 85% by mass with respect to the total mass of the solid content of the composition.

Application

An application of the composition according to the second embodiment is not limited. Examples of the application of the composition according to the second embodiment include the applications described in the above section of “Composition according to first embodiment”. The composition may be used, for example, to form a refractive index adjusting layer.

Dried Product

Hereinafter, a dried product according to an embodiment of the present disclosure will be described. In one embodiment of the present disclosure, the dried product is a dried product of the composition according to the embodiments of the present disclosure. The dried product may be a dried product of the composition according to the first embodiment. The dried product may be a dried product of the composition according to the second embodiment.

A form of the dried product is not limited. The dried product may be a dry film.

The dried product is formed, for example, through drying of the composition. The dried product may be formed through application and drying of the composition.

In the present disclosure, the “drying” means removing at least a part of the solvent included in the object. Examples of the drying method include natural drying, heating drying, and drying under reduced pressure. Multiple drying methods may be combined. As a drying method, heat drying or vacuum drying is preferable.

Examples of an applying method include a printing method, a spray coating method, a roll coating method, a bar coating method, a curtain coating method, a spin coating method, and a die coating method (that is, a slit coating method).

Cured Substance

Hereinafter, a cured substance according to an embodiment of the present disclosure will be described. In one embodiment of the present disclosure, the cured substance is a cured substance of the composition according to the embodiments of the present disclosure. The cured substance may be a cured substance of the composition according to the first embodiment. The cured substance may be a cured substance of the composition according to the second embodiment.

A form of the cured substance is not limited. The cured substance may be a cured film.

The cured substance is formed, for example, through curing of the composition. The cured substance may be formed through drying and curing of the composition. The cured substance may be formed through application, drying, and curing of the composition.

Examples of a curing method include exposure. A light source may be selected from a known light source which irradiates the composition with light of a curable wavelength. Examples of the light source include various lasers, a light emitting diode (LED), an ultra-high pressure mercury lamp, a high pressure mercury lamp, and a metal halide lamp. The light irradiated to the composition preferably includes a wavelength of 365 nm or 405 nm. A main wavelength of the light irradiated to the composition is preferably 365 nm. The main wavelength is a wavelength having the highest intensity. An exposure amount is preferably 5 mJ/cm² to 200 mJ/cm² and more preferably 10 mJ/cm² to 200 mJ/cm².

Examples of a drying method include the drying method described in the above section of “Dried product”.

Examples of an applying method include the applying method described in the above section of “Dried product”.

Transfer Film

Hereinafter, a transfer film according to an embodiment of the present disclosure will be described. In one embodiment of the present disclosure, the transfer film includes a temporary support and the dried product of the composition according to the embodiments of the present disclosure.

Examples of a constitution of the transfer film are shown below. However, the constitution of the transfer film is not limited to the following specific examples.
(1) “temporary support/dried product of composition/refractive index adjusting layer/protective film”
(2) “temporary support/dried product of composition/protective film”
(3) “temporary support/interlayer/dried product of composition/protective film”
(4) “temporary support/thermoplastic resin layer/interlayer/dried product of composition/protective film”

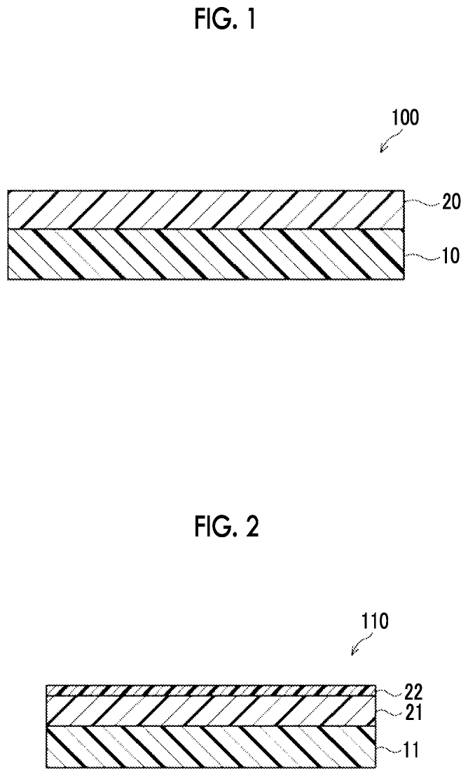

The transfer film will be described with reference to FIGS. 1 and 2. FIG. 1 is a schematic cross-sectional view showing a transfer film according to one embodiment. A transfer film 100 shown in FIG. 1 includes a temporary support 10 and a dried product 20 of a composition. FIG. 2 is a schematic cross-sectional view showing a transfer film according to another embodiment. A transfer film 110 shown in FIG. 2 includes a temporary support 11, a dried product 21 of a composition, and a dried product 22 of a composition. The dried product 21 of the composition is the dried product of the composition according to the first embodiment, and the dried product 22 of the composition may be the dried product of the composition according to the second embodiment.

Temporary Support

The transfer film includes a temporary support. The temporary support is a member which supports other constituent elements (for example, the dried product of the composition), and is finally removed by a peeling treatment.

The temporary support may be a monolayer structure or a multilayer structure.

The temporary support is preferably a film and more preferably a resin film. As the temporary support, a film which has flexibility and does not generate significant deformation, contraction, or stretching under pressure or under pressure and heating is preferable. Examples of the film include a polyethylene terephthalate film (for example, a biaxial stretching polyethylene terephthalate film), a polymethylmethacrylate film, a cellulose triacetate film, a polystyrene film, a polyimide film, and a polycarbonate film. As the temporary support, a polyethylene terephthalate film is preferable. In addition, it is preferable that the film used as the temporary support does not have deformation such as wrinkles or scratches.

From the viewpoint that pattern exposure through the temporary support can be performed, the temporary support preferably has high transparency, and the transmittance at 365 nm is preferably 60% or more and more preferably 70% or more.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of pattern formability during pattern exposure through the temporary support and transparency of the temporary support, it is preferable that the number of fine particles, foreign substances, and defects included in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is not particularly limited, but is preferably 5 μm to 200 μm. In addition, from the viewpoint of ease of handling and general-purpose properties, the thickness of the temporary support is more preferably 5 μm to 150 μm, still more preferably 5 μm to 50 μm, and most preferably 5 μm to 25 μm. The thickness of the temporary support is calculated as an average value of any five points measured by a cross-sectional observation with a scanning electron microscope (SEM).

In order to improve adhesiveness between the temporary support and a transfer layer, a surface of the temporary support in contact with the transfer layer may be surface-modified by ultraviolet irradiation, corona discharge, plasma, or the like. The transfer layer is a layer other than the temporary support, and means a layer disposed on the object in the process of using the transfer film, specifically, in the bonding of the transfer film and the object. Examples of the transfer layer include a dried product of the composition. On the other hand, the protective film described later is not included in the transfer layer.

In a case where the temporary support is surface-modified by ultraviolet irradiation, an exposure amount is preferably 10 mJ/cm² to 2000 mJ/cm² and more preferably 50 mJ/cm² to 1000 mJ/cm².

Examples of a light source for the ultraviolet irradiation include a low pressure mercury lamp, a high pressure mercury lamp, a ultra-high pressure mercury lamp, a carbon arc lamp, a metal halide lamp, a xenon lamp, a chemical lamp, an electrodeless discharge lamp, and a light emitting diode (LED), all of which emit a light in a wavelength range of 150 to 450 nm. As long as the amount of light irradiated is within the range, the lamp output or the illuminance is not particularly limited.

Examples of the temporary support include a biaxial stretching polyethylene terephthalate film having a film thickness of 16 μm, a biaxial stretching polyethylene terephthalate film having a film thickness of 12 μm, and a biaxial stretching polyethylene terephthalate film having a film thickness of 9 μm.

A preferred aspect of the temporary support is described in, for example, paragraphs [0017] and [0018] of JP2014-085643A, paragraphs [0019] to [0026] of JP2016-027363A, paragraphs [0041] to [0057] of WO2012/081680A, and paragraphs [0029] to [0040] of WO2018/179370A, the contents of which are incorporated herein by reference.

The temporary support may be a recycled product. Examples of the recycled product include films obtained cleaning used films and the like into chips and using the chips as a material. Specific examples of the recycled product include Ecouse (registered trademark) series manufactured by Toray Industries, Inc.

From the viewpoint of imparting handleability, a layer (lubricant layer) including fine particles may be provided on the surface of the temporary support. The lubricant layer may be provided on one surface of the temporary support, or on both surfaces thereof. A diameter of the particles included in the lubricant layer is preferably 0.05 μm to 0.8 μm. In addition, a film thickness of the lubricant layer is preferably 0.05 μm to 1.0 μm.

Examples of a commercially available product of the temporary support include LUMIRROR 16KS40 and LUMIRROR 16FB40 (all of which are manufactured by Toray Industries, Inc.), and COSMOSHINE A4100, COSMOSHINE A4160, COSMOSHINE A4300, COSMOSHINE A4360, and COSMOSHINE A8300 (all of which are manufactured by TOYOBO Co., Ltd.).

Dried Product of Composition

The transfer film includes a dried product of the composition according to the embodiment of the present disclosure. The dried product may be a dried product of the composition according to the first embodiment. The dried product of the composition according to the first embodiment may be adopted as a photosensitive layer. The dried product may be a dried product of the composition according to the second embodiment. The dried product of the composition according to the second embodiment may be adopted as a refractive index adjusting layer.

The transfer film may include the dried product of the composition according to the first embodiment and the dried product of the composition according to the second embodiment. Other constituent elements may be arranged between the dried product of the composition according to the first embodiment and the dried product of the composition according to the second embodiment. The transfer film may include the temporary support, the dried product of the composition according to the first embodiment, and the dried product of the composition according to the second embodiment in this order.

A thickness of the dried product of the composition according to the first embodiment is not particularly limited, but from the viewpoint that the effects of the present disclosure are more excellent, is often 30 μm or less, preferably 20 μm or less, more preferably 15 μm or less, still more preferably 10 μm or less, and particularly preferably 5.0 μm or less. From the viewpoint that hardness of a film obtained by curing the dried product is excellent, the lower limit is preferably 0.60 μm or more and more preferably 1.5 μm or more.

A thickness of the dried product of the composition according to the second embodiment is preferably 50 nm to 500 nm, more preferably 55 nm to 110 nm, and still more preferably 60 nm to 100 nm.

The thickness of the dried product is obtained as an average value of 5 random points measured by cross-sectional observation with a scanning electron microscope (SEM).

Photosensitive Layer

The transfer film may include a photosensitive layer. The transfer film may include the temporary support, the photosensitive layer, and the dried product of the composition according to the second embodiment in this order.

The photosensitive layer may be a known photosensitive layer. The photosensitive layer may be the dried product of the composition according to the first embodiment.

As the photosensitive layer, a negative tone photosensitive layer is preferable. The negative tone photosensitive layer is a layer in which solubility of an exposed portion in a developer is reduced due to exposure. In a case where the photosensitive layer is a negative tone photosensitive layer, the formed pattern corresponds to a cured layer.

Examples of components of the photosensitive layer include the components described in the above section of “Composition according to first embodiment”. The content of each component is adjusted by replacing the “total mass of the solid content of the composition” described in the above section of “Composition according to first embodiment” with “total mass of the photosensitive layer”.

A thickness of the photosensitive layer is not particularly limited, but from the viewpoint that the effects of the present disclosure are more excellent, is often 30 μm or less, preferably 20 μm or less, more preferably 15 μm or less, still more preferably 10 μm or less, and particularly preferably 5.0 μm or less. From the viewpoint that hardness of a film obtained by curing the dried product is excellent, the lower limit is preferably 0.60 μm or more and more preferably 1.5 μm or more. The thickness of the photosensitive layer is obtained as an average value of 5 random points measured by cross-sectional observation with a scanning electron microscope (SEM).

In the photosensitive layer, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in each layer. The content of these compounds in the photosensitive layer is preferably 100 ppm or less, more preferably 20 ppm or less, and particularly preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of reliability and laminating property, the content of water in the photosensitive layer is preferably 0.01% by mass to 1.0% by mass and more preferably 0.05% by mass to 0.5% by mass.

A refractive index of the photosensitive layer is preferably 1.41 to 1.59 and more preferably 1.47 to 1.56

A visible light transmittance of the photosensitive layer at a film thickness of approximately 1.0 μm is preferably 80% or more, more preferably 90% or more, and most preferably 95% or more. As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above. Examples of a preferred value of the transmittance include 87%, 92%, and 98%.

From the viewpoint of rust preventive property of electrode or wiring line, and viewpoint of device reliability, a moisture permeability of the pattern obtained by curing the photosensitive layer (cured film of the photosensitive layer) at a film thickness of 40 μm is preferably 500 g/m²·24 hr, more preferably 300 g/m²·24 hr, and still more preferably 100 g/m²·24 hr. The moisture permeability is measured with a cured film obtained by curing the photosensitive layer by exposing the photosensitive layer with i-rays at an exposure amount of 300 mJ/cm², and then performing post-baking at 145° C. for 30 minutes. The moisture permeability is measured according to a cup method of JIS Z0208. It is preferable that the above-described moisture permeability is as above under any test conditions of temperature 40° C. and humidity 90%, temperature 65° C. and humidity 90%, or temperature 80° C. and humidity 95%. Examples of a specific preferred numerical value include 80 g/m²·24 hr, 150 g/m²·24 hr, and 220 g/m²·24 hr.

From the viewpoint of suppressing residue during development, a dissolution rate of the photosensitive layer in a 1.0% by mass sodium carbonate aqueous solution is preferably 0.01 μm/sec or more, more preferably 0.10 μm/sec or more, and still more preferably 0.20 μm/sec or more. From the viewpoint of edge shape of the pattern, it is preferable to be 5.0 μm/sec or less, more preferable to be 4.0 μm/sec or less, and still more preferable to be 3.0 μm/sec or less. Examples of a specific preferred numerical value include 1.8 μm/sec, 1.0 μm/sec, and 0.7 μm/sec. The dissolution rate of the photosensitive layer in a 1.0% by mass sodium carbonate aqueous solution per unit time is measured as follows. A photosensitive layer (within a film thickness of 1.0 μm to 10 μm) formed on a glass substrate, from which the solvent has been sufficiently removed, is subjected to a shower development with a 1.0% by mass sodium carbonate aqueous solution at 25° C. until the photosensitive layer is dissolved completely (however, the maximum time is 2 minutes). The dissolution rate of the photosensitive layer is obtained by dividing the film thickness of the photosensitive layer by the time required for the photosensitive layer to dissolve completely. In a case where the photosensitive composition layer is not dissolved completely in 2 minutes, the dissolution rate of the photosensitive composition layer is calculated in the same manner as above, from the amount of change in film thickness up to 2 minutes. For development, a shower nozzle of 1/4 MiNJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

A dissolution rate of the cured film (within a film thickness of 1.0 to 10 μm) of the photosensitive layer in a 1.0% by mass sodium carbonate aqueous solution is preferably 3.0 μm/sec or less, more preferably 2.0 μm/sec or less, still more preferably 1.0 μm/sec or less, and most preferably 0.2 μm/sec or less. The cured film of the photosensitive layer is a film obtained by exposing the photosensitive layer with i-rays at an exposure amount of 300 mJ/cm². Examples of a specific preferred numerical value include 0.8 μm/sec, 0.2 μm/sec, and 0.001 μm/sec.

From the viewpoint of improving pattern formability, a swelling ratio of the photosensitive layer after exposure with respect to a 1.0% by mass sodium carbonate aqueous solution is preferably 100% or less, more preferably 50% or less, and still more preferably 30% or less. The swelling ratio of the photosensitive resin layer after exposure with respect to a 1.0% by mass sodium carbonate aqueous solution is measured as follows. A photosensitive resin layer (within a film thickness of 1.0 μm to 10 μm) formed on a glass substrate, from which the solvent has been sufficiently removed, is exposed at an exposure amount of 500 mJ/cm² (i-ray measurement) with an ultra-high pressure mercury lamp. The glass substrate is immersed in a 1.0% by mass sodium carbonate aqueous solution at 25° C., and the film thickness is measured after 30 seconds. Then, an increased proportion of the film thickness after immersion to the film thickness before immersion is calculated. Examples of a specific preferred numerical value include 4%, 13%, and 25%.

From the viewpoint of pattern formability, the number of foreign substances having a diameter of 1.0 μm or more in the photosensitive layer is preferably 10 pieces/mm² or less, and more preferably 5 pieces/mm² or less. The number of foreign substances is measured as follows. Any 5 regions (1 mm×1 mm) on a surface of the photosensitive layer are visually observed from a normal direction of the surface of the photosensitive layer with an optical microscope, the number of foreign substances having a diameter of 1.0 μm or more in each region is measured, and the values are arithmetically averaged to calculate the number of foreign substances. Examples of a specific preferred numerical value include 0 pieces/mm², 1 pieces/mm², 4 pieces/mm², and 8 pieces/mm².

From the viewpoint of suppressing generation of aggregates during development, a haze of a solution obtained by dissolving 1.0 cm³ of the photosensitive resin layer in 1.0 liter of a 1.0% by mass sodium carbonate aqueous solution at 30° C. is preferably 60% or less, more preferably 30% or less, still more preferably 10% or less, and most preferably 1% or less. The haze is measured as follows. First, a 1.0% by mass sodium carbonate aqueous solution is prepared, and a liquid temperature is adjusted to 30° C. 1.0 cm³ of the photosensitive resin layer is added to 1.0 L of the sodium carbonate aqueous solution. The solution is stirred at 30° C. for 4 hours, being careful not to mix air bubbles. After stirring, the haze of the solution in which the photosensitive resin layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm Examples of a specific preferred numerical value include 0.4%, 1.0%, 9%, and 24%.

Refractive Index Adjusting Layer

The transfer film may include a refractive index adjusting layer. The transfer film may include the temporary support, the dried product of the composition according to the first embodiment, and the refractive index adjusting layer in this order.

The refractive index adjusting layer may be a known refractive index adjusting layer. The refractive index adjusting layer may be the dried product of the composition according to the second embodiment.

Examples of components of the refractive index adjusting layer include the components described in the above section of “Composition according to second embodiment”. The content of each component is adjusted by replacing the “total mass of the solid content of the composition” described in the above section of “Composition according to second embodiment” with “total mass of the refractive index adjusting layer”. Examples of the components of the refractive index adjusting layer include a binder polymer and a metal salt.

Examples of a method for controlling a refractive index of the refractive index adjusting layer include a method using a resin having a predetermined refractive index alone, a method using a resin and particles, and a method using a composite body of a metal salt and a resin.

It is preferable that the refractive index of the refractive index adjusting layer is higher than the refractive index of the photosensitive layer. The refractive index of the refractive index adjusting layer is preferably 1.50 or more, more preferably 1.55 or more, still more preferably 1.60 or more, and particularly preferably 1.65 or more. The upper limit of the refractive index of the refractive index adjusting layer is preferably 2.10 or less, more preferably 1.85 or less, and still more preferably 1.78 or less.

A thickness of the refractive index adjusting layer is preferably 50 nm to 500 nm, more preferably 55 nm to 110 nm, and still more preferably 60 nm to 100 nm. The thickness of the refractive index adjusting layer is obtained as an average value of 5 random points measured by cross-sectional observation with a scanning electron microscope (SEM).

Protective Film

The transfer film may include a protective film. The transfer film may include the temporary support, the dried product of the composition according to the embodiment of the present disclosure, and the protective film in this order.

Examples of the protective film include a resin film having heat resistance and solvent resistance. Examples of the protective film include polyolefin films such as a polypropylene film and a polyethylene film, polyester films such as a polyethylene terephthalate film, polycarbonate films, and polystyrene films. In addition, as the protective film, a resin film formed of the same material as in the above-described temporary support may be used. As the protective film, a polyolefin film is preferable, a polypropylene film or a polyethylene film is more preferable, and a polyethylene film is still more preferable.

A thickness of the protective film is preferably 1 μm to 100 μm, more preferably 5 μm to 50 μm, still more preferably 5 μm to 40 μm, and particularly preferably 15 μm to 30 μm. From the viewpoint of excellent mechanical hardness, the thickness of the protective film is preferably 1 μm or more, and from the viewpoint of relatively low cost, the thickness of the protective film is preferably 100 μm or less.

The number of fisheyes with a diameter of 80 μm or more in the protective film is preferably 5 pieces/m² or less. The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles included in the protective film being transferred to the photosensitive layer or a conductive layer.

From the viewpoint of imparting take-up property, in the protective film, an arithmetic average roughness Ra on a surface opposite to a surface in contact with the transfer layer is preferably 0.01 μm or more, more preferably 0.02 μm or more, and still more preferably 0.03 μm or more. On the other hand, it is preferable to be less than 0.50 μm, more preferable to be 0.40 μm or less, and still more preferable to be 0.30 μm or less.

From the viewpoint of suppressing defects during transfer, a surface roughness Ra of the protective film on the surface in contact with the transfer layer is preferably 0.01 μm or more, more preferably 0.02 μm or more, and still more preferably 0.03 μm or more. On the other hand, it is preferable to be less than 0.50 μm, more preferable to be 0.40 μm or less, and still more preferable to be 0.30 μm or less.

Thermoplastic Resin Layer

The transfer film may include a thermoplastic resin layer. The transfer film may include the temporary support, the thermoplastic resin layer, and the dried product of the composition according to the embodiment of the present disclosure in this order. The transfer film may include the temporary support, the thermoplastic resin layer, the dried product of the composition according to the first embodiment, and the dried product of the composition according to the second embodiment in this order.

Thermoplastic Resin

The thermoplastic resin layer includes a thermoplastic resin. As the thermoplastic resin, an alkali-soluble resin is preferable. Examples of the alkali-soluble resin include an acrylic resin, a polystyrene resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, a polyethyleneimine, a polyallylamine, and a polyalkylene glycol.

As the alkali-soluble resin, from the viewpoint of developability and adhesiveness to an adjacent layer, an acrylic resin is preferable. Here, the acrylic resin means a resin having at least one constitutional unit selected from the group consisting of a constitutional unit derived from (meth)acrylic acid, a constitutional unit derived from (meth)acrylic acid ester, and a constitutional unit derived from (meth)acrylic acid amide. As the acrylic resin, it is preferable that the total content of the constitutional unit derived from (meth)acrylic acid, the constitutional unit derived from (meth)acrylic acid ester, and the constitutional unit derived from (meth)acrylic acid amide is 50% by mass or more with respect to the total mass of the acrylic resin. Among these, the total content of the constitutional unit derived from (meth)acrylic acid and the constitutional unit derived from (meth)acrylic acid ester is preferably 30% by mass to 100% by mass and more preferably 50% by mass to 100% by mass with respect to the total mass of the acrylic resin.

The alkali-soluble resin is preferably a polymer having an acid group. Examples of the acid group include a carboxy group, a sulfo group, a phosphonic acid group, and a phosphoric acid group, and a carboxy group is preferable.

As the alkali-soluble resin, from the viewpoint of developability, an alkali-soluble resin having an acid value of 60 mgKOH/g or more is more preferable, and a carboxy group-containing acrylic resin having an acid value of 60 mgKOH/g or more is still more preferable. The upper limit of the acid value of the alkali-soluble resin is not particularly limited, but is preferably 300 mgKOH/g or less, more preferably 250 mgKOH/g or less, still more preferably 200 mgKOH/g or less, and particularly preferably 150 mgKOH/g or less.

The carboxy group-containing acrylic resin having an acid value of 60 mgKOH/g or more is not particularly limited, and can be appropriately selected and used from a known resin. Examples thereof include an alkali-soluble resin which is a carboxy group-containing acrylic resin having an acid value of 60 mgKOH/g or more among polymers described in paragraph [0025] of JP2011-095716A, a carboxy group-containing acrylic resin having an acid value of 60 mgKOH/g or more among polymers described in paragraphs [0033] to [0052] of JP2010-237589A, and a carboxy group-containing acrylic resin having an acid value of 60 mgKOH/g or more among binder polymers described in paragraphs [0053] to [0068] of JP2016-224162A.

A copolymerization ratio of the constitutional unit having a carboxy group in the carboxy group-containing acrylic resin is preferably 5% by mass to 50% by mass, more preferably 10% by mass to 40% by mass, and still more preferably 12% by mass to 30% by mass with respect to the total mass of the acrylic resin.

As the alkali-soluble resin, from the viewpoint of developability and adhesiveness to an adjacent layer, an acrylic resin having a constitutional unit derived from (meth)acrylic acid is particularly preferable.

The alkali-soluble resin may have a reactive group. The reactive group may be any addition-polymerizable group, and examples thereof include an ethylenically unsaturated group; a polycondensable group such as a hydroxy group and a carboxy group; and a polyaddition reactive group such as an epoxy group and a (blocked) isocyanate group.

A weight-average molecular weight (Mw) of the alkali-soluble resin is preferably 1,000 or more, more preferably 10,000 to 100,000, and still more preferably 20,000 to 50,000.

The alkali-soluble resin may be used alone, or in combination of two or more kinds thereof.

From the viewpoint of developability and adhesiveness to an adjacent layer, a content of the alkali-soluble resin is preferably 10% by mass to 99% by mass, more preferably 20% by mass to 90% by mass, still more preferably 40% by mass to 80% by mass, and particularly preferably 50% by mass to 75% by mass with respect to the total mass of the thermoplastic resin layer.

Coloring Agent

The thermoplastic resin layer preferably includes a coloring agent (also simply referred to as a “coloring agent B”) in which a maximal absorption wavelength in a wavelength range of 400 nm to 780 nm during color development is 450 nm or more, and the maximal absorption wavelength changes depending on an acid, a base, or a radical. The “maximal absorption wavelength changes depending on an acid, a base, or a radical” may mean any aspect of an aspect in which a coloring agent in a color developing state is decolorized by the acid, the base, or the radical, an aspect in which a coloring agent in a decolorized state develops color by the acid, the base, or the radical, or an aspect in which a coloring agent in a color developing state changes to a color developing state of another color tone.

Specifically, the coloring agent B may be a compound which develops color by changing a state from the decolorized state due to exposure, or may be a compound which is decolorized by changing a state from the color developing state due to exposure. A coloring agent in which the color developing or decolorized state changes by generating the acid, the base, or the radical in the thermoplastic resin layer due to exposure may be used, or a coloring agent in which the color developing or decolorized state changes by changing a condition (for example, pH) in the thermoplastic resin layer due to the acid, the base, or the radical may be used. In addition, a coloring agent in which the color developing or decolorized state changes by directly receiving the acid, the base, or the radical as a stimulus without exposure.

As the coloring agent B, from the viewpoint of visibility and resolution of the exposed portion and non-exposed portion, a coloring agent in which the maximal absorption wavelength changes by an acid or a radical is preferable, and a coloring agent in which the maximal absorption wavelength changes by an acid is more preferable.

From the viewpoint of visibility and resolution of the exposed portion and non-exposed portion, it is preferable that the thermoplastic resin layer includes, as the coloring agent B, a coloring agent in which the maximal absorption wavelength changes by an acid, and includes a compound which generates an acid with light, which will be described later.

From the viewpoint of visibility of the exposed portion and non-exposed portion, the maximal absorption wavelength of the coloring agent B in a wavelength range of 400 nm to 780 nm during color development is preferably 550 nm or more, more preferably 550 nm to 700 nm, and still more preferably 550 nm to 650 nm.

In addition, the coloring agent B may have only one maximal absorption wavelength in the wavelength range of 400 nm to 780 nm during color development, or may have two or more thereof. In a case where the coloring agent B has two or more maximal absorption wavelengths in the wavelength range of 400 nm to 780 nm during color development, it is sufficient that the maximal absorption wavelength having the highest absorbance in the two or more maximal absorption wavelengths is 450 nm or more.

The maximal absorption wavelength of the coloring agent B is obtained by measuring a transmission spectrum of a solution including the coloring agent B (solution temperature: 25° C.) in a range of 400 nm to 780 nm using a spectrophotometer UV3100 (manufactured by Shimadzu Corporation), and detecting a wavelength (maximal absorption wavelength) at which the intensity of light is minimal.

Examples of the coloring agent which develops or is decolorized by exposure include a leuco compound. Examples of the coloring agent which is decolorized by exposure include a leuco compound, a diarylmethane-based coloring agent, an oxazine-based coloring agent, a xanthene-based coloring agent, an iminonaphthoquinone-based coloring agent, an azomethine-based coloring agent, and an anthraquinone-based coloring agent. As the coloring agent B, from the viewpoint of visibility of the exposed portion and non-exposed portion, a leuco compound is preferable.

Examples of the leuco compound include a leuco compound having a triarylmethane skeleton (triarylmethane-based coloring agent), a leuco compound having a spiropyran skeleton (spiropyran-based coloring agent), a leuco compound having a fluorane skeleton (fluorane-based coloring agent), a leuco compound having a diarylmethane skeleton (diarylmethane-based coloring agent), a leuco compound having a lodamine lactam skeleton (lodamine lactam-based coloring agent), a leuco compound having an indolylphthalide skeleton (indolylphthalide-based coloring agent), and a leuco compound having a leuco auramine skeleton (leuco auramine-based coloring agent). Among these, a triarylmethane-based coloring agent or a fluorane-based coloring agent is preferable, and a leuco compound having a triarylmethane skeleton (triarylmethane-based coloring agent) or a fluorane-based coloring agent is more preferable.

As the leuco compound, from the viewpoint of visibility of the exposed portion and non-exposed portion, it is preferable to have a lactone ring, a sultine ring, or a sultone ring. As a result, by reacting the lactone ring, sultine ring, or sultone ring included in the leuco compound with the radical generated from the photoradical polymerization initiator or the acid generated with the photocationic polymerization initiator, the leuco compound can be changed to a ring-linked state to be decolorized, or the leuco compound can be changed to a ring-opening state to be colored. As the leuco compound, a compound which has a lactone ring, a sultine ring, or a sultone ring, in which the lactone ring, sultine ring, or sultone ring is opened by a radical or an acid to develop color, is preferable, and a compound which has a lactone ring, in which the lactone ring is opened by a radical or an acid to develop color, is more preferable.

Specific examples of the leuco compound include p,p′,p″-hexamethyltriaminotriphenylmethane (Leuco Crystal Violet), Pergascript Blue SRB (manufactured by Ciba Geigy), Crystal Violet Lactone, Malachite Green Lactone, Benzoyl Leuco Methylene Blue, 2-(N-phenyl-N-methylamino)-6-(N-p-tolyl-N-ethyl)aminofluorane, 2-anilino-3-methyl-6-(N-ethyl-p-toluidino)fluorane, 3,6-dimethoxyfluorane, 3-(N,N-diethylamino)-5-methyl-7-(N,N-dibenzylamino)fluorane, 3-(N-cyclohexyl-N-methylamino)-6-methyl-7-anilinofluorane, 3-(N,N-diethylamino)-6-methyl-7-anilinofluorane, 3-(N,N-diethylamino)-6-methyl-7-xylidinofluorane, 3-(N,N-diethylamino)-6-methyl-7-chlorofluorane, 3-(N,N-diethylamino)-6-methoxy-7-aminofluorane, 3-(N,N-diethylamino)-7-(4-chloroanilino)fluorane, 3-(N,N-diethylamino)-7-chlorofluorane, 3-(N,N-diethylamino)-7-benzylaminofluorane, 3-(N,N-diethylamino)-7,8-benzofluorane, 3-(N,N-dibutylamino)-6-methyl-7-anilinofluorane, 3-(N,N-dibutylamino)-6-methyl-7-xylidinofluorane, 3-piperidino-6-methyl-7-anilinofluorane, 3-pyrrolidino-6-methyl-7-anilinofluorane, 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-phthalide, 3-(4-diethylaminophenyl)-3-(1-ethyl-2-methylindol-3-yl)phthalide,3′,6′-bis(diphenylamino)spiroisobenzofuran-1(3H), and 9′-[9H]xanthen-3-one.

The coloring agent B may be a dye. Specific examples of the dye include Brilliant Green, Ethyl Violet, Methyl Green, Crystal Violet, Basic Fuchsin, Methyl Violet 2B, Quinaldine Red, Rose Bengale, Metanil Yellow, Thymolsulfonphthalein, Xylenol Blue, Methyl Orange, Paramethyl Red, Congo Red, Benzopurpurine 4B, α-Naphthyl Red, Nile Blue 2B, Nile Blue A, Methyl Violet, Malachite Green, Parafuchsin, Victoria Pure Blue-naphthalene sulfonate, Victoria Pure Blue BOH (manufactured by Hodogaya Chemical Co., Ltd.), Oil Blue #603 (manufactured by Orient Chemical Industry Co., Ltd.), Oil Pink #312 (manufactured by Orient Chemical Industry Co., Ltd.), Oil Red 5B (manufactured by Orient Chemical Industry Co., Ltd.), Oil Scarlet #308 (manufactured by Orient Chemical Industry Co., Ltd.), Oil Red OG (manufactured by Orient Chemical Industry Co., Ltd.), Oil Red RR) manufactured by Orient Chemical Industry Co., Ltd.), Oil Green #502 (manufactured by Orient Chemical Industry Co., Ltd.), Spiron Red BEH Special (manufactured by Hodogaya Chemical Co., Ltd.), m-Cresol Purple, Cresol Red, Rhodamine B, Rhodamine 6G, Sulforhodamine B, Auramine, 4-p-diethylaminophenyliminonaphthoquinone, 2-carboxyanilino-4-p-diethylaminophenyliminonaphthoquinone, 2-carboxystearylamino-4-p-N,N-bis(hydroxyethyl)aminophenyliminonaphthoquinone, 1-phenyl-3-methyl-4-p-diethylaminophenylimino-5-pyrazolone, and 1-β-naphthyl-4-p-diethylaminophenylimino-5-pyrazolone.

As the coloring agent B, Leuco Crystal Violet, Crystal Violet Lactone, Brilliant Green, or Victoria Pure Blue-naphthalene sulfonate is preferable.

The coloring agent B may be used alone, or in combination of two or more kinds thereof.

From the viewpoint of visibility of the exposed portion and non-exposed portion, a content of the coloring agent B is preferably 0.2% by mass or more, more preferably 0.2% by mass to 6% by mass, still more preferably 0.2% by mass to 5% by mass, and particularly preferably 0.25% by mass to 3.0% by mass with respect to the total mass of the thermoplastic resin layer.

Here, the content of the coloring agent B means the content of coloring agent in a case where all of the coloring agents B included in the thermoplastic resin layer is in a color developing state. Hereinafter, a method for quantifying the content of the coloring agent B will be described by taking a coloring agent which develops color by a radical as an example. A solution in which 0.001 g of the coloring agent is dissolved in 100 mL of methyl ethyl ketone and a solution in which 0.01 g of the coloring agent is dissolved in 100 mL of methyl ethyl ketone are prepared. A photoradical polymerization initiator Irgacure OXE01 (product name, BASF Japan) is added to each of the obtained solutions, and radicals are generated by irradiating the solutions with light of 365 nm to bring all the coloring agents into a color developing state. Thereafter, in an atmospheric atmosphere, an absorbance of each solution having a solution temperature of 25° C. is measured using a spectrophotometer (UV3100, manufactured by Shimadzu Corporation) to create a calibration curve. Next, in the same manner as described above except that, instead of the coloring agent, 0.1 g of thermoplastic resin layer is dissolved in methyl ethyl ketone, an absorbance of the solution in which all the coloring agents develop color is measured. From the absorbance of the obtained solution including the thermoplastic resin layer, the amount of the coloring agent included in the thermoplastic resin layer is calculated based on the calibration curve.

Compound which Generates Acid, Base, or Radical with Light

The thermoplastic resin layer may include a compound (also simply referred to as a “compound C”) which generates an acid, a base, or a radical with light.

As the compound C, a compound which receives an actinic ray such as ultraviolet rays and visible rays to generate an acid, a base, or a radical is preferable. As the compound C, a known photoacid generator, photobase generator, and photoradical generator can be used.

Photoacid Generator

Examples of the photoacid generator include a photocationic polymerization initiator.

The photocationic polymerization initiator is a compound which receives actinic ray to generate an acid. The photocationic polymerization initiator is preferably a compound which is sensitive to actinic ray having a wavelength of 300 nm or more, preferably 300 nm to 450 nm, and generates an acid, and a chemical structure thereof is not limited. A photocationic polymerization initiator which is not directly sensitive to actinic ray having a wavelength of 300 nm or more can also be preferably used in combination with a sensitizer as long as it is a compound which is sensitive to actinic ray having a wavelength of 300 nm or more and generates an acid by being used in combination with the sensitizer.

As the photocationic polymerization initiator, a photocationic polymerization initiator which generates an acid having a pKa of 4 or less is preferable, a photocationic polymerization initiator which generates an acid having a pKa of 3 or less is more preferable, and a photocationic polymerization initiator which generates an acid having a pKa of 2 or less is particularly preferable. The lower limit value of the pKa is not particularly limited, but is preferably −10.0 or more.

Examples of the photocationic polymerization initiator include an ionic photocationic polymerization initiator and a nonionic photocationic polymerization initiator.

Examples of the ionic photocationic polymerization initiator include onium salt compounds such as diaryliodonium salts and triarylsulfonium salts, and quaternary ammonium salts. As the ionic photocationic polymerization initiator, ionic photocationic polymerization initiators described in paragraphs [0114] to [0133] of JP2014-085643A may be used.

Examples of the nonionic photocationic polymerization initiator include trichloromethyl-s-triazines, a diazomethane compound, an imide sulfonate compound, and an oxime sulfonate compound. As the trichloromethyl-s-triazines, the diazomethane compound, and the imide sulfonate compound, compounds described in paragraphs [0083] to [0088] of JP2011-221494A may be used. In addition, as the oxime sulfonate compound, compounds described in paragraphs [0084] to [0088] of WO2018/179640A may be used.

From the viewpoint of sensitivity and resolution, the photoacid generator preferably includes at least one compound selected from the group consisting of an onium salt compound and an oxime sulfonate compound, and from the viewpoint of sensitivity, resolution, and adhesiveness, more preferably include an oxime sulfonate compound.

In addition, as the photoacid generator, a photoacid generator having the following structure is also preferable.

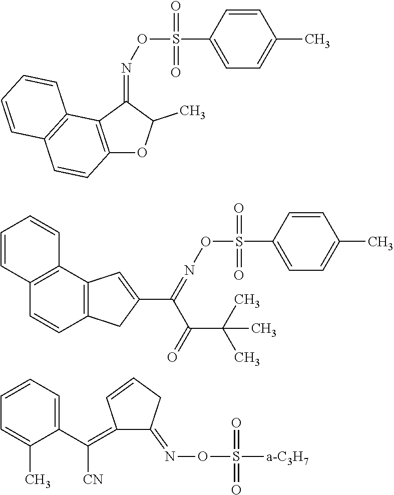

Photobase Generator

The photobase generator is not particularly limited as long as it is a known photobase generator, and examples thereof include 2-nitrobenzylcyclohexylcarbamate, triphenylmethanol, O-carbamoylhydroxylamide, 0-carbamoyloxime, [[(2,6-dinitrobenzyl)oxy]carbonyl]cyclohexylamine, bis[[(2-nitrobenzyl)oxy]carbonyl]hexane 1,6-diamine, 4-(methylthiobenzoyl)-1-methyl-1-morpholinoethane, (4-morpholinobenzoyl)-1-benzyl-1-dimethylaminopropane, N-(2-nitrobenzyloxycarbonyl)pyrrolidine, hexaamminecobalt (III) tris(triphenylmethylborate), 2-benzyl-2-dimethylamino-1-(4-morpholinophenyl)-butanone, 2,6-dimethyl-3,5-diacetyl-4-(2-nitrophenyl)-1,4-dihydropyridine, and 2,6-dimethyl-3,5-diacetyl-4-(2,4-dinitrophenyl)-1,4-dihydropyridine.

Photoradical Generator

Examples of the photoradical generator include a photoradical polymerization initiator.

Examples of the photoradical polymerization initiator include a photopolymerization initiator having an oxime ester structure, a photopolymerization initiator having an α-aminoalkylphenone structure, a photopolymerization initiator having an α-hydroxyalkylphenone structure, a photopolymerization initiator having an acylphosphine oxide structure, and a photopolymerization initiator having an N-phenylglycine structure.

The photoradical polymerization initiator preferably includes at least one selected from the group consisting of a 2,4,5-triarylimidazole dimer and a derivative thereof. Two 2,4,5-triarylimidazole structures in the 2,4,5-triarylimidazole dimer and a derivative thereof may be the same or different from each other. Examples of the derivative of the 2,4,5-triarylimidazole dimer include a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, a 2-(o-methoxyphenyl)-4,5-diphenylimidazole dimer, and a 2-(p-methoxyphenyl)-4,5-diphenylimidazole dimer.

As the photoradical polymerization initiator, for example, polymerization initiators described in paragraphs [0031] to [0042] of JP2011-95716A and paragraphs [0064] to [0081] of JP2015-14783A may be used.

Examples of the photoradical polymerization initiator include dimethylaminobenzoate (DBE, CAS No. 10287-53-3), benzoin methyl ether, anisyl (p,p′-dimethoxybenzyl), TAZ-110 (product name; manufactured by Midori Kagaku Co., Ltd.), benzophenone, 4,4′-bis(diethylamino)benzophenone, TAZ-111 (product name; manufactured by Midori Kagaku Co., Ltd.), Irgacure OXE01, OXE02, OXE03, and OXE04 (manufactured by BASF SE), Omnirad 651 and 369 (product name; manufactured by IGM Resins B.V.), and 2,2′-bis(2-chlorophenyl)-4,4′,5,5′-tetraphenyl-1,2′-biimidazole (manufactured by Tokyo Chemical Industry Co., Ltd.).

Examples of a commercially available product of the photoradical polymerization initiator include 1-[4-(phenylthio)phenyl]-1,2-octanedione-2-(O-benzoyloxime) (product name: IRGACURE (registered trademark) OXE-01, manufactured by BASF SE), 1-[9-ethyl-6-(2-methylbenzoyl)-9H-carbazol-3-yl]ethanone-1-(O-acetyloxime) (product name: IRGACURE OXE-02, manufactured by BASF SE), IRGACURE OXE-03 (manufactured by BASF SE), IRGACURE OXE-04 (manufactured by BASF SE), 2-(dimethylamino)-2-[4-methylphenyl)methyl]-1-[4-(4-morpholinyl)phenyl]-1-butanone (product name: Omnirad 379EG, manufactured by IGM Resins B.V.), 2-methyl-1-(4-methylthiophenyl)-2-morpholinopropan-1-one (product name: Omnirad 907, manufactured by IGM Resins B.V.), 2-hydroxy-1-{4-[4-(2-hydroxy-2-methylpropionyl)benzyl]phenyl}-2-methylpropan-1-one (product name: Omnirad 127, manufactured by IGM Resins B.V.), 2-benzyl-2-dimethylamino-1-(4-morpholinophenyl)butanone-1 (product name: Omnirad 369, manufactured by IGM Resins B.V.), 2-hydroxy-2-methyl-1-phenylpropan-1-one (product name: Omnirad 1173, manufactured by IGM Resins B.V.), 1-hydroxy cyclohexyl phenyl ketone (product name: Omnirad 184, manufactured by IGM Resins B.V.), 2,2-dimethoxy-1,2-diphenylethan-1-one (product name: Omnirad 651, manufactured by IGM Resins B.V.), 2,4,6-trimethylbenzoyl-diphenylphosphine oxide (product name: Omnirad TPO H, manufactured by IGM Resins B.V.), bis(2,4,6-trimethylbenzoyl)phenylphosphine oxide (product name: Omnirad 819, manufactured IGM Resins B.V.), oxime ester-based photopolymerization initiator (product name: Lunar 6, manufactured by DKSH Management Ltd.), 2,2′-bis(2-chlorophenyl)-4,4′,5,5′-tetraphenylbisimidazole (2-(2-chlorophenyl)-4,5-diphenylimidazole dimer) (product name: B-CIM, manufactured by Hampford Research Inc.), 2-(o-chlorophenyl)-4,5-diphenylimidazole dimer (product name: BCTB, manufactured by Tokyo Chemical Industry Co., Ltd.), 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by TRONLY), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY).

The compound C may be used alone, or in combination of two or more kinds thereof.

From the viewpoint of visibility and resolution of the exposed portion and non-exposed portion, a content of the compound C is preferably 0.1% by mass to 10% by mass and more preferably 0.5% by mass to 5% by mass with respect to the total mass of the thermoplastic resin layer.

Plasticizer

From the viewpoint of resolution, adhesiveness to an adjacent layer, and developability, the thermoplastic resin layer preferably includes a plasticizer.

The plasticizer preferably has a smaller molecular weight (in a case of being an oligomer or polymer and having a molecular weight distribution, weight-average molecular weight) than the alkali-soluble resin. The molecular weight (weight-average molecular weight) of the plasticizer is preferably 200 to 2,000.

The plasticizer is not particularly limited as long as it is compatible with the alkali-soluble resin and exhibits plasticity, but from the viewpoint of applying plasticity, the plasticizer preferably has an alkyleneoxy group in the molecule, and is more preferably a polyalkylene glycol compound. It is more preferable that the alkyleneoxy group included in the plasticizer has a polyethyleneoxy structure or a polypropyleneoxy structure.

In addition, from the viewpoint of resolution and storage stability, the plasticizer preferably includes a (meth)acrylate compound. From the viewpoint of compatibility, resolution, and adhesiveness to an adjacent layer, it is more preferable that the alkali-soluble resin is an acrylic resin and the plasticizer includes a (meth)acrylate compound.

In a case where the thermoplastic resin layer includes a (meth)acrylate compound as the plasticizer, from the viewpoint of adhesiveness of the thermoplastic resin layer to an adjacent layer, it is preferable that the (meth)acrylate compound does not polymerize even in the exposed portion after exposure.

As the (meth)acrylate compound used as the plasticizer, from the viewpoint of resolution, adhesiveness to an adjacent layer, and developability of the thermoplastic resin layer, a polyfunctional (meth)acrylate compound having two or more (meth)acryloyl groups in one molecule is preferable.

As the (meth)acrylate compound used as the plasticizer, a (meth)acrylate compound having an acid group or a urethane (meth)acrylate compound is also preferable.

The plasticizer may be used alone, or in combination of two or more kinds thereof.

From the viewpoint of resolution, adhesiveness to an adjacent layer, and developability of the thermoplastic resin layer, a content of the plasticizer is preferably 1% by mass to 70% by mass, more preferably 10% by mass to 60% by mass, and still more preferably 20% by mass to 50% by mass with respect to the total mass of the thermoplastic resin layer.

Sensitizer

The thermoplastic resin layer may include a sensitizer.

Examples of the sensitizer include a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound (for example, 1,2,4-triazole), stilbene compound, a triazine compound, a thiophene compound, a naphthalimide compound, a triarylamine compound, and an aminoacridine compound.

The sensitizer may be used alone, or in combination of two or more kinds thereof.

A content of the sensitizer can be appropriately selected according to the purpose, but from the viewpoint of improvement of sensitivity to the light source and visibility of the exposed portion and non-exposed portion, the content is preferably 0.01% by mass to 5% by mass and more preferably 0.05% by mass to 1% by mass with respect to the total mass of the thermoplastic resin layer.

Additive

The thermoplastic resin layer may include a known additive such as a surfactant as necessary.

The thermoplastic resin layer is described in paragraphs [0189] to [0193] of JP2014-085643A, and the contents described in this publication are incorporated herein by reference.

A thickness of the thermoplastic resin layer is not particularly limited, but from the viewpoint of adhesiveness to an adjacent layer, is preferably 1 μm or more and more preferably 2 μm or more. The upper limit is not particularly limited, but from the viewpoint of developability and resolution, 20 μm or less is preferable, 10 μm or less is more preferable, and 8 μm or less is still more preferable.

Interlayer

The transfer film may include an interlayer. The interlayer is preferably disposed between the thermoplastic resin layer and the dried product of the composition.

Examples of the interlayer include an oxygen blocking layer having an oxygen blocking function, which is described as an “separation layer” in JP1993-072724A (JP-H5-072724A). In a case where the interlayer is an oxygen blocking layer, the sensitivity during exposure is improved, the time load of the exposure machine is reduced, and the productivity is improved. The oxygen blocking layer used as the interlayer may be appropriately selected from a known layer described in the above-described publication and the like. An oxygen blocking layer which exhibits low oxygen permeability and dispersed and is dispersed or dissolved in water or an alkali aqueous solution (1% by mass aqueous solution of sodium carbonate at 22° C.) is preferable.

Examples of the interlayer include a water-soluble resin layer including a water-soluble resin.

Examples of the water-soluble resin include resins such as a polyvinyl alcohol-based resin, a polyvinylpyrrolidone-based resin, a cellulose-based resin, an acrylamide-based resin, a polyethylene oxide-based resin, gelatin, a vinyl ether-based resin, a polyamide resin, and a copolymer thereof. In addition, as the water-soluble resin, a copolymer of (meth)acrylic acid/vinyl compound, or the like can also be used. As the copolymer of (meth)acrylic acid/vinyl compound, a copolymer of (meth)acrylic acid/allyl (meth)acrylic acid is preferable, and a copolymer of methacrylic acid/allyl methacrylate is more preferable. In a case where the water-soluble resin is a copolymer of (meth)acrylic acid/vinyl compound, for example, a compositional ratio (mol %) of each component is preferably 90/10 to 20/80 and more preferably 80/20 to 30/70.

The lower limit value of the weight-average molecular weight of the water-soluble resin is preferably 5,000 or more, more preferably 7,000 or more, and still more preferably 10,000 or more. In addition, the upper limit value thereof is preferably 200,000 or less, more preferably 100,000 or less, and still more preferably 50,000 or less. A dispersity (Mw/Mn) of the water-soluble resin is preferably 1 to 10 and more preferably 1 to 5.

From the viewpoint of further improving interlayer mixing inhibitory ability of the water-soluble resin layer (interlayer), it is preferable that the resin in the water-soluble resin layer (interlayer) is a resin different from the resin included in the layer disposed on one surface side of the water-soluble resin layer (interlayer) and the resin included in the layer disposed on the other surface side.

From the viewpoint of further improving oxygen blocking property and interlayer mixing inhibitory ability, the water-soluble resin preferably includes polyvinyl alcohol, and more preferably includes both polyvinyl alcohol and polyvinylpyrrolidone.

The water-soluble resin may be used alone, or in combination of two or more kinds thereof.

A content of the water-soluble resin is not particularly limited, but from the viewpoint of further improving oxygen blocking property and interlayer mixing inhibitory ability, the content is preferably 50% by mass or more, more preferably 70% by mass or more, still more preferably 80% by mass or more, and particularly preferably 90% by mass or more with respect to the total mass of the water-soluble resin layer (interlayer). The upper limit value thereof is not particularly limited, and for example, 99.9% by mass or less is preferable and 99.8% by mass or less is still more preferable.

The interlayer may include a known additive such as a surfactant as necessary.

A thickness of the water-soluble resin layer (interlayer) is not particularly limited, but is preferably 0.1 μm to 5 μm and more preferably 0.5 μm to 3 μm. In a case where the thickness of the water-soluble resin layer (interlayer) is within the above-described range, the interlayer mixing inhibitory ability is excellent without reducing the oxygen blocking property. In addition, it is also possible to suppress an increase in time for removing the water-soluble resin layer (interlayer) during development.

Manufacturing Method of Transfer Film

A manufacturing method of the transfer film is not limited. The manufacturing method of the transfer film preferably includes, in the following order, applying the composition according to the embodiment of the present disclosure to the temporary support, and drying the composition.

Examples of an applying method include a printing method, a spray coating method, a roll coating method, a bar coating method, a curtain coating method, a spin coating method, and a die coating method (that is, a slit coating method).

Examples of the drying method include natural drying, heating drying, and drying under reduced pressure. Multiple drying methods may be combined. As a drying method, heat drying or vacuum drying is preferable.

In the manufacturing method of the transfer film, a roll-shaped transfer film may be manufactured. The transfer film may be stored in a roll form.

The manufacturing method of the transfer film will be described with reference to FIGS. 1 and 2. In the manufacturing method of the transfer film 100 shown in FIG. 1, the dried product 20 of the composition is formed through applying the composition to the temporary support 10 and drying the composition. In the manufacturing method of the transfer film 110 shown in FIG. 2, the dried product 21 of the composition is formed through applying the composition to the temporary support 11 and drying the composition, and the dried product 22 of the composition is formed through applying the composition to the dried product 21 of the composition and drying the composition.

As long as a transfer film having a desired structure can be obtained, the transfer film may be manufactured by a method other than the above-described method. The manufacturing method of the transfer film may include, in the following order, applying the composition according to the embodiment of the present disclosure to a protective film, drying the composition, and disposing the temporary support on the dried product of the composition.

Pattern Forming Method

Hereinafter, a pattern forming method according to an embodiment of the present disclosure will be described. In one embodiment of the present disclosure, the pattern forming method includes, in the following order, preparing a laminate including a base material and a dried product of the composition according to the embodiment of the present disclosure (hereinafter, may be referred to as a “preparing step”), exposing the dried product in a patterned manner (hereinafter, may be referred to as an “exposing step”), and developing the dried product using a developer to form a resin pattern (hereinafter, may be referred to as a “developing step”).

Preparing Step

In the preparing step, a laminate including a base material and a dried product of the composition according to the embodiment of the present disclosure is prepared.

Examples of the base material include a resin substrate, a glass substrate, and a semiconductor substrate. A preferred aspect of the substrate is described, for example, in paragraph [0140] of WO2018/155193A, the contents of which are incorporated herein by reference. As a component of the resin substrate, a cycloolefin polymer or polyimide is preferable. A thickness of the resin substrate is preferably 5 μm to 200 μm and more preferably 10 μm to 100 μm.

A conductive layer may be disposed on one side of the base material. Conductive layers may be arranged on both surfaces of the base material. A conductive layer having one layer or two or more layers may be disposed on the base material. In a case where a conductive layer having two or more layers is disposed, it is preferable that conductive layers formed of different materials are adopted. The laminate may include the base material, the conductive layer, and the dried product of the composition according to the embodiment of the present disclosure in this order.

As the conductive layer, from the viewpoint of conductivity and fine line formability, at least one layer selected from the group consisting of a metal layer, a conductive metal oxide layer, a graphene layer, a carbon nanotube layer, and a conductive polymer layer is preferable.

A preferred aspect of the conductive layer is described, for example, in paragraph [0141] of WO2018/155193A, the contents of which are incorporated herein by reference.

The conductive layer may include at least one conductive layer selected from the group consisting of a transparent electrode and a lead wire.

For example, the transparent electrode can function suitably as an electrode for a touch panel. The transparent electrode may be configured of a metal oxide film such as indium tin oxide (ITO) and indium zinc oxide (IZO). The transparent electrode may be configured of a fine metal wire such as a metal mesh and a metal nanowire. Examples of the fine metal wire include thin wire of silver and copper. Among these, silver conductive materials such as silver mesh and silver nanowire are preferable.

As a material of the lead wire, metal is preferable. Examples of a metal include gold, silver, copper, molybdenum, aluminum, titanium, chromium, zinc, manganese, and alloy consisting of two or more kinds of these metal elements. As the material of the lead wire, copper, molybdenum, aluminum, or titanium is preferable, copper is particularly preferable.

The dried product may be a dried product of the composition according to the first embodiment. The dried product of the composition according to the first embodiment may be adopted as a photosensitive layer. The dried product may be a dried product of the composition according to the second embodiment. The dried product of the composition according to the second embodiment may be adopted as a refractive index adjusting layer.

The laminate may include the dried product of the composition according to the first embodiment and the dried product of the composition according to the second embodiment. Other constituent elements may be arranged between the dried product of the composition according to the first embodiment and the dried product of the composition according to the second embodiment. The laminate may include the base material, the dried product of the composition according to the second embodiment, and the dried product of the composition according to the first embodiment in this order.

In the preparing step, a pre-manufactured laminate may be prepared. The preparing step may include manufacturing the laminate. The manufacturing method of the laminate is not limited. The laminate may be manufactured using the composition according to the embodiment of the present disclosure. For example, the manufacturing method of the laminate may include, in the following order, applying the composition according to the embodiment of the present disclosure to the base material and drying the composition. Examples of an applying method include a printing method, a spray coating method, a roll coating method, a bar coating method, a curtain coating method, a spin coating method, and a die coating method (that is, a slit coating method). Examples of the drying method include natural drying, heating drying, and drying under reduced pressure. Multiple drying methods may be combined. As a drying method, heat drying or vacuum drying is preferable. In addition, the laminate may be manufactured by using the transfer film according to the embodiment of the present disclosure. For example, the manufacturing method of the laminate may include bonding the base material and the transfer film according to the embodiment of the present disclosure. A known laminator such as a vacuum laminator and an auto-cut laminator may be used for the bonding. A laminating temperature is not particularly limited, but is preferably, for example, 70° C. to 130° C.

Exposing Step

In the exposing step, the dried product is exposed in a patterned manner.

According to the exposing step, an exposed portion and a non-exposed portion are formed. A positional relationship between the exposed portion and the non-exposed portion is not particularly limited, and is appropriately adjusted according to a shape of the target pattern. In the exposing step, the base material and the dried product may be exposed in this order, or the dried product and the base material may be exposed in this order. That is, as long as the dried product is exposed in a patterned manner, an irradiation direction of the light is not limited.

Examples of the light source include various lasers, a light emitting diode (LED), an ultra-high pressure mercury lamp, a high pressure mercury lamp, and a metal halide lamp. The exposure light preferably includes a wavelength of 365 nm or 405 nm. A main wavelength of the exposure light is preferably 365 nm. The main wavelength is a wavelength having the highest intensity. An exposure amount is preferably 5 mJ/cm² to 200 mJ/cm² and more preferably 10 mJ/cm² to 200 mJ/cm².

Developing Step

In the developing step, the dried product after exposure is developed to form a resin pattern.

For example, the development is performed using a developer. As the developer, an alkali aqueous solution is preferable. Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide). Examples of a preferred developer include developers described in paragraph [0194] of WO2015/093271A.

Examples of the development method include a puddle development method, a shower development method, a spin development method, and a dip development method. Examples of a preferred development method include development methods described in paragraph [0195] of WO2015/093271A.

The resin pattern may be adopted to various articles. The resin pattern may be adopted to, for example, a display device, an input device, a printed wiring board, or a semiconductor package. Examples of the input device include an organic electroluminescent display device and a liquid crystal display device. As the application of the resin pattern, a touch panel is preferable, and a capacitive touch panel is more preferable. The resin pattern may be used as a protective film of an electrode for a touch panel or a protective film of a wiring line for a touch panel.

Peeling Step

In a case where the laminate in the preparing step includes the temporary support, the pattern forming method may include, between the preparing step and the exposing step or between the exposing step and the developing step, peeling off the temporary support from the laminate. As a peeling method, a mechanism similar to peeling mechanism of a cover film, described in paragraphs [0161] and [0162] of JP2010-072589A, may be used.

Post-Exposing Step and Post-Baking Step

The pattern forming method may include exposing the resin pattern (hereinafter, may be referred to as a “post-exposing step”). The pattern forming method may include a step of heating the resin pattern (hereinafter, may be referred to as a “post-baking step”). The pattern forming method may include the post-exposing step and the post-baking step. In a case where the pattern forming method includes the post-exposing step and the post-baking step, it is preferable that the post-baking step is performed after the post-exposing step.

An exposure amount in the post-exposing step is preferably 100 mJ/cm² to 5000 mJ/cm² and more preferably 200 mJ/cm² to 3000 mJ/cm².

A temperature in the post-baking step is preferably 80° C. to 250° C. and more preferably 90° C. to 160° C. A time in the post-baking step is preferably 1 minute to 180 minutes and more preferably 10 minutes to 60 minutes.

### EXAMPLES

Hereinafter, the present disclosure will be described in detail according to Examples. However, the present disclosure is not limited to the following Examples. The matters shown in the following Examples (for example, materials, amounts used, proportions, treatment contents, and treatment procedures) may be changed as appropriate within a range not departing from the gist of the present disclosure. In the following Examples, “%” represents % by mass unless otherwise specified. In the following Examples, “wt %” represents % by mass.

Synthesis of Surfactants 1 to 7

Surfactants 1 to 7 shown in Table 1 below were produced according to the following method. Methyl isobutyl ketone (100 parts by mass) was charged into a glass flask equipped with a stirrer, a condenser, a dropping device, and a thermometer, and heated to 105° C. while stirring in a nitrogen stream. Next, a monomer solution in which “CHEMINOX FAAC-4” (35 parts by mass, Unimatec Co., Ltd.) and a monomer (65 parts by mass) selected according to the description in Table 1 below were dissolved in methyl isobutyl ketone (73 parts by mass) and a radical polymerization initiator solution in which t-butylperoxy-2-ethylhexanoate (5 parts by mass) was dissolved in methyl isobutyl ketone (50 parts by mass) were respectively set in a separate dropping device, and the solutions were simultaneously added dropwise to the inside of the flask over 3 hours while keeping the temperature at 105° C. After completion of the dropwise addition, the mixture was stirred at 105° C. for 10 hours, and then the solvent was removed under reduced pressure to obtain a fluorine-based surfactant.

Synthesis of Surfactant 8

A surfactant 8 shown in Table 1 below was produced according to the following method. Methyl isobutyl ketone (100 parts by mass) was charged into a glass flask equipped with a stirrer, a condenser, a dropping device, and a thermometer, and heated to 105° C. while stirring in a nitrogen stream. Next, a monomer solution in which “CHEMINOX FAAC-6” (45 parts by mass, Unimatec Co., Ltd.) and “Blemmer PE-350” (55 parts by mass, NOF Corporation) selected according to the description in Table 1 below were dissolved in methyl isobutyl ketone (73 parts by mass) and a radical polymerization initiator solution in which t-butylperoxy-2-ethylhexanoate (5 parts by mass) was dissolved in methyl isobutyl ketone (50 parts by mass) were respectively set in a separate dropping device, and the solutions were simultaneously added dropwise to the inside of the flask over 3 hours while keeping the temperature at 105° C. After completion of the dropwise addition, the mixture was stirred at 105° C. for 10 hours, and then the solvent was removed under reduced pressure to obtain a fluorine-based surfactant.

TABLE 1

| Surfactant | | | | |
|---|---|---|---|---|
| | | | Content of | |
| | | | fluorine atom | |
| No. | Name | Mw | (% by mass) | Monomer |
| 1 | C4F9xMA(PO)H | 7000 | 19 | Blemmer PP-500 (NOF Corporation) |
| 2 | C4F9xMA(BO)H | 6000 | 19 | Blemmer 10PPB-500B (NOF Corporation) |
| 3 | C4F9xMA(EO)H | 12000 | 19 | Blemmer PE-350 (NOF Corporation) |
| 4 | C4F9xA(PO)H | 6000 | 19 | Blemmer AP-400 (NOF Corporation) |
| 5 | C4F9xA(EO)H | 5000 | 19 | Blemmer AE-200 (NOF Corporation) |
| 6 | C4F9xMA(EO)Me | 8000 | 19 | LIGHT ESTER 130MA (KYOEISHA CHEMICAL |
| | | | | Co., LTD.) |
| 7 | C4F9xA(EO)Me | 8000 | 19 | LIGHT ACRYLATE 130A (KYOEISHA CHEMICAL |
| | | | | Co., LTD.) |
| 8 | C6F13 | 10000 | 27 | Blemmer PE-350 (NOF Corporation) |

### Examples 1A to 61A

Preparation of Photosensitive Composition

A mixture including components shown in “Composition 1” below was prepared. A mixed solvent of methyl ethyl ketone (MEK) and propylene glycol monomethyl ether acetate (PGMEA) (MEK/PGMEA=60%/40%) was added to the mixture to obtain a photosensitive composition having a concentration of solid contents of 25%.

Composition 1

Composition 1 is shown below. The content of each component in the composition 1 is represented by the concentration (%) of solid contents.
NK ESTER A-DCP (Shin-Nakamura Chemical Co., Ltd., polymerizable compound): 17.90%
NK ESTER A-NOD-N(Shin-Nakamura Chemical Co., Ltd., polymerizable compound): 2.73%
KAYARAD DPHA (dipentaerythritol hexaacrylate, Nippon Kayaku Co., Ltd., polymerizable compound): 7.99%
ARONIX TO-2349 (TOAGOSEI CO., LTD., polymerizable compound): 2.98%
Alkali-soluble resin having following structure (ratio of each constitutional unit=by mass, Mw=18000): 52.67%

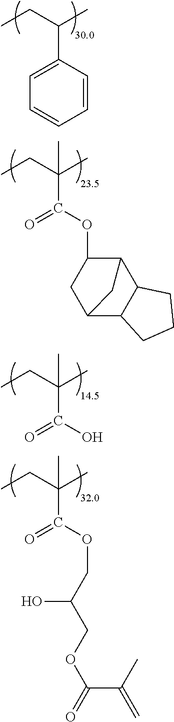

IRGACURE OXE02 (BASF SE, photopolymerization initiator): 0.36%
   Omnirad 907 (IGM Resins B.V., photopolymerization initiator): 0.73%
   N-phenylglycine: 0.10%
   XIRAN EF-40 (Polyscope Polymers BV): 1.20%
   Benzoimidazole: 0.13%
   Isonicotinamide: 0.52%
   DURANATE WT32-B75P (Asahi Kasei Corporation): 12.50%
   Surfactant selected according to description of Table 2: 0.19%

### Examples 62a to 122A

Preparation of Photosensitive Composition

A mixture including components shown in “Composition 2” below was prepared. A mixed solvent of methyl ethyl ketone (MEK) and propylene glycol monomethyl ether acetate (PGMEA) (MEK/PGMEA=60%/40%) was added to the mixture to obtain a photosensitive composition having a concentration of solid contents of 29%.

Composition 2

Composition 2 is shown below. The content of each component in the composition 2 is represented by the concentration (%) of solid contents.
NK ESTER A-DCP (Shin-Nakamura Chemical Co., Ltd., polymerizable compound): 19.3%
8UX-015A (Taisei Fine Chemical Co., Ltd., polymerizable compound): 9.7%
ARONIX TO-2349 (TOAGOSEI CO., LTD., polymerizable compound): 3.2%
Alkali-soluble resin having following structure (ratio of each constitutional unit=mol %, Mw=27000): 53.6%

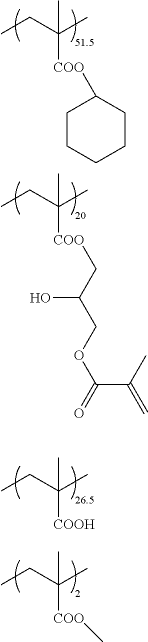

IRGACURE OXE02 (BASF SE, photopolymerization initiator): 0.4%
   Omnirad 907 (IGM Resins B.V., photopolymerization initiator): 0.7%
   N-phenylglycine: 0.1%
   Benzoimidazole: 0.3%
   DURANATE WT32-B75P (Asahi Kasei Corporation): 12.5%
   Surfactant selected according to description of Table 3: 0.16%

### Examples 123A to 183A

Preparation of Photosensitive Composition

A mixture including components shown in “Composition 3” below was prepared. A mixed solvent of methyl ethyl ketone (MEK) and propylene glycol monomethyl ether acetate (PGMEA) (MEK/PGMEA=60%/40%) was added to the mixture to obtain a photosensitive composition having a concentration of solid contents of 22%.

Composition 3

Composition 3 is shown below. The content of each component in the composition 3 is represented by the concentration (%) of solid contents.
KAYARAD R-604 (Nippon Kayaku Co., Ltd., polymerizable compound): 10.9%
NK ESTER A-NOD-N(Shin-Nakamura Chemical Co., Ltd., polymerizable compound): 11.0%
KAYARAD DPHA (dipentaerythritol hexaacrylate, Nippon Kayaku Co., Ltd.,
polymerizable compound): 10.2%
ARONIX TO-2349 (TOAGOSEI CO., LTD., polymerizable compound): 3.9%
Alkali-soluble resin having following structure (Mw=19000): 55.58%

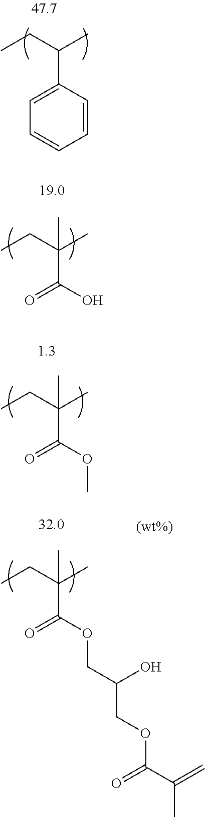

Omnirad 379EG (IGM Resins B.V., photopolymerization initiator): 0.73%
   APi-307 (Shenzhen UV-ChemTech Co., Ltd., photopolymerization initiator): 1.97%
   Phenothiazine: 0.10%
   XIRAN EF-40 (Polyscope Polymers BV): 1.20%
   Benzoimidazole: 0.30%
   Isonicotinamide: 1.00%
   DURANATE SBN-70D (Asahi Kasei Corporation): 2.67%
   Surfactant selected according to description of Table 4: 0.32%

### Examples 184a to 244A

Preparation of Photosensitive Composition

A mixture including components shown in “Composition 4” below was prepared. A mixed solvent of methyl ethyl ketone (MEK) and propylene glycol monomethyl ether acetate (PGMEA) (MEK/PGMEA=60%/40%) was added to the mixture to obtain a photosensitive composition having a concentration of solid contents of 29%.

Composition 4

Composition 4 is shown below. The content of each component in the composition 4 is represented by the concentration (%) of solid contents.
KAYARAD R-604 (Nippon Kayaku Co., Ltd., polymerizable compound): 11.3%
NK ESTER A-NOD-N(Shin-Nakamura Chemical Co., Ltd., polymerizable compound): 11.3%
KAYARAD DPHA (dipentaerythritol hexaacrylate, Nippon Kayaku Co., Ltd., polymerizable compound): 10.4%
ARONIX TO-2349 (TOAGOSEI CO., LTD., polymerizable compound): 3.16%
Alkali-soluble resin having following structure (Mw=29000): 60.2%

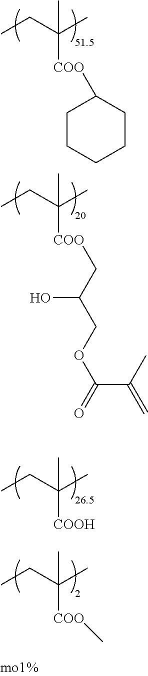

Omnirad 379EG (IGM Resins B.V., photopolymerization initiator): 0.32%
   APi-307 (Shenzhen UV-ChemTech Co., Ltd., photopolymerization initiator): 0.91%
   XIRAN EF-40 (Polyscope Polymers BV): 1.20%
   Benzoimidazole: 0.13%
   Isonicotinamide: 1.00%
   Surfactant selected according to description of Table 5: 0.16%

### Examples 245a to 305A

Preparation of Photosensitive Composition

A mixture including components shown in “Composition 5” below was prepared. A mixed solvent of methyl ethyl ketone (MEK) and propylene glycol monomethyl ether acetate (PGMEA) (MEK/PGMEA=30%/70%) was added to the mixture to obtain a photosensitive composition having a concentration of solid contents of 22%.

Composition 5

Composition 5 is shown below. The content of each component in the composition 5 is represented by the concentration (%) of solid contents.
NK ESTER A-NOD-N(Shin-Nakamura Chemical Co., Ltd., polymerizable compound): 40.2%
Alkali-soluble resin having following structure (Mw=28000): 57.5%

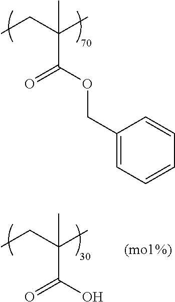

APi-307 (Shenzhen UV-ChemTech Co., Ltd., photopolymerization initiator): 2.12%
   2-Naphthalenethiol: 0.03%
   Surfactant selected according to description of Table 6: 0.16%

### Examples 306a to 366A

Preparation of Photosensitive Composition

A mixture including components shown in “Composition 6” below was prepared. A mixed solvent of methyl ethyl ketone (MEK) and propylene glycol monomethyl ether acetate (PGMEA) (MEK/PGMEA=66%/34%) was added to the mixture to obtain a photosensitive composition having a concentration of solid contents of 13%.

Composition 6

Composition 6 is shown below. The content of each component in the composition 6 is represented by the concentration (%) of solid contents.
B-IMD (KUROGANE KASEI Co., Ltd.): 6.8%
SB-PI 70 (SANYO TRADING CO., LTD.): 0.30%
Phenothiazine: 0.27%
Compound having following structure: 0.14%

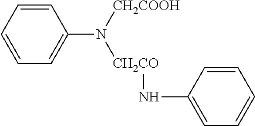

Compound having following structure: 0.01%

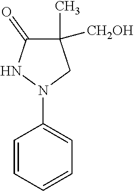

Alkali-soluble resin (styrene:methyl methacrylate:methacrylic acid=52%:19%:29%, Mw=70000, acid value=189 mgKOH/g, Tg=131° C.): 50.4%
   ARONIX M270 (TOAGOSEI CO., LTD., polymerizable compound): 3.9%
   NK ESTER BPE-500 (Shin-Nakamura Chemical Co., Ltd., polymerizable compound): 37.4%
   Leuco Crystal Violet (LCV): 0.40%
   CBT-1 (JOHOKU CHEMICAL CO., LTD., photopolymerization initiator): 0.10% Surfactant selected according to description of Table 7: 0.32%

### Examples 367a to 427A

Preparation of Photosensitive Composition

A mixture including components shown in “Composition 7” below was prepared. A mixed solvent of methyl ethyl ketone (MEK) and propylene glycol monomethyl ether acetate (PGMEA) (MEK/PGMEA=50%/50%) was added to the mixture to obtain a photosensitive composition having a concentration of solid contents of 16%.

Composition 7

Composition 7 is shown below. The content of each component in the composition 7 is represented by the concentration (%) of solid contents.
FDK-017 (carbon black composition, TOKYO PRINTING INK MFG CO., LTD.): 31.5%
Alkali-soluble resin having following structure (ratio of each constitutional unit=mol %, Mw=12000): 43.1%

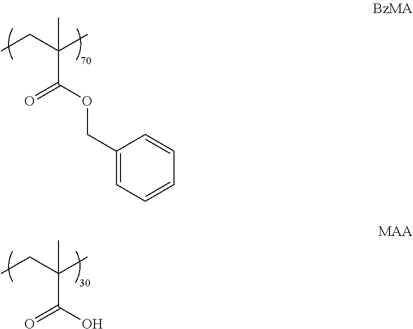

NK ESTER A-NOD-N(Shin-Nakamura Chemical Co., Ltd., polymerizable compound): 2.8%
NK ESTER A-DCP (Shin-Nakamura Chemical Co., Ltd., polymerizable compound): 8.3%
8UX-015A (Taisei Fine Chemical Co., Ltd., polymerizable compound): 5.5%
KAYARAD DPHA (dipentaerythritol hexaacrylate, Nippon Kayaku Co., Ltd.,
polymerizable compound): 1.8%
IRGACURE OXE02 (BASF SE, photopolymerization initiator): 4.8%
1,2,4-Triazole: 2.0%
Surfactant selected according to description of Table 8: 0.15%

### Examples 428a to 488A

Preparation of Photosensitive Composition

A mixture including components shown in “Composition 8” below was prepared. A mixed solvent of methyl ethyl ketone (MEK) and propylene glycol monomethyl ether acetate (PGMEA) (MEK/PGMEA=60%/40%) was added to the mixture to obtain a photosensitive composition having a concentration of solid contents of 35%.

Composition 8

Composition 8 is shown below. The content of each component in the composition 8 is represented by the concentration (%) of solid contents.
Alkali-soluble resin (methacrylic acid:styrene:methyl methacrylate:glycidyl methacrylate-methyl methacrylate=20%:46%:2%:32%): 53.3%
NK ESTER A-NOD-N (1,9-nonanediol diacrylate, Shin-Nakamura Chemical Co., Ltd., polymerizable compound): 24%
KAYARAD DPHA (dipentaerythritol hexaacrylate, Nippon Kayaku Co., Ltd., polymerizable compound): 11%
ARONIX TO-2349 (TOAGOSEI CO., LTD., polymerizable compound): 4%
B-CIM (Hampford Research Inc., photopolymerization initiator): 6.8%
SB-PI 701 (SANYO TRADING CO., LTD.): 0.075%
N-Phenylcarbamoylmethyl-N-carboxymethylaniline (FUJIFILM Wako Pure Chemical Corporation): 0.135%
TDP-G (Kawaguchi Chemical Industry Co., LTD.): 0.26%
CBT-1 (JOHOKU CHEMICAL CO., LTD.): 0.12%
4-Hydroxymethyl-4-methyl-1-phenyl-3-pyrazolidone (FUJIFILM Wako Pure Chemical Corporation): 0.01%
Surfactant selected according to description of Table 9: 0.30%

### Examples 489a to 494A

Preparation of Photosensitive Composition

A mixture having composition 9 was prepared by changing the surfactant in “Composition 1” described above to a surfactant selected according to the description of Table 10. A mixed solvent of methyl ethyl ketone (MEK) and toluene (MEK/toluene=60%/40%) was added to the mixture to obtain a photosensitive composition having a concentration of solid contents of 25%.

### Examples 495a to 500A

Preparation of Photosensitive Composition

A mixture having composition 10 was prepared by changing the surfactant in “Composition 1” described above to a surfactant selected according to the description of Table 10. A mixed solvent of ethylene glycol monoethyl ether and ethylene glycol monoethyl ether acetate (ethylene glycol monoethyl ether/ethylene glycol monoethyl ether acetate=50%/50%) was added to the mixture to obtain a photosensitive composition having a concentration of solid contents of 25%.

### Examples 501a to 562A

Preparation of Photosensitive Composition

A mixture including components shown in “Composition 11” below was prepared. A mixed solvent of methyl ethyl ketone (MEK) and propylene glycol monomethyl ether acetate (PGMEA) (MEK/PGMEA=50%/50%) was added to the mixture to obtain a photosensitive composition having a concentration of solid contents of 16%.

Composition 11

Composition 11 is shown below. The content of each component in the composition 11 is represented by the concentration (%) of solid contents.
Resin-coated carbon black (dispersed particle size (dynamic light scattering method)=160 nm): 25.0%
Polymerized pigment dispersing agent (BYK-2012, BYK Chemie Japan): 4.5%
Pigment dispersion aid having following structure (X is a counter salt): 2.0%

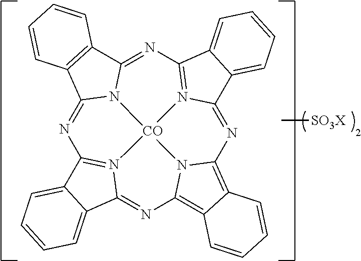

Alkali-soluble resin having following structure (ratio of each constitutional unit=mol %, Mw=15,000): 43.1%

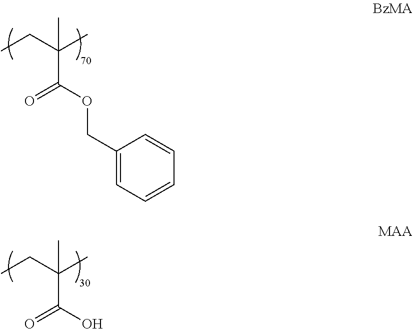

NK ESTER A-NOD-N (1,9-nonanediol diacrylate, Shin-Nakamura Chemical Co., Ltd., polymerizable compound): 2.8%
NK ESTER A-DCP (Shin-Nakamura Chemical Co., Ltd., polymerizable compound): 8.3%
8UX-015A (Taisei Fine Chemical Co., Ltd., polymerizable compound): 5.5%
KAYARAD DPHA (dipentaerythritol hexaacrylate, Nippon Kayaku Co., Ltd., polymerizable compound): 1.8%
IRGACURE OXE02 (BASF SE, photopolymerization initiator): 4.8% 1,2,4-Triazole: 2.0%
Surfactant selected according to description of Table 11: 0.15%

### Examples 563a to 565A

Preparation of Photosensitive Composition

A mixture including components shown in “Composition 12” below was prepared. A mixed solvent of methyl ethyl ketone (MEK) and propylene glycol monomethyl ether acetate (PGMEA) (MEK/PGMEA=60%/40%) was added to the mixture to obtain photosensitive compositions (OC-1) to (OC-3) having a concentration of solid contents of 25%.

Composition 12

Composition 12 is shown below. The content of each component in the composition 12 is represented by the concentration (%) of solid contents.
NK ESTER A-DCP (Shin-Nakamura Chemical Co., Ltd., polymerizable compound): 17.90%
NK ESTER A-NOD-N(Shin-Nakamura Chemical Co., Ltd., polymerizable compound): 2.73%
KAYARAD DPHA (dipentaerythritol hexaacrylate, Nippon Kayaku Co., Ltd., polymerizable compound): 7.99%
ARONIX TO-2349 (TOAGOSEI CO., LTD., polymerizable compound): 2.98%
Alkali-soluble resin having following structure (ratio of each constitutional unit=% by mass, Mw=18000): 52.60%

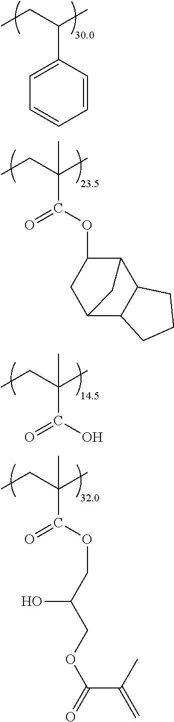

IRGACURE OXE02 (BASF SE, photopolymerization initiator): 0.36%
   Omnirad 907 (IGM Resins B.V., photopolymerization initiator): 0.73%
   N-phenylglycine: 0.10%
   XIRAN EF-40 (Polyscope Polymers BV): 1.20%
   Benzoimidazole: 0.13%
   Isonicotinamide: 0.52%
   DURANATE WT32-B75P (Asahi Kasei Corporation): 12.50%
   Surfactant selected according to description of Table 12: 0.25%

Synthesis of Surfactant S-1

A surfactant S-1 was produced according to the following method.

15.0 g of 3-methacryloyloxypropyltris(trimethylsiloxy)silane and 79.0 g of methyl ethyl ketone as a solvent were charged into a flask replaced with nitrogen, and the mixture was heated to 50° C. while stirring under a nitrogen stream. Next, 4.2 g of 2,2′-bipyridyl and 1.5 g of cuprous chloride were charged thereto, and the inside of the flask was stirred for 30 minutes while keeping the temperature at 50° C. Thereafter, 2.7 g of ethyl 2-bromoisobutyrate was added thereto and reacted at 50° C. for 3 hours under a nitrogen stream to obtain a polymer block of 3-methacryloyloxypropyltris(trimethylsiloxy)silane.

Next, 35.0 g of polypropylene glycol monomethacrylate (average repetition number of polypropylene glycol: 4 to 6) was added to the reaction system including the polymer block of 3-methacryloyloxypropyltris(trimethylsiloxy)silane, and the mixture was reacted at 50° C. for 18 hours to obtain a reaction product. Next, 30 g of activated alumina was added to the obtained reaction product, and the mixture was stirred. After filtering the activated alumina, the solvent was distilled off under reduced pressure to obtain a block copolymer (S-1).

As a result of measuring a molecular weight of the obtained block copolymer (S-1) by GPC, the weight-average molecular weight (Mw) was 10,300, the number-average molecular weight (Mn) was 9,200, and (Mw/Mn) was 1.1. In addition, from the raw material preparation ratio, the content of the functional group represented by —Si[OSi(CH₃)₃]₃ in the block copolymer (S-1) was 22% by mass.

The block copolymer (S-1) obtained as described above was used as the surfactant S-1.

Synthesis of Surfactant S-2

A surfactant S-2 was produced according to the following method. 33.5 g of 3-methacryloyloxypropyltris(trimethylsiloxy)silane and 75.0 g of methyl ethyl ketone as a solvent were charged into a flask replaced with nitrogen, and the mixture was heated to 60° C. while stirring under a nitrogen stream. Next, 4.2 g of 2,2′-bipyridyl and 1.5 g of cuprous chloride were charged thereto, and the inside of the flask was stirred for 30 minutes while keeping the temperature at 60° C. Thereafter, 2.7 g of ethyl 2-bromoisobutyrate was added thereto and reacted at 60° C. for 8 hours under a nitrogen stream to obtain a polymer block of 3-methacryloyloxypropyltris(trimethylsiloxy)silane.

Next, 16.5 g of poly(1,2-butylene glycol) monomethacrylate (average repetition number of 1,2-butylene glycol: 6) was added to the reaction system including the polymer block of 3-methacryloyloxypropyltris(trimethylsiloxy)silane, and the mixture was reacted at 60° C. for 20 hours to obtain a reaction product. Next, 30 g of activated alumina was added to the obtained reaction product, and the mixture was stirred. After filtering the activated alumina, the solvent was distilled off under reduced pressure to obtain a block copolymer (S-2).

As a result of measuring a molecular weight of the obtained block copolymer (S-2) by GPC, the weight-average molecular weight (Mw) was 10,300, the number-average molecular weight (Mn) was 7,900, and (Mw/Mn) was 1.3. The content of the functional group represented by —Si[OSi(CH₃)₃]₃ in the obtained block copolymer (S-2) was 49% by mass.

The block copolymer (S-2) obtained as described above was used as the surfactant S-2.

### Examples 566a to 568A

Preparation of Photosensitive Composition

A mixture including components shown in “Composition 13” below was prepared. A mixed solvent of methyl ethyl ketone (MEK) and propylene glycol monomethyl ether acetate (PGMEA) (MEK/PGMEA=60%/40%) was added to the mixture to obtain photosensitive compositions (OC-4) to (OC-6) having a concentration of solid contents of 29%.

Composition 13

Composition 13 is shown below. The content of each component in the composition 13 is represented by the concentration (%) of solid contents.
NK ESTER A-DCP (Shin-Nakamura Chemical Co., Ltd., polymerizable compound): 19.3%
8UX-015A (Taisei Fine Chemical Co., Ltd., polymerizable compound): 9.7%
ARONIX TO-2349 (TOAGOSEI CO., LTD., polymerizable compound): 3.2%
Alkali-soluble resin having following structure (ratio of each constitutional unit=mol %, Mw=27000): 53.24%

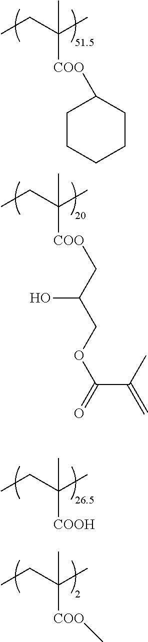

IRGACURE OXE02 (BASF SE, photopolymerization initiator): 0.4%
   Omnirad 907 (IGM Resins B.V., photopolymerization initiator): 0.7%
   N-phenylglycine: 0.1%
   Benzoimidazole: 0.3%
   DURANATE WT32-B75P (Asahi Kasei Corporation): 12.5%
   Surfactant selected according to description of Table 12: 0.22%

### Comparative Example 1A

A photosensitive composition was obtained by the same procedure as in Example 1A, except that no surfactant was used.

### Comparative Example 2A

A photosensitive composition was obtained by the same procedure as in Example 1A, except that the surfactant was changed according to the description in Table 12.

Surface Tension

A surface tension of each of the photosensitive compositions of Examples and Comparative Examples described above was measured by the following method. A 50 mL photosensitive composition was taken as a sample, and the surface tension was measured three times by the Wilhelmy method in an environment of 25° C. and 60% RH (relative humidity). In the measurement of the surface tension, a CBVP-A3 type automatic surface tension meter manufactured by Kyowa Interface Science Co., Ltd. was used, and a platinum plate was used as a probe according to the Wilhelmy method. An arithmetic mean value of the measured value was adopted as the surface tension of the photosensitive composition. The measurement results classified according to the following standard are shown in Tables 2 to 13.
E: surface tension≤22.0 mN/m
C: 22.0 mN/m<surface tension≤23.0 mN/m
A: 23.0 mN/m<surface tension≤26.5 mN/m
B: 26.5 mN/m<surface tension≤29.0 mN/m
D: 29.0 mN/m<surface tension

Surface Tension (Methanol/Water)

A surface tension was measured by the following method using each of the surfactants of Examples and Comparative Examples described above. A mixture of 1 parts by mass of the solid content of the surfactant, 1,000 parts by mass of water, and 2,300 parts by mass of methanol was prepared. A 50 mL mixture was taken as a sample, and the surface tension was measured three times by the Wilhelmy method in an environment of 25° C. and 60% RH (relative humidity). In the measurement of the surface tension, a CBVP-A3 type automatic surface tension meter manufactured by Kyowa Interface Science Co., Ltd. was used, and a platinum plate was used as a probe according to the Wilhelmy method. An arithmetic mean value of the measured value was adopted as the surface tension of the mixture. The measurement results classified according to the following standard are shown in Tables 2 to 13.
E: surface tension<20.0 mN/m
C: 20.0 mN/m<surface tension≤23.0 mN/m
A: 23.0 mN/m<surface tension≤26.5 mN/m
B: 26.5 mN/m<surface tension≤29.0 mN/m
D: 29.0 mN/m<surface tension

Evaluation

The following evaluations were performed using each of the photosensitive compositions of Examples and Comparative Examples described above.

Foaming Property

On a polyethylene terephthalate film (temporary support, LUMIRROR 16KS40, Toray Industries, Inc., thickness: 16 μm), the photosensitive composition was applied using a slit-shaped nozzle, and the solvent was removed by drying the coating liquid with a hot air convection dryer having a temperature gradient of 75° C. to 120° C. to form a photosensitive layer. The coating amount of the photosensitive composition was adjusted according to the thickness of the photosensitive layer shown in Tables 2 to 13. In the formation of the photosensitive layer using each of the photosensitive compositions of Examples 1A to 568A, the photosensitive composition was applied neatly without streak and unevenness.

The photosensitive layer was added to a 1% sodium carbonate aqueous solution (600 parts by mass) to prepare a test solution. 30 g of the test solution was placed in a LABORAN screw tube jar (AS ONE Corporation, transparent, 50 mL, No. 7) and capped to obtain a test piece. After stirring the test piece for 30 minutes at 1500 revolutions per minute (rpm), a height of bubbles was measured based on the liquid level before stirring, and a foaming property was evaluated according to the following standard. The evaluation results are shown in Tables 2 to 13.
A: height of the bubbles was less than 10 mm, or no bubbles were generated.
B: height of the bubbles was 10 mm or more.

Defoaming Property

The test piece was stirred for 30 minutes at 1500 revolutions per minute (rpm) according to the method for evaluating the foaming property described above. A time from the end of stirring to the disappearance of bubbles was measured, and a defoaming property was evaluated according to the following standard. The evaluation results are shown in Tables 2 to 13.
A: no bubbles were generated, or even in a case where the bubbles were generated, all bubbles disappeared in less than 30 seconds.
B: bubbles were generated, but all bubbles disappeared in 30 seconds or more and less than 1 minute.
C: bubbles were generated, and the bubbles did not disappear even after 1 minute or more.

TABLE 2

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 1A | 1 | EXP.MFS-578-2 | Fluorine-based | B | A | 5.5 | B | B |
| Example 2A | 1 | EXP.MFS-628 | Fluorine-based | B | A | 5.5 | B | B |
| Example 3A | 1 | EXP.MFS-631 | Fluorine-based | B | A | 5.5 | B | B |
| Example 4A | 1 | EXP.MFS-603 | Fluorine-based | B | A | 5.5 | B | B |
| Example 5A | 1 | C4F9xMA(PO)H | Fluorine-based | A | A | 5.5 | B | A |
| Example 6A | 1 | C4F9xMA(BO)H | Fluorine-based | B | A | 5.5 | B | B |
| Example 7A | 1 | C4F9xMA(EO)H | Fluorine-based | A | A | 5.5 | B | A |
| Example 8A | 1 | C4F9xA(PO)H | Fluorine-based | A | A | 5.5 | B | A |
| Example 9A | 1 | C4F9xA(EO)H | Fluorine-based | A | A | 5.5 | B | A |
| Example 10A | 1 | C4F9xMA(EO)Me | Fluorine-based | B | A | 5.5 | B | B |
| Example 11A | 1 | C4F9xA(EO)Me | Fluorine-based | B | A | 5.5 | B | B |
| Example 12A | 1 | PIONIN D-6115 | Hydrocarbon-based | B | A | 5.5 | B | B |
| Example 13A | 1 | PIONIN D-1105 | Hydrocarbon-based | B | A | 5.5 | B | B |
| Example 14A | 1 | EXP.S-310-2 | Silicone-based | A | A | 5.5 | A | A |
| Example 15A | 1 | EXP.S-309-2 | Silicone-based | A | A | 5.5 | A | A |
| Example 16A | 1 | EXP.S-315 | Silicone-based | A | A | 5.5 | A | A |
| Example 17A | 1 | EXP.S-503-2 | Silicone-based | A | A | 5.5 | A | A |
| Example 18A | 1 | EXP.S-505-2 | Silicone-based | A | A | 5.5 | A | A |
| Example 19A | 1 | BYK-302 | Silicone-based | B | A | 5.5 | A | B |
| Example 20A | 1 | BYK-307 | Silicone-based | B | A | 5.5 | A | B |
| Example 21A | 1 | BYK-313 | Silicone-based | A | A | 5.5 | A | A |
| Example 22A | 1 | BYK-315N | Silicone-based | A | A | 5.5 | A | A |
| Example 23A | 1 | BYK-323 | Silicone-based | A | A | 5.5 | A | A |
| Example 24A | 1 | BYK-330 | Silicone-based | A | A | 5.5 | A | A |
| Example 25A | 1 | BYK-331 | Silicone-based | B | A | 5.5 | A | B |
| Example 26A | 1 | BYK-333 | Silicone-based | B | A | 5.5 | A | B |
| Example 27A | 1 | BYK-342 | Silicone-based | B | A | 5.5 | A | B |
| Example 28A | 1 | BYK-377 | Silicone-based | A | A | 5.5 | A | A |
| Example 29A | 1 | BYK-378 | Silicone-based | B | A | 5.5 | A | B |
| Example 30A | 1 | BYK-300 | Silicone-based | A | A | 5.5 | A | A |
| Example 31A | 1 | BYK-306 | Silicone-based | A | A | 5.5 | A | A |
| Example 32A | 1 | BYK-310 | Silicone-based | A | A | 5.5 | A | A |
| Example 33A | 1 | BYK-320 | Silicone-based | A | A | 5.5 | A | A |
| Example 34A | 1 | BYK-325 | Silicone-based | B | A | 5.5 | A | B |
| Example 35A | 1 | BYK-370 | Silicone-based | A | A | 5.5 | A | A |
| Example 36A | 1 | KP-124 | Silicone-based | A | A | 5.5 | A | A |
| Example 37A | 1 | KP-109 | Silicone-based | A | A | 5.5 | A | A |
| Example 38A | 1 | KP-121 | Silicone-based | A | A | 5.5 | A | A |
| Example 39A | 1 | KP-103 | Silicone-based | A | A | 5.5 | A | A |
| Example 40A | 1 | KP-341 | Silicone-based | A | A | 5.5 | A | A |
| Example 41A | 1 | KP-112 | Silicone-based | B | A | 5.5 | A | B |
| Example 42A | 1 | KP-125 | Silicone-based | B | A | 5.5 | A | B |
| Example 43A | 1 | KP-101 | Silicone-based | B | A | 5.5 | A | B |
| Example 44A | 1 | KP-106 | Silicone-based | B | A | 5.5 | A | B |
| Example 45A | 1 | KP-120 | Silicone-based | B | A | 5.5 | A | B |
| Example 46A | 1 | KP-105 | Silicone-based | B | A | 5.5 | A | B |
| Example 47A | 1 | KP-104 | Silicone-based | B | A | 5.5 | A | B |
| Example 48A | 1 | KP-611 | Silicone-based | A | A | 5.5 | A | A |
| Example 49A | 1 | KP-626 | Silicone-based | A | A | 5.5 | A | A |
| Example 50A | 1 | KP-327 | Silicone-based | A | A | 5.5 | A | A |
| Example 51A | 1 | KP-323 | Silicone-based | A | A | 5.5 | A | A |
| Example 52A | 1 | KP-322 | Silicone-based | A | A | 5.5 | A | A |
| Example 53A | 1 | KP-310 | Silicone-based | A | A | 5.5 | A | A |
| Example 54A | 1 | KP-109 | Silicone-based | A | A | 5.5 | A | A |
| Example 55A | 1 | KP-620 | Silicone-based | A | A | 5.5 | A | A |
| Example 56A | 1 | KP-652 | Silicone-based | A | A | 5.5 | A | A |
| Example 57A | 1 | KP-306 | Silicone-based | A | A | 5.5 | A | A |
| Example 58A | 1 | KP-301 | Silicone-based | A | A | 5.5 | A | A |
| Example 59A | 1 | KP-621 | Silicone-based | A | A | 5.5 | A | A |
| Example 60A | 1 | KP-369 | Silicone-based | A | A | 5.5 | A | A |
| Example 61A | 1 | KP-368 | Silicone-based | A | A | 5.5 | A | A |

TABLE 3

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 62A | 2 | EXP.MFS-578-2 | Fluorine-based | B | A | 8.1 | B | B |
| Example 63A | 2 | EXP.MFS-628 | Fluorine-based | B | A | 8.1 | B | B |
| Example 64A | 2 | EXP.MFS-631 | Fluorine-based | B | A | 8.1 | B | B |
| Example 65A | 2 | EXP.MFS-603 | Fluorine-based | B | A | 8.1 | B | B |
| Example 66A | 2 | C4F9xMA(PO)H | Fluorine-based | A | A | 8.1 | B | A |
| Example 67A | 2 | C4F9xMA(BO)H | Fluorine-based | B | A | 8.1 | B | B |
| Example 68A | 2 | C4F9xMA(EO)H | Fluorine-based | A | A | 8.1 | B | A |
| Example 69A | 2 | C4F9xA(PO)H | Fluorine-based | A | A | 8.1 | B | A |
| Example 70A | 2 | C4F9xA(EO)H | Fluorine-based | A | A | 8.1 | B | A |
| Example 71A | 2 | C4F9xMA(EO)Me | Fluorine-based | B | A | 8.1 | B | B |
| Example 72A | 2 | C4F9xA(EO)Me | Fluorine-based | B | A | 8.1 | B | B |
| Example 73A | 2 | PIONIN D-6115 | Hydrocarbon-based | B | A | 8.1 | B | B |
| Example 74A | 2 | PIONIN D-1105 | Hydrocarbon-based | B | A | 8.1 | B | B |
| Example 75A | 2 | EXP.S-310-2 | Silicone-based | A | A | 8.1 | A | A |
| Example 76A | 2 | EXP.S-309-2 | Silicone-based | A | A | 8.1 | A | A |
| Example 77A | 2 | EXP.S-315 | Silicone-based | A | A | 8.1 | A | A |
| Example 78A | 2 | EXP.S-503-2 | Silicone-based | A | A | 8.1 | A | A |
| Example 79A | 2 | EXP.S-505-2 | Silicone-based | A | A | 8.1 | A | A |
| Example 80A | 2 | BYK-302 | Silicone-based | B | A | 8.1 | A | B |
| Example 81A | 2 | BYK-307 | Silicone-based | B | A | 8.1 | A | B |
| Example 82A | 2 | BYK-313 | Silicone-based | A | A | 8.1 | A | A |
| Example 83A | 2 | BYK-315N | Silicone-based | A | A | 8.1 | A | A |
| Example 84A | 2 | BYK-323 | Silicone-based | A | A | 8.1 | A | A |
| Example 85A | 2 | BYK-330 | Silicone-based | A | A | 8.1 | A | A |
| Example 86A | 2 | BYK-331 | Silicone-based | B | A | 8.1 | A | B |
| Example 87A | 2 | BYK-333 | Silicone-based | B | A | 8.1 | A | B |
| Example 88A | 2 | BYK-342 | Silicone-based | B | A | 8.1 | A | B |
| Example 89A | 2 | BYK-377 | Silicone-based | A | A | 8.1 | A | A |
| Example 90A | 2 | BYK-378 | Silicone-based | B | A | 8.1 | A | B |
| Example 91A | 2 | BYK-300 | Silicone-based | A | A | 8.1 | A | A |
| Example 92A | 2 | BYK-306 | Silicone-based | A | A | 8.1 | A | A |
| Example 93A | 2 | BYK-310 | Silicone-based | A | A | 8.1 | A | A |
| Example 94A | 2 | BYK-320 | Silicone-based | A | A | 8.1 | A | A |
| Example 95A | 2 | BYK-325 | Silicone-based | B | A | 8.1 | A | B |
| Example 96A | 2 | BYK-370 | Silicone-based | A | A | 8.1 | A | A |
| Example 97A | 2 | KP-124 | Silicone-based | A | A | 8.1 | A | A |
| Example 98A | 2 | KP-109 | Silicone-based | A | A | 8.1 | A | A |
| Example 99A | 2 | KP-121 | Silicone-based | A | A | 8.1 | A | A |
| Example 100A | 2 | KP-103 | Silicone-based | A | A | 8.1 | A | A |
| Example 101A | 2 | KP-341 | Silicone-based | A | A | 8.1 | A | A |
| Example 102A | 2 | KP-112 | Silicone-based | B | A | 8.1 | A | B |
| Example 103A | 2 | KP-125 | Silicone-based | B | A | 8.1 | A | B |
| Example 104A | 2 | KP-101 | Silicone-based | B | A | 8.1 | A | B |
| Example 105A | 2 | KP-106 | Silicone-based | B | A | 8.1 | A | B |
| Example 106A | 2 | KP-120 | Silicone-based | B | A | 8.1 | A | B |
| Example 107A | 2 | KP-105 | Silicone-based | B | A | 8.1 | A | B |
| Example 108A | 2 | KP-104 | Silicone-based | B | A | 8.1 | A | B |
| Example 109A | 2 | KP-611 | Silicone-based | A | A | 8.1 | A | A |
| Example 110A | 2 | KP-626 | Silicone-based | A | A | 8.1 | A | A |
| Example 111A | 2 | KP-327 | Silicone-based | A | A | 8.1 | A | A |
| Example 112A | 2 | KP-323 | Silicone-based | A | A | 8.1 | A | A |
| Example 113A | 2 | KP-322 | Silicone-based | A | A | 8.1 | A | A |
| Example 114A | 2 | KP-310 | Silicone-based | A | A | 8.1 | A | A |
| Example 115A | 2 | KP-109 | Silicone-based | A | A | 8.1 | A | A |
| Example 116A | 2 | KP-620 | Silicone-based | A | A | 8.1 | A | A |
| Example 117A | 2 | KP-652 | Silicone-based | A | A | 8.1 | A | A |
| Example 118A | 2 | KP-306 | Silicone-based | A | A | 8.1 | A | A |
| Example 119A | 2 | KP-301 | Silicone-based | A | A | 8.1 | A | A |
| Example 120A | 2 | KP-621 | Silicone-based | A | A | 8.1 | A | A |
| Example 121A | 2 | KP-369 | Silicone-based | A | A | 8.1 | A | A |
| Example 122A | 2 | KP-368 | Silicone-based | A | A | 8.1 | A | A |

TABLE 4

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 123A | 3 | EXP.MFS-578-2 | Fluorine-based | B | A | 3.5 | B | B |
| Example 124A | 3 | EXP.MFS-628 | Fluorine-based | B | A | 3.5 | B | B |
| Example 125A | 3 | EXP.MFS-631 | Fluorine-based | B | A | 3.5 | B | B |
| Example 126A | 3 | EXP.MFS-603 | Fluorine-based | B | A | 3.5 | B | B |
| Example 127A | 3 | C4F9xMA(PO)H | Fluorine-based | A | A | 3.5 | B | A |
| Example 128A | 3 | C4F9xMA(BO)H | Fluorine-based | B | A | 3.5 | B | B |
| Example 129A | 3 | C4F9xMA(EO)H | Fluorine-based | A | A | 3.5 | B | A |
| Example 130A | 3 | C4F9xA(PO)H | Fluorine-based | A | A | 3.5 | B | A |
| Example 131A | 3 | C4F9xA(EO)H | Fluorine-based | A | A | 3.5 | B | A |
| Example 132A | 3 | C4F9xMA(EO)Me | Fluorine-based | B | A | 3.5 | B | B |
| Example 133A | 3 | C4F9xA(EO)Me | Fluorine-based | B | A | 3.5 | B | B |
| Example 134A | 3 | PIONIN D-6115 | Hydrocarbon-based | B | A | 3.5 | B | B |
| Example 135A | 3 | PIONIN D-1105 | Hydrocarbon-based | B | A | 3.5 | B | B |
| Example 136A | 3 | EXP.S-310-2 | Silicone-based | A | A | 3.5 | A | A |
| Example 137A | 3 | EXP.S-309-2 | Silicone-based | A | A | 3.5 | A | A |
| Example 138A | 3 | EXP.S-315 | Silicone-based | A | A | 3.5 | A | A |
| Example 139A | 3 | EXP.S-503-2 | Silicone-based | A | A | 3.5 | A | A |
| Example 140A | 3 | EXP.S-505-2 | Silicone-based | A | A | 3.5 | A | A |
| Example 141A | 3 | BYK-302 | Silicone-based | B | A | 3.5 | A | B |
| Example 142A | 3 | BYK-307 | Silicone-based | B | A | 3.5 | A | B |
| Example 143A | 3 | BYK-313 | Silicone-based | A | A | 3.5 | A | A |
| Example 144A | 3 | BYK-315N | Silicone-based | A | A | 3.5 | A | A |
| Example 145A | 3 | BYK-323 | Silicone-based | A | A | 3.5 | A | A |
| Example 146A | 3 | BYK-330 | Silicone-based | A | A | 3.5 | A | A |
| Example 147A | 3 | BYK-331 | Silicone-based | B | A | 3.5 | A | B |
| Example 148A | 3 | BYK-333 | Silicone-based | B | A | 3.5 | A | B |
| Example 149A | 3 | BYK-342 | Silicone-based | B | A | 3.5 | A | B |
| Example 150A | 3 | BYK-377 | Silicone-based | A | A | 3.5 | A | A |
| Example 151A | 3 | BYK-378 | Silicone-based | B | A | 3.5 | A | B |
| Example 152A | 3 | BYK-300 | Silicone-based | A | A | 3.5 | A | A |
| Example 153A | 3 | BYK-306 | Silicone-based | A | A | 3.5 | A | A |
| Example 154A | 3 | BYK-310 | Silicone-based | A | A | 3.5 | A | A |
| Example 155A | 3 | BYK-320 | Silicone-based | A | A | 3.5 | A | A |
| Example 156A | 3 | BYK-325 | Silicone-based | B | A | 3.5 | A | B |
| Example 157A | 3 | BYK-370 | Silicone-based | A | A | 3.5 | A | A |
| Example 158A | 3 | KP-124 | Silicone-based | A | A | 3.5 | A | A |
| Example 159A | 3 | KP-109 | Silicone-based | A | A | 3.5 | A | A |
| Example 160A | 3 | KP-121 | Silicone-based | A | A | 3.5 | A | A |
| Example 161A | 3 | KP-103 | Silicone-based | A | A | 3.5 | A | A |
| Example 162A | 3 | KP-341 | Silicone-based | A | A | 3.5 | A | A |
| Example 163A | 3 | KP-112 | Silicone-based | B | A | 3.5 | A | B |
| Example 164A | 3 | KP-125 | Silicone-based | B | A | 3.5 | A | B |
| Example 165A | 3 | KP-101 | Silicone-based | B | A | 3.5 | A | B |
| Example 166A | 3 | KP-106 | Silicone-based | B | A | 3.5 | A | B |
| Example 167A | 3 | KP-120 | Silicone-based | B | A | 3.5 | A | B |
| Example 168A | 3 | KP-105 | Silicone-based | B | A | 3.5 | A | B |
| Example 169A | 3 | KP-104 | Silicone-based | B | A | 3.5 | A | B |
| Example 170A | 3 | KP-611 | Silicone-based | A | A | 3.5 | A | A |
| Example 171A | 3 | KP-626 | Silicone-based | A | A | 3.5 | A | A |
| Example 172A | 3 | KP-327 | Silicone-based | A | A | 3.5 | A | A |
| Example 173A | 3 | KP-323 | Silicone-based | A | A | 3.5 | A | A |
| Example 174A | 3 | KP-322 | Silicone-based | A | A | 3.5 | A | A |
| Example 175A | 3 | KP-310 | Silicone-based | A | A | 3.5 | A | A |
| Example 176A | 3 | KP-109 | Silicone-based | A | A | 3.5 | A | A |
| Example 177A | 3 | KP-620 | Silicone-based | A | A | 3.5 | A | A |
| Example 178A | 3 | KP-652 | Silicone-based | A | A | 3.5 | A | A |
| Example 179A | 3 | KP-306 | Silicone-based | A | A | 3.5 | A | A |
| Example 180A | 3 | KP-301 | Silicone-based | A | A | 3.5 | A | A |
| Example 181A | 3 | KP-621 | Silicone-based | A | A | 3.5 | A | A |
| Example 182A | 3 | KP-369 | Silicone-based | A | A | 3.5 | A | A |
| Example 183A | 3 | KP-368 | Silicone-based | A | A | 3.5 | A | A |

TABLE 5

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 184A | 4 | EXP.MFS-578-2 | Fluorine-based | B | A | 3.5 | B | B |
| Example 185A | 4 | EXP.MFS-628 | Fluorine-based | B | A | 3.5 | B | B |
| Example 186A | 4 | EXP.MFS-631 | Fluorine-based | B | A | 3.5 | B | B |
| Example 187A | 4 | EXP.MFS-603 | Fluorine-based | B | A | 3.5 | B | B |
| Example 188A | 4 | C4F9xMA(PO)H | Fluorine-based | A | A | 3.5 | B | A |
| Example 189A | 4 | C4F9xMA(BO)H | Fluorine-based | B | A | 3.5 | B | B |
| Example 190A | 4 | C4F9xMA(EO)H | Fluorine-based | A | A | 3.5 | B | A |
| Example 191A | 4 | C4F9xA(PO)H | Fluorine-based | A | A | 3.5 | B | A |
| Example 192A | 4 | C4F9xA(EO)H | Fluorine-based | A | A | 3.5 | B | A |
| Example 193A | 4 | C4F9xMA(EO)Me | Fluorine-based | B | A | 3.5 | B | B |
| Example 194A | 4 | C4F9xA(EO)Me | Fluorine-based | B | A | 3.5 | B | B |
| Example 195A | 4 | PIONIN D-6115 | Hydrocarbon-based | B | A | 3.5 | B | B |
| Example 196A | 4 | PIONIN D-1105 | Hydrocarbon-based | B | A | 3.5 | B | B |
| Example 197A | 4 | EXP.S-310-2 | Silicone-based | A | A | 3.5 | A | A |
| Example 198A | 4 | EXP.S-309-2 | Silicone-based | A | A | 3.5 | A | A |
| Example 199A | 4 | EXP.S-315 | Silicone-based | A | A | 3.5 | A | A |
| Example 200A | 4 | EXP.S-503-2 | Silicone-based | A | A | 3.5 | A | A |
| Example 201A | 4 | EXP.S-505-2 | Silicone-based | A | A | 3.5 | A | A |
| Example 202A | 4 | BYK-302 | Silicone-based | B | A | 3.5 | A | B |
| Example 203A | 4 | BYK-307 | Silicone-based | B | A | 3.5 | A | B |
| Example 204A | 4 | BYK-313 | Silicone-based | A | A | 3.5 | A | A |
| Example 205A | 4 | BYK-315N | Silicone-based | A | A | 3.5 | A | A |
| Example 206A | 4 | BYK-323 | Silicone-based | A | A | 3.5 | A | A |
| Example 207A | 4 | BYK-330 | Silicone-based | A | A | 3.5 | A | A |
| Example 208A | 4 | BYK-331 | Silicone-based | B | A | 3.5 | A | B |
| Example 209A | 4 | BYK-333 | Silicone-based | B | A | 3.5 | A | B |
| Example 210A | 4 | BYK-342 | Silicone-based | B | A | 3.5 | A | B |
| Example 211A | 4 | BYK-377 | Silicone-based | A | A | 3.5 | A | A |
| Example 212A | 4 | BYK-378 | Silicone-based | B | A | 3.5 | A | B |
| Example 213A | 4 | BYK-300 | Silicone-based | A | A | 3.5 | A | A |
| Example 214A | 4 | BYK-306 | Silicone-based | A | A | 3.5 | A | A |
| Example 215A | 4 | BYK-310 | Silicone-based | A | A | 3.5 | A | A |
| Example 216A | 4 | BYK-320 | Silicone-based | A | A | 3.5 | A | A |
| Example 217A | 4 | BYK-325 | Silicone-based | B | A | 3.5 | A | B |
| Example 218A | 4 | BYK-370 | Silicone-based | A | A | 3.5 | A | A |
| Example 219A | 4 | KP-124 | Silicone-based | A | A | 3.5 | A | A |
| Example 220A | 4 | KP-109 | Silicone-based | A | A | 3.5 | A | A |
| Example 221A | 4 | KP-121 | Silicone-based | A | A | 3.5 | A | A |
| Example 222A | 4 | KP-103 | Silicone-based | A | A | 3.5 | A | A |
| Example 223A | 4 | KP-341 | Silicone-based | A | A | 3.5 | A | A |
| Example 224A | 4 | KP-112 | Silicone-based | B | A | 3.5 | A | B |
| Example 225A | 4 | KP-125 | Silicone-based | B | A | 3.5 | A | B |
| Example 226A | 4 | KP-101 | Silicone-based | B | A | 3.5 | A | B |
| Example 227A | 4 | KP-106 | Silicone-based | B | A | 3.5 | A | B |
| Example 228A | 4 | KP-120 | Silicone-based | B | A | 3.5 | A | B |
| Example 229A | 4 | KP-105 | Silicone-based | B | A | 3.5 | A | B |
| Example 230A | 4 | KP-104 | Silicone-based | B | A | 3.5 | A | B |
| Example 231A | 4 | KP-611 | Silicone-based | A | A | 3.5 | A | A |
| Example 232A | 4 | KP-626 | Silicone-based | A | A | 3.5 | A | A |
| Example 233A | 4 | KP-327 | Silicone-based | A | A | 3.5 | A | A |
| Example 234A | 4 | KP-323 | Silicone-based | A | A | 3.5 | A | A |
| Example 235A | 4 | KP-322 | Silicone-based | A | A | 3.5 | A | A |
| Example 236A | 4 | KP-310 | Silicone-based | A | A | 3.5 | A | A |
| Example 237A | 4 | KP-109 | Silicone-based | A | A | 3.5 | A | A |
| Example 238A | 4 | KP-620 | Silicone-based | A | A | 3.5 | A | A |
| Example 239A | 4 | KP-652 | Silicone-based | A | A | 3.5 | A | A |
| Example 240A | 4 | KP-306 | Silicone-based | A | A | 3.5 | A | A |
| Example 241A | 4 | KP-301 | Silicone-based | A | A | 3.5 | A | A |
| Example 242A | 4 | KP-621 | Silicone-based | A | A | 3.5 | A | A |
| Example 243A | 4 | KP-369 | Silicone-based | A | A | 3.5 | A | A |
| Example 244A | 4 | KP-368 | Silicone-based | A | A | 3.5 | A | A |

TABLE 6

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 245A | 5 | EXP.MFS-578-2 | Fluorine-based | B | A | 2.9 | B | B |
| Example 246A | 5 | EXP.MFS-628 | Fluorine-based | B | A | 2.9 | B | B |
| Example 247A | 5 | EXP.MFS-631 | Fluorine-based | B | A | 2.9 | B | B |
| Example 248A | 5 | EXP.MFS-603 | Fluorine-based | B | A | 2.9 | B | B |
| Example 249A | 5 | C4F9xMA(PO)H | Fluorine-based | A | A | 2.9 | B | A |
| Example 250A | 5 | C4F9xMA(BO)H | Fluorine-based | B | A | 2.9 | B | B |
| Example 251A | 5 | C4F9xMA(EO)H | Fluorine-based | A | A | 2.9 | B | A |
| Example 252A | 5 | C4F9xA(PO)H | Fluorine-based | A | A | 2.9 | B | A |
| Example 253A | 5 | C4F9xA(EO)H | Fluorine-based | A | A | 2.9 | B | A |
| Example 254A | 5 | C4F9xMA(EO)Me | Fluorine-based | B | A | 2.9 | B | B |
| Example 255A | 5 | C4F9xA(EO)Me | Fluorine-based | B | A | 2.9 | B | B |
| Example 256A | 5 | D-6115 | Hydrocarbon-based | B | A | 2.9 | B | B |
| Example 257A | 5 | D-1105 | Hydrocarbon-based | B | A | 2.9 | B | B |
| Example 258A | 5 | EXP.S-310-2 | Silicone-based | A | A | 2.9 | A | A |
| Example 259A | 5 | EXP.S-309-2 | Silicone-based | A | A | 2.9 | A | A |
| Example 260A | 5 | EXP.S-315 | Silicone-based | A | A | 2.9 | A | A |
| Example 261A | 5 | EXP.S-503-2 | Silicone-based | A | A | 2.9 | A | A |
| Example 262A | 5 | EXP.S-505-2 | Silicone-based | A | A | 2.9 | A | A |
| Example 263A | 5 | BYK-302 | Silicone-based | B | A | 2.9 | A | B |
| Example 264A | 5 | BYK-307 | Silicone-based | B | A | 2.9 | A | B |
| Example 265A | 5 | BYK-313 | Silicone-based | A | A | 2.9 | A | A |
| Example 266A | 5 | BYK-315N | Silicone-based | A | A | 2.9 | A | A |
| Example 267A | 5 | BYK-323 | Silicone-based | A | A | 2.9 | A | A |
| Example 268A | 5 | BYK-330 | Silicone-based | A | A | 2.9 | A | A |
| Example 269A | 5 | BYK-331 | Silicone-based | B | A | 2.9 | A | B |
| Example 270A | 5 | BYK-333 | Silicone-based | B | A | 2.9 | A | B |
| Example 271A | 5 | BYK-342 | Silicone-based | B | A | 2.9 | A | B |
| Example 272A | 5 | BYK-377 | Silicone-based | A | A | 2.9 | A | A |
| Example 273A | 5 | BYK-378 | Silicone-based | B | A | 2.9 | A | B |
| Example 274A | 5 | BYK-300 | Silicone-based | A | A | 2.9 | A | A |
| Example 275A | 5 | BYK-306 | Silicone-based | A | A | 2.9 | A | A |
| Example 276A | 5 | BYK-310 | Silicone-based | A | A | 2.9 | A | A |
| Example 277A | 5 | BYK-320 | Silicone-based | A | A | 2.9 | A | A |
| Example 278A | 5 | BYK-325 | Silicone-based | B | A | 2.9 | A | B |
| Example 279A | 5 | BYK-370 | Silicone-based | A | A | 2.9 | A | A |
| Example 280A | 5 | KP-124 | Silicone-based | A | A | 2.9 | A | A |
| Example 281A | 5 | KP-109 | Silicone-based | A | A | 2.9 | A | A |
| Example 282A | 5 | KP-121 | Silicone-based | A | A | 2.9 | A | A |
| Example 283A | 5 | KP-103 | Silicone-based | A | A | 2.9 | A | A |
| Example 284A | 5 | KP-341 | Silicone-based | A | A | 2.9 | A | A |
| Example 285A | 5 | KP-112 | Silicone-based | B | A | 2.9 | A | B |
| Example 286A | 5 | KP-125 | Silicone-based | B | A | 2.9 | A | B |
| Example 287A | 5 | KP-101 | Silicone-based | B | A | 2.9 | A | B |
| Example 288A | 5 | KP-106 | Silicone-based | B | A | 2.9 | A | B |
| Example 289A | 5 | KP-120 | Silicone-based | B | A | 2.9 | A | B |
| Example 290A | 5 | KP-105 | Silicone-based | B | A | 2.9 | A | B |
| Example 291A | 5 | KP-104 | Silicone-based | B | A | 2.9 | A | B |
| Example 292A | 5 | KP-611 | Silicone-based | A | A | 2.9 | A | A |
| Example 293A | 5 | KP-626 | Silicone-based | A | A | 2.9 | A | A |
| Example 294A | 5 | KP-327 | Silicone-based | A | A | 2.9 | A | A |
| Example 295A | 5 | KP-323 | Silicone-based | A | A | 2.9 | A | A |
| Example 296A | 5 | KP-322 | Silicone-based | A | A | 2.9 | A | A |
| Example 297A | 5 | KP-310 | Silicone-based | A | A | 2.9 | A | A |
| Example 298A | 5 | KP-109 | Silicone-based | A | A | 2.9 | A | A |
| Example 299A | 5 | KP-620 | Silicone-based | A | A | 2.9 | A | A |
| Example 300A | 5 | KP-652 | Silicone-based | A | A | 2.9 | A | A |
| Example 301A | 5 | KP-306 | Silicone-based | A | A | 2.9 | A | A |
| Example 302A | 5 | KP-301 | Silicone-based | A | A | 2.9 | A | A |
| Example 303A | 5 | KP-621 | Silicone-based | A | A | 2.9 | A | A |
| Example 304A | 5 | KP-369 | Silicone-based | A | A | 2.9 | A | A |
| Example 305A | 5 | KP-368 | Silicone-based | A | A | 2.9 | A | A |

TABLE 7

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 306A | 6 | EXP.MFS-578-2 | Fluorine-based | B | A | 2.5 | B | B |
| Example 307A | 6 | EXP.MFS-628 | Fluorine-based | B | A | 2.5 | B | B |
| Example 308A | 6 | EXP.MFS-631 | Fluorine-based | B | A | 2.5 | B | B |
| Example 309A | 6 | EXP.MFS-603 | Fluorine-based | B | A | 2.5 | B | B |
| Example 310A | 6 | C4F9xMA(PO)H | Fluorine-based | A | A | 2.5 | B | A |
| Example 311A | 6 | C4F9xMA(BO)H | Fluorine-based | B | A | 2.5 | B | B |
| Example 312A | 6 | C4F9xMA(EO)H | Fluorine-based | A | A | 2.5 | B | A |
| Example 313A | 6 | C4F9xA(PO)H | Fluorine-based | A | A | 2.5 | B | A |
| Example 314A | 6 | C4F9xA(EO)H | Fluorine-based | A | A | 2.5 | B | A |
| Example 315A | 6 | C4F9xMA(EO)Me | Fluorine-based | B | A | 2.5 | B | B |
| Example 316A | 6 | C4F9xA(EO)Me | Fluorine-based | B | A | 2.5 | B | B |
| Example 317A | 6 | D-6115 | Hydrocarbon-based | B | A | 2.5 | B | B |
| Example 318A | 6 | D-1105 | Hydrocarbon-based | B | A | 2.5 | B | B |
| Example 319A | 6 | EXP.S-310-2 | Silicone-based | A | A | 2.5 | A | A |
| Example 320A | 6 | EXP.S-309-2 | Silicone-based | A | A | 2.5 | A | A |
| Example 321A | 6 | EXP.S-315 | Silicone-based | A | A | 2.5 | A | A |
| Example 322A | 6 | EXP.S-503-2 | Silicone-based | A | A | 2.5 | A | A |
| Example 323A | 6 | EXP.S-505-2 | Silicone-based | A | A | 2.5 | A | A |
| Example 324A | 6 | BYK-302 | Silicone-based | B | A | 2.5 | A | B |
| Example 325A | 6 | BYK-307 | Silicone-based | B | A | 2.5 | A | B |
| Example 326A | 6 | BYK-313 | Silicone-based | A | A | 2.5 | A | A |
| Example 327A | 6 | BYK-315N | Silicone-based | A | A | 2.5 | A | A |
| Example 328A | 6 | BYK-323 | Silicone-based | A | A | 2.5 | A | A |
| Example 329A | 6 | BYK-330 | Silicone-based | A | A | 2.5 | A | A |
| Example 330A | 6 | BYK-331 | Silicone-based | B | A | 2.5 | A | B |
| Example 331A | 6 | BYK-333 | Silicone-based | B | A | 2.5 | A | B |
| Example 332A | 6 | BYK-342 | Silicone-based | B | A | 2.5 | A | B |
| Example 333A | 6 | BYK-377 | Silicone-based | A | A | 2.5 | A | A |
| Example 334A | 6 | BYK-378 | Silicone-based | B | A | 2.5 | A | B |
| Example 335A | 6 | BYK-300 | Silicone-based | A | A | 2.5 | A | A |
| Example 336A | 6 | BYK-306 | Silicone-based | A | A | 2.5 | A | A |
| Example 337A | 6 | BYK-310 | Silicone-based | A | A | 2.5 | A | A |
| Example 338A | 6 | BYK-320 | Silicone-based | A | A | 2.5 | A | A |
| Example 339A | 6 | BYK-325 | Silicone-based | B | A | 2.5 | A | B |
| Example 340A | 6 | BYK-370 | Silicone-based | A | A | 2.5 | A | A |
| Example 341A | 6 | KP-124 | Silicone-based | A | A | 2.5 | A | A |
| Example 342A | 6 | KP-109 | Silicone-based | A | A | 2.5 | A | A |
| Example 343A | 6 | KP-121 | Silicone-based | A | A | 2.5 | A | A |
| Example 344A | 6 | KP-103 | Silicone-based | A | A | 2.5 | A | A |
| Example 345A | 6 | KP-341 | Silicone-based | A | A | 2.5 | A | A |
| Example 346A | 6 | KP-112 | Silicone-based | B | A | 2.5 | A | B |
| Example 347A | 6 | KP-125 | Silicone-based | B | A | 2.5 | A | B |
| Example 348A | 6 | KP-101 | Silicone-based | B | A | 2.5 | A | B |
| Example 349A | 6 | KP-106 | Silicone-based | B | A | 2.5 | A | B |
| Example 350A | 6 | KP-120 | Silicone-based | B | A | 2.5 | A | B |
| Example 351A | 6 | KP-105 | Silicone-based | B | A | 2.5 | A | B |
| Example 352A | 6 | KP-104 | Silicone-based | B | A | 2.5 | A | B |
| Example 353A | 6 | KP-611 | Silicone-based | A | A | 2.5 | A | A |
| Example 354A | 6 | KP-626 | Silicone-based | A | A | 2.5 | A | A |
| Example 355A | 6 | KP-327 | Silicone-based | A | A | 2.5 | A | A |
| Example 356A | 6 | KP-323 | Silicone-based | A | A | 2.5 | A | A |
| Example 357A | 6 | KP-322 | Silicone-based | A | A | 2.5 | A | A |
| Example 358A | 6 | KP-310 | Silicone-based | A | A | 2.5 | A | A |
| Example 359A | 6 | KP-109 | Silicone-based | A | A | 2.5 | A | A |
| Example 360A | 6 | KP-620 | Silicone-based | A | A | 2.5 | A | A |
| Example 361A | 6 | KP-652 | Silicone-based | A | A | 2.5 | A | A |
| Example 362A | 6 | KP-306 | Silicone-based | A | A | 2.5 | A | A |
| Example 363A | 6 | KP-301 | Silicone-based | A | A | 2.5 | A | A |
| Example 364A | 6 | KP-621 | Silicone-based | A | A | 2.5 | A | A |
| Example 365A | 6 | KP-369 | Silicone-based | A | A | 2.5 | A | A |
| Example 366A | 6 | KP-368 | Silicone-based | A | A | 2.5 | A | A |

TABLE 8

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 367A | 7 | EXP.MFS-578-2 | Fluorine-based | B | A | 2.5 | B | B |
| Example 368A | 7 | EXP.MFS-628 | Fluorine-based | B | A | 2.5 | B | B |
| Example 369A | 7 | EXP.MFS-631 | Fluorine-based | B | A | 2.5 | B | B |
| Example 370A | 7 | EXP.MFS-603 | Fluorine-based | B | A | 2.5 | B | B |
| Example 371A | 7 | C4F9xMA(PO)H | Fluorine-based | A | A | 2.5 | B | A |
| Example 372A | 7 | C4F9xMA(BO)H | Fluorine-based | B | A | 2.5 | B | B |
| Example 373A | 7 | C4F9xMA(EO)H | Fluorine-based | A | A | 2.5 | B | A |
| Example 374A | 7 | C4F9xA(PO)H | Fluorine-based | A | A | 2.5 | B | A |
| Example 375A | 7 | C4F9xA(EO)H | Fluorine-based | A | A | 2.5 | B | A |
| Example 376A | 7 | C4F9xMA(EO)Me | Fluorine-based | B | A | 2.5 | B | B |
| Example 377A | 7 | C4F9xA(EO)Me | Fluorine-based | B | A | 2.5 | B | B |
| Example 378A | 7 | D-6115 | Hydrocarbon-based | B | A | 2.5 | B | B |
| Example 379A | 7 | D-1105 | Hydrocarbon-based | B | A | 2.5 | B | B |
| Example 380A | 7 | EXP.S-310-2 | Silicone-based | A | A | 2.5 | A | A |
| Example 381A | 7 | EXP.S-309-2 | Silicone-based | A | A | 2.5 | A | A |
| Example 382A | 7 | EXP.S-315 | Silicone-based | A | A | 2.5 | A | A |
| Example 383A | 7 | EXP.S-503-2 | Silicone-based | A | A | 2.5 | A | A |
| Example 384A | 7 | EXP.S-505-2 | Silicone-based | A | A | 2.5 | A | A |
| Example 385A | 7 | BYK-302 | Silicone-based | B | A | 2.5 | A | B |
| Example 386A | 7 | BYK-307 | Silicone-based | B | A | 2.5 | A | B |
| Example 387A | 7 | BYK-313 | Silicone-based | A | A | 2.5 | A | A |
| Example 388A | 7 | BYK-315N | Silicone-based | A | A | 2.5 | A | A |
| Example 389A | 7 | BYK-323 | Silicone-based | A | A | 2.5 | A | A |
| Example 390A | 7 | BYK-330 | Silicone-based | A | A | 2.5 | A | A |
| Example 391A | 7 | BYK-331 | Silicone-based | B | A | 2.5 | A | B |
| Example 392A | 7 | BYK-333 | Silicone-based | B | A | 2.5 | A | B |
| Example 393A | 7 | BYK-342 | Silicone-based | B | A | 2.5 | A | B |
| Example 394A | 7 | BYK-377 | Silicone-based | A | A | 2.5 | A | A |
| Example 395A | 7 | BYK-378 | Silicone-based | B | A | 2.5 | A | B |
| Example 396A | 7 | BYK-300 | Silicone-based | A | A | 2.5 | A | A |
| Example 397A | 7 | BYK-306 | Silicone-based | A | A | 2.5 | A | A |
| Example 398A | 7 | BYK-310 | Silicone-based | A | A | 2.5 | A | A |
| Example 399A | 7 | BYK-320 | Silicone-based | A | A | 2.5 | A | A |
| Example 400A | 7 | BYK-325 | Silicone-based | B | A | 2.5 | A | B |
| Example 401A | 7 | BYK-370 | Silicone-based | A | A | 2.5 | A | A |
| Example 402A | 7 | KP-124 | Silicone-based | A | A | 2.5 | A | A |
| Example 403A | 7 | KP-109 | Silicone-based | A | A | 2.5 | A | A |
| Example 404A | 7 | KP-121 | Silicone-based | A | A | 2.5 | A | A |
| Example 405A | 7 | KP-103 | Silicone-based | A | A | 2.5 | A | A |
| Example 406A | 7 | KP-341 | Silicone-based | A | A | 2.5 | A | A |
| Example 407A | 7 | KP-112 | Silicone-based | B | A | 2.5 | A | B |
| Example 408A | 7 | KP-125 | Silicone-based | B | A | 2.5 | A | B |
| Example 409A | 7 | KP-101 | Silicone-based | B | A | 2.5 | A | B |
| Example 410A | 7 | KP-106 | Silicone-based | B | A | 2.5 | A | B |
| Example 411A | 7 | KP-120 | Silicone-based | B | A | 2.5 | A | B |
| Example 412A | 7 | KP-105 | Silicone-based | B | A | 2.5 | A | B |
| Example 413A | 7 | KP-104 | Silicone-based | B | A | 2.5 | A | B |
| Example 414A | 7 | KP-611 | Silicone-based | A | A | 2.5 | A | A |
| Example 415A | 7 | KP-626 | Silicone-based | A | A | 2.5 | A | A |
| Example 416A | 7 | KP-327 | Silicone-based | A | A | 2.5 | A | A |
| Example 417A | 7 | KP-323 | Silicone-based | A | A | 2.5 | A | A |
| Example 418A | 7 | KP-322 | Silicone-based | A | A | 2.5 | A | A |
| Example 419A | 7 | KP-310 | Silicone-based | A | A | 2.5 | A | A |
| Example 420A | 7 | KP-109 | Silicone-based | A | A | 2.5 | A | A |
| Example 421A | 7 | KP-620 | Silicone-based | A | A | 2.5 | A | A |
| Example 422A | 7 | KP-652 | Silicone-based | A | A | 2.5 | A | A |
| Example 423A | 7 | KP-306 | Silicone-based | A | A | 2.5 | A | A |
| Example 424A | 7 | KP-301 | Silicone-based | A | A | 2.5 | A | A |
| Example 425A | 7 | KP-621 | Silicone-based | A | A | 2.5 | A | A |
| Example 426A | 7 | KP-369 | Silicone-based | A | A | 2.5 | A | A |
| Example 427A | 7 | KP-368 | Silicone-based | A | A | 2.5 | A | A |

TABLE 9

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 428A | 8 | EXP.MFS-578-2 | Fluorine-based | B | A | 3.5 | B | B |
| Example 429A | 8 | EXP.MFS-628 | Fluorine-based | B | A | 3.5 | B | B |
| Example 430A | 8 | EXP.MFS-631 | Fluorine-based | B | A | 3.5 | B | B |
| Example 431A | 8 | EXP.MFS-603 | Fluorine-based | B | A | 3.5 | B | B |
| Example 432A | 8 | C4F9xMA(PO)H | Fluorine-based | A | A | 3.5 | B | A |
| Example 433A | 8 | C4F9xMA(BO)H | Fluorine-based | B | A | 3.5 | B | B |
| Example 434A | 8 | C4F9xMA(EO)H | Fluorine-based | A | A | 3.5 | B | A |
| Example 435A | 8 | C4F9xA(PO)H | Fluorine-based | A | A | 3.5 | B | A |
| Example 436A | 8 | C4F9xA(EO)H | Fluorine-based | A | A | 3.5 | B | A |
| Example 437A | 8 | C4F9xMA(EO)Me | Fluorine-based | B | A | 3.5 | B | B |
| Example 438A | 8 | C4F9xA(EO)Me | Fluorine-based | B | A | 3.5 | B | B |
| Example 439A | 8 | D-6115 | Hydrocarbon-based | B | A | 3.5 | B | B |
| Example 440A | 8 | D-1105 | Hydrocarbon-based | B | A | 3.5 | B | B |
| Example 441A | 8 | EXP.S-310-2 | Silicone-based | A | A | 3.5 | A | A |
| Example 442A | 8 | EXP.S-309-2 | Silicone-based | A | A | 3.5 | A | A |
| Example 443A | 8 | EXP.S-315 | Silicone-based | A | A | 3.5 | A | A |
| Example 444A | 8 | EXP.S-503-2 | Silicone-based | A | A | 3.5 | A | A |
| Example 445A | 8 | EXP.S-505-2 | Silicone-based | A | A | 3.5 | A | A |
| Example 446A | 8 | BYK-302 | Silicone-based | B | A | 3.5 | A | B |
| Example 447A | 8 | BYK-307 | Silicone-based | B | A | 3.5 | A | B |
| Example 448A | 8 | BYK-313 | Silicone-based | A | A | 3.5 | A | A |
| Example 449A | 8 | BYK-315N | Silicone-based | A | A | 3.5 | A | A |
| Example 450A | 8 | BYK-323 | Silicone-based | A | A | 3.5 | A | A |
| Example 451A | 8 | BYK-330 | Silicone-based | A | A | 3.5 | A | A |
| Example 452A | 8 | BYK-331 | Silicone-based | B | A | 3.5 | A | B |
| Example 453A | 8 | BYK-333 | Silicone-based | B | A | 3.5 | A | B |
| Example 454A | 8 | BYK-342 | Silicone-based | B | A | 3.5 | A | B |
| Example 455A | 8 | BYK-377 | Silicone-based | A | A | 3.5 | A | A |
| Example 456A | 8 | BYK-378 | Silicone-based | B | A | 3.5 | A | B |
| Example 457A | 8 | BYK-300 | Silicone-based | A | A | 3.5 | A | A |
| Example 458A | 8 | BYK-306 | Silicone-based | A | A | 3.5 | A | A |
| Example 459A | 8 | BYK-310 | Silicone-based | A | A | 3.5 | A | A |
| Example 460A | 8 | BYK-320 | Silicone-based | A | A | 3.5 | A | A |
| Example 461A | 8 | BYK-325 | Silicone-based | B | A | 3.5 | A | B |
| Example 462A | 8 | BYK-370 | Silicone-based | A | A | 3.5 | A | A |
| Example 463A | 8 | KP-124 | Silicone-based | A | A | 3.5 | A | A |
| Example 464A | 8 | KP-109 | Silicone-based | A | A | 3.5 | A | A |
| Example 465A | 8 | KP-121 | Silicone-based | A | A | 3.5 | A | A |
| Example 466A | 8 | KP-103 | Silicone-based | A | A | 3.5 | A | A |
| Example 467A | 8 | KP-341 | Silicone-based | A | A | 3.5 | A | A |
| Example 468A | 8 | KP-112 | Silicone-based | B | A | 3.5 | A | B |
| Example 469A | 8 | KP-125 | Silicone-based | B | A | 3.5 | A | B |
| Example 470A | 8 | KP-101 | Silicone-based | B | A | 3.5 | A | B |
| Example 471A | 8 | KP-106 | Silicone-based | B | A | 3.5 | A | B |
| Example 472A | 8 | KP-120 | Silicone-based | B | A | 3.5 | A | B |
| Example 473A | 8 | KP-105 | Silicone-based | B | A | 3.5 | A | B |
| Example 474A | 8 | KP-104 | Silicone-based | B | A | 3.5 | A | B |
| Example 475A | 8 | KP-611 | Silicone-based | A | A | 3.5 | A | A |
| Example 476A | 8 | KP-626 | Silicone-based | A | A | 3.5 | A | A |
| Example 477A | 8 | KP-327 | Silicone-based | A | A | 3.5 | A | A |
| Example 478A | 8 | KP-323 | Silicone-based | A | A | 3.5 | A | A |
| Example 479A | 8 | KP-322 | Silicone-based | A | A | 3.5 | A | A |
| Example 480A | 8 | KP-310 | Silicone-based | A | A | 3.5 | A | A |
| Example 481A | 8 | KP-109 | Silicone-based | A | A | 3.5 | A | A |
| Example 482A | 8 | KP-620 | Silicone-based | A | A | 3.5 | A | A |
| Example 483A | 8 | KP-652 | Silicone-based | A | A | 3.5 | A | A |
| Example 484A | 8 | KP-306 | Silicone-based | A | A | 3.5 | A | A |
| Example 485A | 8 | KP-301 | Silicone-based | A | A | 3.5 | A | A |
| Example 486A | 8 | KP-621 | Silicone-based | A | A | 3.5 | A | A |
| Example 487A | 8 | KP-369 | Silicone-based | A | A | 3.5 | A | A |
| Example 488A | 8 | KP-368 | Silicone-based | A | A | 3.5 | A | A |

TABLE 10

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 489A | 9 | EXP.MFS-578-2 | Fluorine-based | B | A | 5.5 | B | B |
| Example 490A | 9 | EXP.MFS-628 | Fluorine-based | B | A | 5.5 | B | B |
| Example 491A | 9 | EXP.S-310-2 | Silicone-based | A | A | 5.5 | A | A |
| Example 492A | 9 | EXP.S-309-2 | Silicone-based | A | A | 5.5 | A | A |
| Example 493A | 9 | EXP.S-315 | Silicone-based | A | A | 5.5 | A | A |
| Example 494A | 9 | BYK-302 | Silicone-based | A | A | 5.5 | A | A |
| Example 495A | 10 | EXP.MFS-578-2 | Fluorine-based | B | A | 5.5 | B | B |
| Example 496A | 10 | EXP.MFS-628 | Fluorine-based | B | A | 5.5 | B | B |
| Example 497A | 10 | EXP.S-310-2 | Silicone-based | A | A | 5.5 | A | A |
| Example 498A | 10 | EXP.S-309-2 | Silicone-based | A | A | 5.5 | A | A |
| Example 499A | 10 | EXP.S-315 | Silicone-based | A | A | 5.5 | A | A |
| Example 500A | 10 | BYK-302 | Silicone-based | A | A | 5.5 | A | A |

TABLE 11

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Example 489A | 11 | EXP.MFS-578-2 | Fluorine-based | B | A | 1.9 | B | B |
| Example 502A | 11 | EXP.MFS-628 | Fluorine-based | B | A | 1.9 | B | B |
| Example 503A | 11 | EXP.MFS-631 | Fluorine-based | B | A | 1.9 | B | B |
| Example 504A | 11 | EXP.MFS-603 | Fluorine-based | B | A | 1.9 | B | B |
| Example 505A | 11 | C4F9xMA(PO)H | Fluorine-based | A | A | 1.9 | B | A |
| Example 506A | 11 | C4F9xMA(BO)H | Fluorine-based | B | A | 1.9 | B | B |
| Example 507A | 11 | C4F9xMA(EO)H | Fluorine-based | A | A | 1.9 | B | A |
| Example 508A | 11 | C4F9xA(PO)H | Fluorine-based | A | A | 1.9 | B | A |
| Example 509A | 11 | C4F9xA(EO)H | Fluorine-based | A | A | 1.9 | B | A |
| Example 510A | 11 | C4F9xMA(EO)Me | Fluorine-based | B | A | 1.9 | B | B |
| Example 511A | 11 | C4F9xA(EO)Me | Fluorine-based | B | A | 1.9 | B | B |
| Example 512A | 11 | D-6115 | Hydrocarbon-based | B | A | 1.9 | B | B |
| Example 513A | 11 | D-1105 | Hydrocarbon-based | B | A | 1.9 | B | B |
| Example 514A | 11 | EXP.S-310-2 | Silicone-based | A | A | 1.9 | A | A |
| Example 515A | 11 | EXP.S-309-2 | Silicone-based | A | A | 1.9 | A | A |
| Example 516A | 11 | EXP.S-315 | Silicone-based | A | A | 1.9 | A | A |
| Example 517A | 11 | EXP.S-503-2 | Silicone-based | A | A | 1.9 | A | A |
| Example 518A | 11 | EXP.S-505-2 | Silicone-based | A | A | 1.9 | A | A |
| Example 519A | 11 | BYK-302 | Silicone-based | B | A | 1.9 | A | B |
| Example 520A | 11 | BYK-307 | Silicone-based | B | A | 1.9 | A | B |
| Example 521A | 11 | BYK-313 | Silicone-based | A | A | 1.9 | A | A |
| Example 522A | 11 | BYK-315N | Silicone-based | A | A | 1.9 | A | A |
| Example 523A | 11 | BYK-323 | Silicone-based | A | A | 1.9 | A | A |
| Example 524A | 11 | BYK-330 | Silicone-based | A | A | 1.9 | A | A |
| Example 525A | 11 | BYK-331 | Silicone-based | B | A | 1.9 | A | B |
| Example 526A | 11 | BYK-333 | Silicone-based | B | A | 1.9 | A | B |
| Example 527A | 11 | BYK-342 | Silicone-based | B | A | 1.9 | A | B |
| Example 528A | 11 | BYK-377 | Silicone-based | A | A | 1.9 | A | A |
| Example 529A | 11 | BYK-378 | Silicone-based | B | A | 1.9 | A | B |
| Example 530A | 11 | BYK-300 | Silicone-based | A | A | 1.9 | A | A |
| Example 531A | 11 | BYK-306 | Silicone-based | A | A | 1.9 | A | A |
| Example 532A | 11 | BYK-310 | Silicone-based | A | A | 1.9 | A | A |
| Example 533A | 11 | BYK-320 | Silicone-based | A | A | 1.9 | A | A |
| Example 534A | 11 | BYK-325 | Silicone-based | B | A | 1.9 | A | B |
| Example 535A | 11 | BYK-370 | Silicone-based | A | A | 1.9 | A | A |
| Example 536A | 11 | KP-124 | Silicone-based | A | A | 1.9 | A | A |
| Example 537A | 11 | KP-109 | Silicone-based | A | A | 1.9 | A | A |
| Example 538A | 11 | KP-121 | Silicone-based | A | A | 1.9 | A | A |
| Example 539A | 11 | KP-103 | Silicone-based | A | A | 1.9 | A | A |
| Example 540A | 11 | KP-341 | Silicone-based | A | A | 1.9 | A | A |
| Example 541A | 11 | KP-112 | Silicone-based | B | A | 1.9 | A | B |
| Example 542A | 11 | KP-125 | Silicone-based | B | A | 1.9 | A | B |
| Example 543A | 11 | KP-101 | Silicone-based | B | A | 1.9 | A | B |
| Example 544A | 11 | KP-106 | Silicone-based | B | A | 1.9 | A | B |
| Example 545A | 11 | KP-120 | Silicone-based | B | A | 1.9 | A | B |
| Example 546A | 11 | KP-105 | Silicone-based | B | A | 1.9 | A | B |
| Example 547A | 11 | KP-104 | Silicone-based | B | A | 1.9 | A | B |
| Example 548A | 11 | KP-611 | Silicone-based | A | A | 1.9 | A | A |
| Example 549A | 11 | KP-626 | Silicone-based | A | A | 1.9 | A | A |
| Example 550A | 11 | KP-327 | Silicone-based | A | A | 1.9 | A | A |
| Example 551A | 11 | KP-323 | Silicone-based | A | A | 1.9 | A | A |
| Example 552A | 11 | KP-322 | Silicone-based | A | A | 1.9 | A | A |
| Example 553A | 11 | KP-310 | Silicone-based | A | A | 1.9 | A | A |
| Example 554A | 11 | KP-109 | Silicone-based | A | A | 1.9 | A | A |
| Example 555A | 11 | KP-620 | Silicone-based | A | A | 1.9 | A | A |
| Example 556A | 11 | KP-652 | Silicone-based | A | A | 1.9 | A | A |
| Example 557A | 11 | KP-306 | Silicone-based | A | A | 1.9 | A | A |
| Example 558A | 11 | KP-301 | Silicone-based | A | A | 1.9 | A | A |
| Example 559A | 11 | KP-621 | Silicone-based | A | A | 1.9 | A | A |
| Example 560A | 11 | KP-369 | Silicone-based | A | A | 1.9 | A | A |
| Example 561A | 11 | KP-368 | Silicone-based | A | A | 1.9 | A | A |
| Example 562A | 11 | C6F13 | Fluorine-based | E | E | 5.5 | C | B |

TABLE 12

| | Photosensitive composition | | | | | | | |
|---|---|---|---|---|---|---|---|---|
| | | | Surfactant A | | | | | |
| | | Thickness | | | Amount | Surface tension | Surfactant B | |
| | No. | (μm) | Name | Classification | (%) | (methanol/water) | Name | Classification |
| Example 563A | OC-1 | 12 | EXP.S-324 | Silicone-based | 0.19 | A | EXP.S-506 | Silicone-based |
| Example 564A | OC-2 | 12 | EXP.S-324 | Silicone-based | 0.19 | A | EXP.S-309-2 | Silicone-based |
| Example 565A | OC-3 | 12 | S-1 | Silicone-based | 0.19 | A | S-2 | Silicone-based |
| Example 566A | OC-4 | 13 | EXP.S-324 | Silicone-based | 0.16 | A | EXP.S-506 | Silicone-based |
| Example 567A | OC-5 | 13 | EXP.S-324 | Silicone-based | 0.16 | A | EXP.S-309-2 | Silicone-based |
| Example 568A | OC-6 | 13 | S-1 | Silicone-based | 0.16 | A | S-2 | Silicone-based |

| | Photosensitive composition | | | Photosensitive | | |
|---|---|---|---|---|---|---|
| | Surfactant B | | | layer | Evaluation | |
| | Amount | Surface tension | Surface | Thickness | Foaming | Defoaming |
| | (%) | (methanol/water) | tenstion | (μm) | property | property |
| Example 563A | 0.07 | A | A | 5.5 | A | A |
| Example 564A | 0.07 | A | A | 5.5 | A | A |
| Example 565A | 0.07 | A | A | 5.5 | A | A |
| Example 566A | 0.06 | A | A | 8.1 | A | A |
| Example 567A | 0.06 | A | A | 8.1 | A | A |
| Example 568A | 0.06 | A | A | 8.1 | A | A |

TABLE 13

| | Photosensitive composition | | | | | Photosensitive | | |
|---|---|---|---|---|---|---|---|---|
| | | Surfactant | | | | layer | Evaluation | |
| | | | | Surface tension | Surface | Thickness | Foaming | Defoaming |
| | Composition | Name | Classification | (methanol/water) | tension | (μm) | property | property |
| Comparative Example 1A | 1 | — | — | — | — | 5.5 | B | C |
| Comparative Example 2A | 1 | BYK-348 | Silicone-based | E | B | 5.5 | B | C |

In the surfactant described in Tables 2 to 13, names including “EXP.” are product names manufactured by DIC Corporation.

In the surfactant described in Tables 2 to 13, names including “BYK” are product names manufactured by BYK Chemie Japan.

In the surfactant described in Tables 2 to 13, names including “KP” are product names manufactured by Shin-Etsu Chemical Co., Ltd.

In the surfactant described in Tables 2 to 13, names including “PIONIN” are product names manufactured by Takemoto Oil&Fat Co., Ltd.

Each of the photosensitive compositions of Examples 1A to 568A corresponds to the composition according to the first embodiment described above. Tables 2 to 13 show that, in Examples, the disappearance time of bubbles is shorter than that of Comparative Example even in case where the bubbles are generated by the developing step.

Synthesis of Binder Polymer P′-1

Propylene glycol monomethyl ether (270.0 g) was charged into a three-necked flask and heated to 70° C. under a nitrogen stream while stirring. On the other hand, allyl methacrylate (45.6 g, FUJIFILM Wako Pure Chemical Corporation) and methacrylic acid (14.4 g) were dissolved in propylene glycol monomethyl ether (270.0 g), V-65 (3.94 g, FUJIFILM Wako Pure Chemical Corporation) was further dissolved therein to produce a dropping solution, and then the obtained dropping solution was added dropwise to the three-necked flask over 2.5 hours. The obtained solution was reacted for 2 hours while stirring. Thereafter, the obtained solution was allows to cool to room temperature, and while stirring an ion exchange water (2.7 L), the obtained was added dropwise to the ion exchange water, and then reprecipitation was performed to obtain a suspension. A filtration was performed by introducing the suspension in Nutche with a filter paper, and the filtered material was further washed with ion exchange water to obtain a wet binder polymer P′-1 powder. Next, the powder was dried by blowing air at 45° C., and it was confirmed that the amount was constant to obtain a binder polymer P′-1 as a powder in a yield of 70%. A structural formula of the binder polymer P′-1 is shown below. The ratio of each constitutional unit included in the following binder polymer P′-1 is expressed by % by mass. The weight-average molecular weight of the binder polymer P′-1 was 37000.

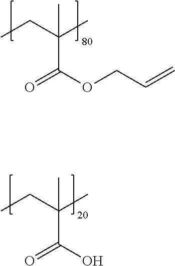

Preparation of Composition for Forming Coating Film

Compositions for forming a coating film were prepared according to compositions shown in Tables 14 and 15. The unit of the amount of each component in Tables 14 to 15 is parts by mass.

TABLE 14

| | YA-1 | YA-2 | YA-3 | YA-4 | YA-5 | YA-6 | YA-7 | YA-8 | YA-9 | YA-10 |
|---|---|---|---|---|---|---|---|---|---|---|
| NanoUse OZ-S30M: ZrO2 | 4.34 | 4.34 | 4.34 | 4.34 | 4.34 | 4.34 | 4.34 | 4.34 | 4.33 | 4.34 |
| particles methanol | | | | | | | | | | |
| dispersion liquid | | | | | | | | | | |
| (non-volatile component: | | | | | | | | | | |
| 30.5%) (Nissan Chemical | | | | | | | | | | |
| Corporation) | | | | | | | | | | |
| Ammonia water (25%) | 7.84 | 7.84 | 7.84 | 7.84 | 7.84 | 7.84 | 7.84 | 7.84 | 7.83 | 7.84 |
| Binder polymer P′-1 | 0.85 | 0.85 | 0.85 | 0.85 | 0.85 | 0.85 | 0.85 | 0.85 | 0.85 | 0.85 |
| (powder) | | | | | | | | | | |
| Kuraray Poval 4-88LA | — | — | — | — | — | — | — | — | — | — |
| (Kuraray Co., Ltd.) | | | | | | | | | | |
| Monomer having carboxy | 0.03 | 0.03 | 0.03 | 0.03 | 0.03 | 0.03 | 0.03 | 0.03 | 0.03 | 0.03 |
| group ARONIX TO-2349 | | | | | | | | | | |
| (Toagosei Co., Ltd.) | | | | | | | | | | |
| Polyvinylpyrrolidone | — | — | — | — | — | — | — | — | — | — |
| K-30 (NIPPON | | | | | | | | | | |
| SHOKUBAI CO., | | | | | | | | | | |
| LTD.) | | | | | | | | | | |
| FOM-03010 (FUJIFILM | — | — | — | — | — | — | — | — | — | — |
| Wako Pure Chemical | | | | | | | | | | |
| Corporation) | | | | | | | | | | |
| FOM-03006 (FUJIFILM | — | — | — | — | — | — | — | — | — | — |
| Wako Pure Chemical | | | | | | | | | | |
| Corporation) | | | | | | | | | | |
| Monoisopropanolamine | 0.02 | 0.02 | 0.02 | 0.02 | 0.02 | 0.02 | 0.02 | 0.02 | 0.02 | 0.02 |
| N-Methyldiethanolamine | 0.03 | 0.03 | 0.03 | 0.03 | 0.03 | 0.03 | 0.03 | 0.03 | 0.03 | — |
| Adenine | 0.03 | 0.03 | 0.03 | 0.03 | 0.03 | 0.03 | 0.03 | 0.03 | 0.03 | — |
| 1-Benzotriazole | — | — | — | — | — | — | — | — | — | 0.03 |
| (FUJIFILM Wako Pure | | | | | | | | | | |
| Chemical Corporation) | | | | | | | | | | |
| FOM-03011 (FUJIFILM | — | — | — | — | — | — | — | — | — | — |
| Wako Pure Chemical | | | | | | | | | | |
| Corporation) | | | | | | | | | | |
| BYK-345 (BYK Chemie | 0.02 | — | — | — | — | — | — | — | — | 0.03 |
| Japan, surfactant) | | | | | | | | | | |
| BYK-347 (BYK Chemie | — | 0.03 | — | — | — | — | — | — | — | — |
| Japan, surfactant) | | | | | | | | | | |
| HYDROPALAT WE 3323 | — | — | 0.02 | — | — | — | — | — | — | — |
| (BASF Japan, surfactant) | | | | | | | | | | |
| BYK-348 (BYK Chemie | — | — | — | 0.02 | — | — | — | — | — | — |
| Japan, surfactant) | | | | | | | | | | |
| U-120E (Uni-chem Co., | — | — | — | — | 0.01 | 0.05 | — | — | — | — |
| Ltd., surfactant) | | | | | | | | | | |
| BYK-349 (BYK Chemie | — | — | — | — | — | — | 0.02 | — | — | — |
| Japan, surfactant) | | | | | | | | | | |
| FTERGENT 212M (NEOS | — | — | — | — | — | — | — | 0.05 | 0.14 | — |
| COMPANY LIMITED, | | | | | | | | | | |
| surfactant) | | | | | | | | | | |
| BYK-342 (BYK Chemie | — | — | — | — | — | — | — | — | — | — |
| Japan, surfactant) | | | | | | | | | | |
| BYK-3450 (BYK Chemie | — | — | — | — | — | — | — | — | — | — |
| Japan, surfactant) | | | | | | | | | | |
| HYDROPALAT WE 3650 | — | — | — | — | — | — | — | — | — | — |
| (BASF Japan, surfactant) | | | | | | | | | | |
| Ion exchange water | 21.7 | 21.7 | 21.7 | 21.7 | 21.7 | 21.7 | 21.7 | 21.7 | 21.6 | 21.7 |
| Methanol | 65.1 | 65.1 | 65.1 | 65.1 | 65.1 | 65.1 | 65.1 | 65.1 | 65.1 | 65.1 |
| Total (part by mass) | 100 | 100 | 100 | 100 | 100 | 100 | 100 | 100 | 100 | 100 |

| | YA-11 | YA-12 | YA-13 | YA-14 | YA-15 | YA-16 | YA-17 | YB-1 | YB-2 | YB-3 |
|---|---|---|---|---|---|---|---|---|---|---|
| NanoUse OZ-S30M: ZrO2 | 4.33 | 4.34 | 4.34 | 4.34 | 4.34 | — | — | 4.34 | 4.34 | 4.34 |
| particles methanol | | | | | | | | | | |
| dispersion liquid | | | | | | | | | | |
| (non-volatile component: | | | | | | | | | | |
| 30.5%) (Nissan Chemical | | | | | | | | | | |
| Corporation) | | | | | | | | | | |
| Ammonia water (25%) | 7.84 | 7.84 | 7.84 | 7.84 | 7.84 | — | — | 7.84 | 7.84 | 7.84 |
| Binder polymer P′-1 | 0.85 | 0.85 | 0.85 | 0.85 | 0.85 | — | — | 0.85 | 0.85 | 0.85 |
| (powder) | | | | | | | | | | |
| Kuraray Poval 4-88LA | — | — | — | — | — | 4.83 | — | — | — | — |
| (Kuraray Co., Ltd.) | | | | | | | | | | |
| Monomer having carboxy | 0.03 | 0.03 | 0.03 | 0.03 | 0.03 | — | — | 0.03 | 0.03 | 0.03 |
| group ARONIX TO-2349 | | | | | | | | | | |
| (Toagosei Co., Ltd.) | | | | | | | | | | |
| Polyvinylpyrrolidone | — | — | — | — | — | 2.24 | — | — | — | — |
| K-30 (NIPPON | | | | | | | | | | |
| SHOKUBAI CO., | | | | | | | | | | |
| LTD.) | | | | | | | | | | |
| FOM-03010 (FUJIFILM | — | — | — | — | — | — | 11.00 | — | — | — |
| Wako Pure Chemical | | | | | | | | | | |
| Corporation) | | | | | | | | | | |
| FOM-03006 (FUJIFILM | — | — | — | — | — | — | 6.00 | — | — | — |
| Wako Pure Chemical | | | | | | | | | | |
| Corporation) | | | | | | | | | | |
| Monoisopropanolamine | 0.02 | 0.02 | 0.02 | 0.02 | 0.02 | — | — | 0.02 | 0.02 | 0.02 |
| N-Methyldiethanolamine | 0.03 | 0.03 | 0.03 | 0.03 | 0.03 | — | — | 0.03 | 0.03 | 0.03 |
| Adenine | — | 0.03 | 0.03 | 0.03 | 0.03 | — | — | 0.03 | 0.03 | 0.03 |
| 1-Benzotriazole | — | — | — | — | — | — | — | — | — | — |
| (FUJIFILM Wako Pure | | | | | | | | | | |
| Chemical Corporation) | | | | | | | | | | |
| FOM-03011 (FUJIFILM | 0.03 | — | — | — | — | — | 0.60 | — | — | — |
| Wako Pure Chemical | | | | | | | | | | |
| Corporation) | | | | | | | | | | |
| BYK-345 (BYK Chemie | 0.02 | 0.02 | 0.02 | 0.02 | 0.02 | 0.05 | — | — | — | — |
| Japan, surfactant) | | | | | | | | | | |
| BYK-347 (BYK Chemie | — | — | — | — | — | — | 0.05 | — | — | — |
| Japan, surfactant) | | | | | | | | | | |
| HYDROPALAT WE 3323 | — | — | — | — | — | — | — | — | — | — |
| (BASF Japan, surfactant) | | | | | | | | | | |
| BYK-348 (BYK Chemie | — | — | — | — | — | — | — | — | — | — |
| Japan, surfactant) | | | | | | | | | | |
| U-120E (Uni-chem Co., | — | — | — | — | — | — | — | — | — | — |
| Ltd., surfactant) | | | | | | | | | | |
| BYK-349 (BYK Chemie | — | — | — | — | — | — | — | — | — | — |
| Japan, surfactant) | | | | | | | | | | |
| FTERGENT 212M (NEOS | — | — | — | — | — | — | — | — | — | — |
| COMPANY LIMITED, | | | | | | | | | | |
| surfactant) | | | | | | | | | | |
| BYK-342 (BYK Chemie | — | — | — | — | — | — | — | 0.02 | — | — |
| Japan, surfactant) | | | | | | | | | | |
| BYK-3450 (BYK Chemie | — | — | — | — | — | — | — | — | 0.02 | — |
| Japan, surfactant) | | | | | | | | | | |
| HYDROPALAT WE 3650 | — | — | — | — | — | — | — | — | — | 0.02 |
| (BASF Japan, surfactant) | | | | | | | | | | |
| Ion exchange water | 21.7 | 16.8 | 13.3 | 51.8 | 42.8 | 30.0 | 22.4 | 21.7 | 21.7 | 21.7 |
| Methanol | 65.1 | 70.0 | 73.5 | 35.0 | 44.0 | 62.9 | 60.0 | 65.1 | 65.1 | 65.1 |
| Total (part by mass) | 100 | 100 | 100 | 100 | 100 | 100 | 100 | 100 | 100 | 100 |

TABLE 15

| | YA-18 | YA-19 | YA-20 | YA-21 | YA-22 |
|---|---|---|---|---|---|
| NanoUse OZ-S30M: ZrO2 particles methanol dispersion liquid | 4.34 | 4.34 | 4.34 | 4.34 | 4.34 |
| (non-volatile component: 30.5%) (Nissan Chemical Corporation) | | | | | |
| Ammonia water (25%) | 7.84 | 7.84 | 7.84 | 7.84 | 7.84 |
| Copolymer resin of methacrylic acid/allyl methacrylate (Mw: 38,000, | 0.20 | 0.20 | 0.20 | 0.20 | 0.20 |
| composition ratio = 20/80 wt %) | | | | | |
| ARUFON UC-3920 (manufactured by Toagosei Co., Ltd.) | 0.02 | 0.02 | 0.02 | 0.02 | 0.02 |
| Monomer having carboxy group | 0.03 | 0.03 | 0.03 | 0.03 | 0.03 |
| ARONIX TO-2349 (manufactured by Toagosei Co., Ltd.) | 0.03 | 0.03 | 0.03 | 0.03 | 0.03 |
| Adenine (manufactured by Tokyo Chemical Industry Co., Ltd.) | 0.03 | 0.03 | 0.03 | 0.03 | 0.03 |
| Ion exchange water | 21.3 | 21.3 | 21.3 | 21.3 | 21.3 |
| Methanol | 66.2 | 66.2 | 66.2 | 66.2 | 66.2 |
| BYK-345 (BYK Chemie Japan, surfactant) | 0.02 | 0.04 | — | — | 0.02 |
| BYK-348 (BYK Chemie Japan, surfactant) | — | — | 0.02 | 0.03 | — |
| EXP.S-506 (DIC Corporation) | — | — | — | — | 0.01 |
| Total (part by mass) | 100 | 100 | 100 | 100 | 100 |

Measurement of Surface Tension

A surface tension T1 and a surface tension T2 of each composition for forming a coating film described in Tables 14 and 15 were measured by the following methods. In the measurement of the surface tension, a CBVP-A3 type automatic surface tension meter manufactured by Kyowa Interface Science Co., Ltd. was used, and a platinum plate was used as a probe according to the Wilhelmy method.

Surface Tension T1

A 50 mL composition was taken as a sample, and the surface tension was measured three times by the Wilhelmy method in an environment of 25° C. and 60% RH (relative humidity). An arithmetic mean value of measurement values was defined as the surface tension T1. The measurement results are shown in Table 16.

Surface Tension T2

After measuring the surface tension T1, the sample was covered with a mesh to prevent foreign matter such as dust from entering the sample, and then the sample was left in a draft at 25° C. and 60% RH (relative humidity) and dried until a liquid volume of the sample reached 30 mL. After drying, the surface tension was measured three times by the Wilhelmy method. An arithmetic mean value of measurement values was defined as the surface tension T2. The measurement results are shown in Table 16. The time until the liquid volume of the sample reached 30 mL varies depending on the composition, but the liquid volume of the sample reached 30 mL in approximately 45 to 60 minutes.

### Example 1B

A composition YA-1 for forming a coating film was applied to a PET film (Toray Industries, Inc., LUMIRROR 16KS40) having a thickness of 16 μm as a base material using a slit-shaped nozzle at a coating rate of 70 m/m in a coating amount such that a thickness after drying was 70 nm, and the composition was dried at a drying temperature of 80° C. to form a coating film and wound into a roll. In addition, the coating rate was changed to 50 m/m to form a coating film according to the method described above and wound into a roll.

### Examples 2B to 26B and Comparative Examples 1B to 3B

A coating film was formed and wound into a roll by the same procedure as in Example 1B, except that the type of the composition for forming a coating film and the thickness after drying were appropriately changed according to the description in Table 16.

Evaluation: Coating Streak

The following evaluation was performed using the coating films produced in each of Examples 1B to 26B and Comparative Examples 1B to 3B. After feeding out the laminate of the base material and the coating film from the roll, a test piece having a size of 30 cm×20 cm was collected. The base material and the coating film of the test piece were arranged in this order on a black paper, light of a low-pressure sodium lamp was applied to the coating film in a dark room, and the reflected light on the surface of the coating film was visually observed to evaluate the presence or absence of coating streak. The surface observation as described above was repeated 5 times, and the coating streak was evaluated according to the following standard. The evaluation results are shown in Table 16.
A: no coating streak was observed.
B: number of coating streaks generated per 30 cm×20 cm was 3 or less.
C: number of coating streaks generated per 30 cm×20 cm was 4 or more.

TABLE 16

| | Composition for forming coating film | | | | | | Coating streak | |
|---|---|---|---|---|---|---|---|---|
| | | Surface | Surface | | Thickness after | | Coating rate | Coating rate |
| | Type | tension T1 | tension T2 | T1-T2 | drying [nm] | Base material | 70 m/m | 50 m/m |
| Example 1B | YA-1 | 29.4 | 23.8 | 5.6 | 70 | 16KS40 | A | A |
| Example 2B | YA-2 | 29.1 | 24.0 | 5.1 | 70 | 16KS40 | A | A |
| Example 3B | YA-3 | 29.4 | 26.0 | 3.4 | 70 | 16KS40 | B | A |
| Example 4B | YA-4 | 28.2 | 24.1 | 4.1 | 70 | 16KS40 | B | A |
| Example 5B | YA-5 | 28.3 | 21.5 | 6.8 | 70 | 16KS40 | A | A |
| Example 6B | YA-6 | 29.3 | 22.5 | 6.8 | 70 | 16KS40 | A | A |
| Example 7B | YA-7 | 29.6 | 25.8 | 3.8 | 70 | 16KS40 | B | A |
| Example 8B | YA-8 | 29.5 | 26.4 | 3.1 | 70 | 16KS40 | B | B |
| Example 9B | YA-9 | 28.4 | 26.3 | 2.1 | 70 | 16KS40 | B | B |
| Example 10B | YA-10 | 29.1 | 23.8 | 5.3 | 70 | 16KS40 | A | A |
| Example 11B | YA-11 | 29.9 | 24.2 | 5.7 | 70 | 16KS40 | A | A |
| Example 12B | YA-12 | 28.9 | 22.8 | 6.1 | 70 | 16KS40 | A | A |
| Example 13B | YA-13 | 27.8 | 23.1 | 4.7 | 70 | 16KS40 | B | A |
| Example 14B | YA-14 | 33.8 | 26.3 | 7.5 | 70 | 16KS40 | B | A |
| Example 15B | YA-15 | 32.7 | 25.9 | 6.8 | 70 | 16KS40 | A | A |
| Example 16B | YA-16 | 29.7 | 23.6 | 6.1 | 500 | 16KS40 | A | A |
| Example 17B | YA-16 | 29.7 | 23.6 | 6.1 | 1600 | 16KS40 | A | A |
| Example 18B | YA-17 | 29.9 | 24.8 | 5.1 | 1000 | 16KS40 | A | A |
| Example 19B | YA-17 | 29.9 | 24.8 | 5.1 | 3000 | 16KS40 | A | A |
| Example 20B | YA-1 | 29.4 | 23.8 | 5.6 | 50 | 16KS40 | A | A |
| Example 21B | YA-1 | 29.4 | 23.8 | 5.6 | 200 | 16KS40 | A | A |
| Example 22B | YA-18 | 29.4 | 23.8 | 5.6 | 70 | 16KS40 | A | A |
| Example 23B | YA-19 | 29.2 | 22.8 | 6.4 | 70 | 16KS40 | A | A |
| Example 24B | YA-20 | 28.2 | 24.1 | 4.1 | 70 | 16KS40 | B | A |
| Example 25B | YA-21 | 28.0 | 23.8 | 4.2 | 70 | 16KS40 | B | A |
| Example 26B | YA-22 | 29.4 | 23.8 | 5.6 | 70 | 16KS40 | A | A |
| Comparative | YB-1 | 28.7 | 29.6 | −0.9 | 70 | 16KS40 | C | C |
| Example 1B | | | | | | | | |
| Comparative | YB-2 | 28.7 | 32.5 | −3.8 | 70 | 16KS40 | C | C |
| Example 2B | | | | | | | | |
| Comparative | YB-3 | 29.5 | 29.6 | −0.1 | 70 | 16KS40 | C | C |
| Example 3B | | | | | | | | |

Each of the photosensitive compositions of Examples 1B to 26B corresponds to the composition according to the second embodiment described above. Table 16 shows that the occurrence of coating streak was suppressed in Examples as compared with Comparative Examples. Specifically, according to the compositions for forming a coating film of Examples, the coating streak was unlikely to occur even at a coating rate of 50 m/m or more.

### Example 101B

The photosensitive composition (specifically, the photosensitive composition produced in Example 14A described above) was applied to a PET film (Toray Industries, Inc., LUMIRROR 16KS40) having a thickness of 16 μm as a temporary support using a slit-shaped nozzle in a coating amount such that a thickness after drying was 5.5 nm, and the solvent was volatilized in a drying zone at 100° C. to form a photosensitive layer. Further, the composition YA-1 for forming a coating film was applied to the photosensitive layer using a slit-shaped nozzle in a coating amount such that a thickness after drying was 70 nm, and the composition was dried at a drying temperature of 80° C. to form refractive index adjusting layer. A PET film (Toray Industries, Inc., LUMIRROR 16KS40) having a thickness of 16 μm as a protective film was pressure-bonded onto the refractive index adjusting layer, and then wound into a roll to produce a transfer film.

### Example 102B

A substrate having an ITO transparent electrode pattern and a copper lead wire in this order was prepared on a cycloolefin transparent film. Using the transfer film of Example 101B, the transfer film was laminated at a position where the photosensitive layer covered the ITO transparent electrode pattern and the copper lead wire. Specifically, the lamination was performed using a vacuum laminator manufactured by MCK under conditions of a temperature of the cycloolefin transparent film: 40° C., a rubber roller temperature: 100° C., a linear pressure: 3 N/cm, and a transportation speed: 2 m/min. Using a proximity type exposure machine (manufactured by Hitachi High-Tech Electronics Engineering Co., Ltd.) including an ultra-high pressure mercury lamp, an exposure mask (specifically, quartz exposure mask having a pattern for forming an overcoat) and the temporary support were closely attached, and the laminate was exposed in a patterned manner with an exposure amount of 100 mJ/cm² (exposure amount measured by i-rays) through the temporary support. After peeling off the temporary support, development treatment was performed for 45 seconds with a 1.0% sodium carbonate aqueous solution (25° C.). The residue was removed by spraying ultrapure water onto the cycloolefin transparent film from an ultrahigh pressure washing nozzle. Next, air was blown to remove water, and post-baking treatment was performed at 145° C. for 30 minutes to form a transparent laminate having the cycloolefin transparent film, the ITO transparent electrode pattern, the copper lead wire, the refractive index adjusting layer, and the cured film pattern in this order. Using the produced transparent laminate, a touch panel was produced by a known method. The produced touch panel was attached to a liquid crystal display element produced by a method described in paragraphs [0097] to [0119] of JP2009-47936A, thereby producing a liquid crystal display device equipped with a touch panel. It was confirmed that there was no problem in display characteristics and the operation in the liquid crystal display device equipped with a touch panel.

### Examples 103B to 132B

Production of Transfer Film

The photosensitive composition was applied to a PET film (Toray Industries, Inc., LUMIRROR 16KS40) having a thickness of 16 μm as a temporary support using a slit-shaped nozzle in a coating amount such that a thickness after drying was the thickness shown in Table 17, and the solvent was volatilized in a drying zone at 100° C. to form a photosensitive layer. As the photosensitive composition, specifically, any of the photosensitive compositions OC-1 to OC-6 produced in Examples 563A to 568A described above was used. Further, any of the compositions YA-18 to YA-22 for forming a coating film was applied to the photosensitive layer using a slit-shaped nozzle in a coating amount such that a thickness after drying was 70 nm, and the composition was dried at a drying temperature of 80° C. to form refractive index adjusting layer. A PET film (Toray Industries, Inc., LUMIRROR 16KS40) having a thickness of 16 μm as a protective film was pressure-bonded onto the refractive index adjusting layer, and then wound into a roll to produce a transfer film.

Production of Transparent Laminate

Transfer

A transparent film substrate having an ITO transparent electrode pattern formed on a cycloolefin transparent film was prepared. Using each transfer film from which the protective film had been peeled off, the transfer film was laminated on the transparent film substrate so that the refractive index adjusting layer covered the transparent electrode pattern of the transparent electrode pattern film. Specifically, the lamination was performed using a vacuum laminator manufactured by MCK under conditions of a temperature of the transparent film substrate: 40° C., a rubber roller temperature: 110° C., a linear pressure: 3 N/cm, and a transportation speed: 2 m/min. The obtained laminate had the cycloolefin transparent film, the ITO transparent electrode pattern, the refractive index adjusting layer, the photosensitive layer, and the temporary support in this order.

Pattern Exposure

Next, using a proximity type exposure machine (manufactured by Hitachi High-Tech Electronics Engineering Co., Ltd.) including an ultra-high pressure mercury lamp, a distance between an exposure mask (specifically, quartz exposure mask having a pattern for forming an overcoat) and the temporary support was set to 125 μm, and the laminate was exposed in a patterned manner with an exposure amount of 150 mJ/cm² (exposure amount measured by i-rays) through the temporary support. After peeling off the temporary support, development treatment was performed for 60 seconds with a 1% sodium carbonate aqueous solution (32° C.). The residue was removed by spraying ultrapure water onto the transparent film substrate after washing from an ultrahigh pressure washing nozzle. Subsequently, air was blown to remove water on the transparent film substrate, and post-baking treatment was performed at 145° C. for 30 minutes to obtain a transparent laminate having the cycloolefin transparent film, the transparent electrode pattern, the refractive index adjusting layer disposed in direct contact with the transparent electrode pattern, and the cured film pattern of the photosensitive layer disposed in direct contact with the refractive index adjusting layer in this order. In a region where the transparent electrode pattern did not exist, the refractive index adjusting layer was in direct contact with the cycloolefin transparent film.

Evaluation

Color Unevenness

For each of the obtained transparent laminates, a black PET material (product name: PT100 NB, manufactured by LINTEC Corporation) and the cycloolefin transparent film were adhered to each other through a transparent adhesive tape (product name: OCA Tape 8171CL, manufactured by 3M Company) so as to be adjacent to each other to produce an evaluation substrate. Light was incident from the cured film pattern side of the evaluation substrate, and the reflected light was visually observed obliquely, and color unevenness was evaluated according to the following evaluation standard. —Evaluation standard—
5 points: no color unevenness could be seen.
4 points: partially color unevenness was seen.
3 points: color unevenness was slightly seen in many parts.
2 points: color unevenness was partially seen clearly.
1 point: color unevenness was clearly seen on the entire surface.

The obtained results are shown in Table 17 below. As the point of the evaluation is higher, the color unevenness is more suppressed, which is preferable.

TABLE 17

| | Refractive index adjusting later | | Photosensitve layer | | | |
|---|---|---|---|---|---|---|
| | | Thickness after | | Thickness after | Base material | Color |
| | No. | drying [nm] | No. | drying [nm] | Type | unevenness |
| Example 103B | YA-18 | 70 | OC-1 | 5.5 | 16KS40 | 4 |
| Example 104B | YA-19 | 70 | OC-1 | 5.5 | 16KS40 | 5 |
| Example 105B | YA-20 | 70 | OC-1 | 5.5 | 16KS40 | 4 |
| Example 106B | YA-21 | 70 | OC-1 | 5.5 | 16KS40 | 5 |
| Example 107B | YA-22 | 70 | OC-1 | 5.5 | 16KS40 | 5 |
| Example 108B | YA-18 | 70 | OC-2 | 5.5 | 16KS40 | 3 |
| Example 109B | YA-19 | 70 | OC-2 | 5.5 | 16KS40 | 4 |
| Example 110B | YA-20 | 70 | OC-2 | 5.5 | 16KS40 | 3 |
| Example 111B | YA-21 | 70 | OC-2 | 5.5 | 16KS40 | 4 |
| Example 112B | YA-22 | 70 | OC-2 | 5.5 | 16KS40 | 4 |
| Example 113B | YA-18 | 70 | OC-3 | 5.5 | 16KS40 | 4 |
| Example 114B | YA-19 | 70 | OC-3 | 5.5 | 16KS40 | 5 |
| Example 115B | YA-20 | 70 | OC-3 | 5.5 | 16KS40 | 4 |
| Example 116B | YA-21 | 70 | OC-3 | 5.5 | 16KS40 | 5 |
| Example 117B | YA-22 | 70 | OC-3 | 5.5 | 16KS40 | 5 |
| Example 118B | YA-18 | 70 | OC-4 | 8.1 | 16KS40 | 4 |
| Example 119B | YA-19 | 70 | OC-4 | 8.1 | 16KS40 | 5 |
| Example 120B | YA-20 | 70 | OC-4 | 8.1 | 16KS40 | 4 |
| Example 121B | YA-21 | 70 | OC-4 | 8.1 | 16KS40 | 5 |
| Example 122B | YA-22 | 70 | OC-4 | 8.1 | 16KS40 | 5 |
| Example 123B | YA-18 | 70 | OC-5 | 8.1 | 16KS40 | 3 |
| Example 124B | YA-19 | 70 | OC-5 | 8.1 | 16KS40 | 4 |
| Example 125B | YA-20 | 70 | OC-5 | 8.1 | 16KS40 | 3 |
| Example 126B | YA-21 | 70 | OC-5 | 8.1 | 16KS40 | 4 |
| Example 127B | YA-22 | 70 | OC-5 | 8.1 | 16KS40 | 4 |
| Example 128B | YA-18 | 70 | OC-6 | 8.1 | 16KS40 | 4 |
| Example 129B | YA-19 | 70 | OC-6 | 8.1 | 16KS40 | 5 |
| Example 130B | YA-20 | 70 | OC-6 | 8.1 | 16KS40 | 4 |
| Example 131B | YA-21 | 70 | OC-6 | 8.1 | 16KS40 | 5 |
| Example 132B | YA-22 | 70 | OC-6 | 8.1 | 16KS40 | 5 |

Table 17 shows that the transparent laminates of Examples 103B to 132B suppress the occurrence of color unevenness.

In a case where the transparent laminate is irradiated with light, the incident light is reflected at one interface and the other interface of the refractive index adjusting layer, and optical interference occurs due to the difference in optical path length. In this case, in a case where the thickness of the refractive index adjusting layer is not constant, a difference in interference color occurs in the plane, and there is a tendency for color unevenness to be visually recognized That is, by setting the thickness of the refractive index adjusting layer uniform, the color unevenness is reduced. From the viewpoint of improving uniformity of the thickness of the refractive index adjusting layer, it is preferable that the surfactant included in the refractive index adjusting layer has a high molecular weight, and it is preferable that the content of the surfactant in the composition forming the refractive index adjusting layer is high.

### Examples 103C to 122C

A transfer film and a transparent laminate were produced in the same manner as in Examples 103B to 122B and the color unevenness was evaluated, except that the temporary support and the protective film used to produce the transfer film were changed to the temporary support and the protective film shown below. The results were the same as those of Examples 103B to 122B, respectively.

Temporary support: product name “COSMOSHINE (registered trademark) A4160”, manufactured by TOYOBO Co., Ltd., thickness: 50 μm, PET film Protective film: product name “Alphan (registered trademark) E-210F”, manufactured by Oji F-Tex Co., Ltd., thickness: 50 μm, polypropylene film

### Examples 103D to 122D

A transfer film and a transparent laminate were produced in the same manner as in Examples 103B to 122B and the color unevenness was evaluated, except that the temporary support and the protective film used to produce the transfer film were changed to the temporary support and the protective film shown below. The results were the same as those of Examples 103B to 122B, respectively.

Temporary support: product name “COSMOSHINE (registered trademark) A4360”, manufactured by TOYOBO Co., Ltd., thickness: 38 μm, PET film Protective film: product name “Alphan (registered trademark) FG-201”, manufactured by Oji F-Tex Co., Ltd., thickness: 30 μm, polypropylene film

### Examples 103E to 122E

A transfer film and a transparent laminate were produced in the same manner as in Examples 103B to 122B and the color unevenness was evaluated, except that the temporary support and the protective film used to produce the transfer film were changed to the temporary support and the protective film shown below. The results were the same as those of Examples 103B to 122B, respectively.

Temporary support: product name “LUMIRROR (registered trademark) 16FB40”, manufactured by Toray Industries, Inc., thickness: 16 μm, PET film Protective film: product name “Alphan (registered trademark) E-210F”, manufactured by Oji F-Tex Co., Ltd., thickness: 50 μm, polypropylene film

### Example 123

A substrate having an ITO transparent electrode as an electromagnetic wave shield and a copper lead wire in this order was prepared on a cycloolefin transparent film. The protective film was peeled off from the transfer film of Example 103B, and the ITO transparent electrode and the copper lead wire were laminated at a position covered by the refractive index adjusting layer. Specifically, the lamination was performed using a vacuum laminator manufactured by MCK under conditions of a temperature of the cycloolefin transparent film: 40° C., a rubber roller temperature: 100° C., a linear pressure: 3 N/cm, and a transportation speed: 2 m/min.

Using a proximity type exposure machine (manufactured by Hitachi High-Tech Electronics Engineering Co., Ltd.) including an ultra-high pressure mercury lamp, an exposure mask (quartz exposure mask which shields only unnecessary parts around) and the temporary support were closely attached, and the laminate was exposed in a patterned manner with an exposure amount of 100 mJ/cm² (exposure amount measured by i-rays) through the temporary support.

After peeling off the temporary support, development treatment was performed for 45 seconds with a 1.0% sodium carbonate aqueous solution (25° C.). The residue was removed by spraying ultrapure water onto the cycloolefin transparent film from an ultrahigh pressure washing nozzle. Next, air was blown to remove water, and post-baking treatment was performed at 145° C. for 30 minutes to form a transparent laminate having the cycloolefin transparent film, the ITO transparent electrode, the copper lead wire, the refractive index adjusting layer, and the cured film in this order.

Using the produced transparent laminate, an electromagnetic wave shielding material was produced by a known method.

In the liquid crystal display device equipped with a touch panel, which was produced in Example 102B, the above-described electromagnetic wave shielding material was installed between the liquid crystal display device and the touch panel to produce a liquid crystal display device equipped with a touch panel and an electromagnetic wave shielding material. It was confirmed that there was no problem in display characteristics and the operation in the display device.

Explanation of References
10, 11: temporary support
20, 21, 22: dried product of composition
100, 110: transfer film

What is claimed is:

1. A composition, comprising:
an alkali-soluble resin;
a polymerizable compound;
a photopolymerization initiator;
a surfactant; and
a solvent,
wherein a surface tension of the composition measured by a Wilhelmy method at 25° C. is 26.5 mN/m or less.

2. The composition according to claim 1,
wherein the surface tension at 25° C. is 23.0 mN/m or more.

3. The composition according to claim 1,
wherein the surfactant comprises at least one compound selected from the group consisting of a fluorine-based surfactant, a silicone-based surfactant, and a hydrocarbon-based surfactant.

4. The composition according to claim 1,
wherein the surfactant comprises a silicone-based surfactant.

5. The composition according to claim 1,
wherein a surface tension of a mixture of 1 part by mass of a solid content of the surfactant, 1,000 parts by mass of water, and 2,300 parts by mass of methanol, which is measured by the Wilhelmy method, at 25° C., is 20.0 mN/m to 29.0 mN/m.

6. The composition according to claim 1,
wherein the solvent comprises at least one compound selected from the group consisting of methyl ethyl ketone, propylene glycol monomethyl ether acetate, propylene glycol monomethyl ether, toluene, xylene, isobutanol, phenyl glycol, methoxypropyl acetate, phenoxyethanol, dipropylene glycol monomethyl ether, n-butyl acetate, n-propyl acetate, ethyl acetate, isopropyl acetate, isobutyl acetate, methyl acetate, diacetone alcohol, cyclohexanone, ethylene glycol monoethyl ether, ethylene glycol monoethyl ether acetate, ethylene glycol mono-n-butyl ether, and ethylene glycol monomethyl ether.

7. A transfer film, comprising:
a temporary support; and
a dried product of the composition according to claim 1.

8. A pattern forming method, comprising, in the following order:
preparing a laminate comprising a base material and a dried product of the composition according to claim 1;
exposing the dried product in a patterned manner; and
developing the dried product using a developer to form a resin pattern.

9. A cured substance of the composition according to claim 1.

10. A composition, comprising:
a surfactant; and
a solvent,
wherein a surface tension T1 measured by a Wilhelmy method at 25° C. and a surface tension T2 measured by a Wilhelmy method at 25° C. immediately before a timing that a volume reaches 60% of an initial volume in an environment of a temperature of 25° C. and a relative humidity of 60% satisfy a relationship of T1>T2.

11. The composition according to claim 10,
wherein the surface tension T1 is 25 mN/m to 35 mN/m.

12. The composition according to claim 10,
wherein the surface tension T2 is 20 mN/m to 26 mN/m.

13. The composition according to claim 1,
wherein the surface tension T1 and the surface tension T2 satisfy a relationship of 5 mN/m<(T1−T2)<10 mN/m.

14. The composition according to claim 10,
wherein the solvent comprises water and an organic solvent.

15. The composition according to claim 14,
wherein the organic solvent comprises an organic solvent which does not azeotrope with the water.

16. The composition according to claim 15,
wherein a ratio of a content of the organic solvent which does not azeotrope with the water to a content of the water is 10/90 to 90/10 on a mass basis.

17. The composition according to claim 15,
wherein the organic solvent which does not azeotrope with the water comprises methanol.

18. The composition according to claim 10,
wherein the surfactant comprises at least one compound selected from the group consisting of a fluorine-based surfactant, a silicone-based surfactant, or a hydrocarbon-based surfactant.

19. The composition according to claim 10,
wherein the surfactant comprises a nonionic surfactant.

20. The composition according to claim 10, further comprising:
at least one selected from the group consisting of a photopolymerization initiator, a polymerizable compound, a polymer, and particles.

21. A pattern forming method, comprising, in the following order:
preparing a laminate including a base material and a dried product of the composition according to claim 10;
exposing the dried product in a patterned manner; and
developing the dried product using a developer to form a resin pattern.

22. A transfer film, comprising:
a temporary support; and
a dried product of the composition according to claim 10.

23. A dried product of the composition according to claim 10.
